(19) United States
(12) Patent Application Publication
(10) Pub. No.: US 2014/0246225 A1
(43) Pub. Date: Sep. 4, 2014

(54) TRANSPARENT CONDUCTIVE ELEMENT, INPUT DEVICE, ELECTRONIC APPARATUS, AND MASTER FOR PRODUCING TRANSPARENT CONDUCTIVE ELEMENT

(71) Applicant: DEXERIALS CORPORATION, Tokyo (JP)

(72) Inventors: Mikihisa Mizuno, Sendai-shi (JP); Junichi Inoue, Utsunomiya-shi (JP); Naoto Kaneko, Utsunomiya-shi (JP)

(73) Assignee: Dexerials Corporation, Tokyo (JP)

(21) Appl. No.: 14/352,945

(22) PCT Filed: Jan. 24, 2013
(86) PCT No.: PCT/JP2013/051375

§ 371 Date: Apr. 18, 2014

(30) Foreign Application Priority Data
Jan. 24, 2012 (JP) 2012-012527

(51) Int. Cl. H05K 1/02

(52) U.S. Cl. CPC H05K 1/0274
USPC 174/255

(57) ABSTRACT

A transparent conductive element having superior visibility includes: a substrate having a surface; and a transparent conductive portion and a transparent insulating portion provided alternately in a planar manner on the surface. At least one of the transparent conductive portion and the transparent insulating portion is a transparent conductive layer having a regular pattern therein. A shape pattern is provided in a boundary portion between the transparent conductive portion and the transparent insulating portion.

### TECHNICAL FIELD

The present technique relates to a transparent conductive element, an input device, an electronic apparatus, and a master for producing a transparent conductive element. More specifically, the invention relates to a transparent conductive element capable of improving visibility.

### BACKGROUND ART

In recent years, the cases that a capacitive touch panel is installed in a mobile device such as a mobile phone or a portable music terminal are increasing. The capacitive touch panel employs a transparent conductive film having a patterned transparent conductive layer provided on a substrate film surface. In the conventional transparent conductive film having such a configuration, however, an optical property difference is large between a portion having the transparent conductive layer and a portion where the transparent conductive layer has been removed. Therefore, the pattern of the transparent conductive layer becomes noticeable, resulting in a problem of a reduction in the visibility of the transparent conductive film.

In view of this, a technique has been proposed in which layered films formed by layering dielectric layers with different refractive indexes are provided between a transparent conductive thin-film layer and a substrate film, so that the visibility of the transparent conductive film is improved by utilizing optical interference of these layered films (Patent Literatures 1 and 2, for example).

### CITATION LIST

### Patent Literature

Patent Literature 1: Japanese Patent Application Laid-Open No. 2010-23282
Patent Literature 2: Japanese Patent Application Laid-Open No. 2010-27294

### SUMMARY OF INVENTION

### Technical Problem

In the above-described technique, however, the optical adjustment function of the layered films has a wavelength dependency. Therefore, it is difficult to sufficiently improve the visibility of the transparent conductive film. Thus, a technique to replace the above-described layered films has been desired in recent years as a technique for improving the visibility of the transparent conductive film.

It is therefore an object of the present technique to provide a transparent conductive element having superior visibility, an input device, an electronic apparatus, and a master for producing a transparent conductive element.

### Solution to Problem

In order to solve the above-described problem, the first technique relates to a transparent conductive element including:

a substrate having a surface; and

a transparent conductive portion and a transparent insulating portion provided alternately in a planar manner on the surface, wherein

at least one of the transparent conductive portion and the transparent insulating portion is a transparent conductive layer having a regular pattern therein, and

a shape pattern is provided in a boundary portion between the transparent conductive portion and the transparent insulating portion.

The second technique relates to an input device including:

a substrate having a first surface and a second surface; and

a transparent conductive portion and a transparent insulating portion provided alternately in a planar manner on the first surface and the second surface, wherein

at least one of the transparent conductive portion and the transparent insulating portion is a transparent conductive layer having a regular pattern therein, and

a shape pattern is provided in a boundary portion between the transparent conductive portion and the transparent insulating portion.

The third technique relates to an input device including:

a first transparent conductive element; and

a second transparent conductive element provided on a surface of the first transparent conductive element, wherein

the first transparent conductive element and the second transparent conductive element each include:
a substrate having a surface; and
a transparent conductive portion and a transparent insulating portion provided alternately in a planar manner on the surface,

at least one of the transparent conductive portion and the transparent insulating portion is a transparent conductive layer having a regular pattern therein, and

a shape pattern is provided in a boundary portion between the transparent conductive portion and the transparent insulating portion.

The fourth technique relates to an electronic apparatus including a transparent conductive element having: a substrate with a first surface and a second surface; and a transparent conductive portion and a transparent insulating portion provided alternately in a planar manner on the first surface and the second surface, wherein

at least one of the transparent conductive portion and the transparent insulating portion is a transparent conductive layer having a regular pattern therein, and

a shape pattern is provided in a boundary portion between the transparent conductive portion and the transparent insulating portion.

The fifth technique relates to an electronic apparatus including:

a first transparent conductive element; and

a second transparent conductive element provided on a surface of the first transparent conductive element, wherein

the first transparent conductive element and the second transparent conductive element each include:
a substrate having a first surface and a second surface; and
a transparent conductive portion and a transparent insulating portion provided alternately in a planar manner on the first surface and the second surface,

at least one of the transparent conductive portion and the transparent insulating portion is a transparent conductive layer having a regular pattern therein, and

a shape pattern is provided in a boundary portion between the transparent conductive portion and the transparent insulating portion.

The sixth technique relates to a master for forming a transparent conductive element, including a surface where a transparent conductive portion forming region and a transparent insulating portion forming region are provided alternately in a planar manner, wherein

at least one of the transparent conductive portion forming region and the transparent insulating portion forming region has a regular pattern in that region, and

a shape pattern is provided in a boundary portion between the transparent conductive portion forming region and the transparent insulating portion forming region.

In the present technique, the transparent conductive portion and the transparent insulating portion are provided alternately in a planar manner on the substrate surface. Therefore, a reflectance difference between the region with the transparent conductive portion and the region without the transparent conductive portion can be reduced.

Since the shape pattern is provided in the boundary portion between the transparent electrode portion and the transparent insulating portion, a straight-line boundary can be prevented from extending for a long distance. Therefore, the visual recognition of the boundary can be restrained.

### Advantageous Effects of Invention

As described above, the present technique can realize a transparent conductive element having superior visibility.

### BRIEF DESCRIPTION OF DRAWINGS

FIG. 1 is a cross-sectional view illustrating a configuration example of an information input device according to a first embodiment of the present technique.

FIG. 2A is a plan view illustrating a configuration example of a first transparent conductive element according to the first embodiment of the present technique. FIG. 2B is a cross-sectional view taken along line A-A illustrated in FIG. 2A.

FIG. 3A is a plan view illustrating a configuration example of a transparent electrode portion in the first transparent conductive element. FIG. 3B is a cross-sectional view taken along line A-A illustrated in FIG. 3A. FIG. 3C is a plan view illustrating a configuration example of a transparent insulating portion in the first transparent conductive element. FIG. 3D is a cross-sectional view taken along line A-A illustrated in FIG. 3C.

FIG. 4A is a plan view for explaining how to obtain an average boundary line length in the transparent electrode portion. FIG. 4B is a plan view for explaining how to obtain an average boundary line length in the transparent insulating portion.

FIGS. 5A to 5D are each a plan view illustrating an exemplary shape pattern in a boundary portion.

FIGS. 6A to 6D are each a plan view illustrating an exemplary shape pattern in the boundary portion.

FIGS. 7A to 7D are each a plan view illustrating an exemplary shape pattern in the boundary portion.

FIGS. 8A and 8B are each a plan view illustrating an exemplary shape pattern in the boundary portion.

FIGS. 9A to 9D are each a plan view illustrating a modification of the shape pattern in the boundary portion.

FIG. 10A is a plan view illustrating a configuration example of a second transparent conductive element according to the first embodiment of the present technique. FIG. 10B is a cross-sectional view taken along line A-A illustrated in FIG. 10A.

FIG. 11A is a plan view illustrating the first transparent conductive element in the state illustrated in FIG. 1 and the second transparent conductive element. FIG. 11B is a plan view illustrating a region R shown in FIG. 11A in an enlarged manner.

FIGS. 12A to 12D are each a process chart for explaining an example of a method for producing the first transparent conductive element of the present technique.

FIGS. 13A to 13D are each a cross-sectional view illustrating a modification of the first transparent conductive element according to the first embodiment of the present technique.

FIG. 14A is a plan view illustrating a configuration example of the transparent electrode portion of the first transparent conductive element. FIG. 14B is a cross-sectional view taken along line A-A illustrated in FIG. 14A. FIG. 14C is a plan view illustrating a configuration example of the transparent insulating portion of the first transparent conductive element. FIG. 14D is a cross-sectional view taken along line A-A illustrated in FIG. 14C.

FIGS. 15A to 15C are each a plan view illustrating an exemplary shape pattern in the boundary portion.

FIGS. 16A and 16B are each a plan view illustrating a modification of the shape pattern in the boundary portion.

FIG. 17A is a plan view illustrating a configuration example of the transparent electrode portion of the first transparent conductive element. FIG. 17B is a cross-sectional view taken along line A-A illustrated in FIG. 17A. FIG. 17C is a plan view illustrating a configuration example of the transparent insulating portion of the first transparent conductive element. FIG. 17D is a cross-sectional view taken along line A-A illustrated in FIG. 17C.

FIGS. 18A to 18D are each a plan view illustrating an exemplary shape pattern in the boundary portion.

FIGS. 19A to 19D are each a plan view illustrating an exemplary shape pattern in the boundary portion.

FIGS. 20A to 20D are each a plan view illustrating an exemplary shape pattern in the boundary portion.

FIGS. 21A and 21B are each a plan view illustrating an exemplary shape pattern in the boundary portion. FIGS. 21C and 21D are each a plan view illustrating a modification of the shape pattern in the boundary portion.

FIG. 22 is a schematic diagram for explaining an algorithm for generating a random pattern.

FIG. 23 is a flow chart for explaining the algorithm for generating a random pattern.

FIG. 24 is a schematic diagram for explaining an algorithm for generating a random pattern.

FIG. 25 is a flow chart for explaining the algorithm for generating a random pattern.

FIG. 26 is a schematic diagram for explaining the algorithm for generating a random pattern.

FIG. 27A is a schematic view illustrating an image of the method for generating a random pattern. FIG. 27B is a diagram illustrating an example of random pattern generation with the area ratio of circles set at 80%.

FIG. 28A is a diagram illustrating an example in which circle radii are made smaller as compared to the generated pattern. FIG. 28B is a diagram illustrating an example in which a pattern is generated by squares with corners being rounded off.

FIG. 29A is a plan view illustrating a configuration example of the transparent electrode portion of the first transparent conductive element. FIG. 29B is a cross-sectional view taken along line A-A illustrated in FIG. 29A. FIG. 29C is a plan view illustrating a configuration example of the transparent insulating portion of the first transparent conductive element. FIG. 29D is a cross-sectional view taken along line A-A illustrated in FIG. 29C.

FIGS. 30A to 30D are each a plan view illustrating an exemplary shape pattern in the boundary portion.

FIGS. 31A to 31D are each a plan view illustrating an exemplary shape pattern in the boundary portion.

FIGS. 32A to 32D are each a plan view illustrating an exemplary shape pattern in the boundary portion.

FIGS. 33A and 33B are each a plan view illustrating an exemplary shape pattern in the boundary portion. FIGS. 33C and 33D are each a plan view illustrating a modification of the shape pattern in the boundary portion.

FIG. 34A is a plan view illustrating a configuration example of the transparent electrode portion of the first transparent conductive element. FIG. 34B is a cross-sectional view taken along line A-A illustrated in FIG. 34A. FIG. 34C is a plan view illustrating a configuration example of the transparent insulating portion of the first transparent conductive element. FIG. 34D is a cross-sectional view taken along line A-A illustrated in FIG. 34C.

FIG. 35A is a plan view for explaining how to obtain an average boundary line length in the transparent electrode portion. FIG. 35B is a plan view for explaining how to obtain an average boundary line length in the transparent insulating portion.

FIGS. 36A and 36B are each a plan view illustrating an exemplary shape pattern in the boundary portion.

FIGS. 37A to 37C are each a schematic diagram for explaining an example of a method for generating a random pattern.

FIG. 38 is a schematic diagram for explaining a modification of the method for generating a random pattern.

FIG. 39 is a plan view illustrating modifications of a groove pattern width (a line width of a gap portion).

FIG. 40A is a plan view illustrating a configuration example of the transparent electrode portion of the first transparent conductive element. FIG. 40B is a cross-sectional view taken along line A-A illustrated in FIG. 40A. FIG. 40C is a plan view illustrating a configuration example of the transparent insulating portion of the first transparent conductive element. FIG. 40D is a cross-sectional view taken along line A-A illustrated in FIG. 40C.

FIGS. 41A and 41B are each a plan view illustrating an exemplary shape pattern in the boundary portion.

FIG. 42A is a plan view illustrating a configuration example of the first transparent conductive element according to a seventh embodiment of the present technique. FIG. 42B is a plan view illustrating a configuration example of the second transparent conductive element according to the seventh embodiment of the present technique.

FIG. 43A is a plan view illustrating the first transparent conductive element in the state illustrated in FIG. 1 and the second transparent conductive element. FIG. 43B is a plan view illustrating a region R shown in FIG. 43A in an enlarged manner.

FIG. 44 is a schematic diagram illustrating an example of regions of the transparent electrode portion and the transparent insulating portion.

FIG. 45 is a cross-sectional view illustrating a configuration example of an information input device according to an eighth embodiment of the present technique.

FIG. 46A is a plan view illustrating a configuration example of an information input device according to a ninth embodiment of the present technique. FIG. 46B is a cross-sectional view taken along line A-A illustrated in FIG. 46A.

FIG. 47A is a plan view illustrating the vicinity of an intersecting portion C shown in FIG. 46A in an enlarged manner. FIG. 47B is a cross-sectional view taken along line A-A illustrated in FIG. 47A.

FIG. 48 is a perspective view illustrating an example of a shape of a master used in a method for producing the first transparent conductive element according to a tenth embodiment of the present technique.

FIG. 49A is a plan view illustrating a first region of a master in an enlarged manner. FIG. 49B is a cross-sectional view taken along line A-A illustrated in FIG. 49A. FIG. 49C is a plan view illustrating a second region of the master in an enlarged manner. FIG. 49D is a cross-sectional view taken along line A-A illustrated in FIG. 49C.

FIG. 50A is a plan view illustrating a boundary portion between the first region and the second region in an enlarged manner. FIG. 50B is a cross-sectional view taken along line A-A illustrated in FIG. 50A.

FIGS. 51A and 51B are each a process chart for explaining an example of the method for producing the first transparent conductive element according to the tenth embodiment of the present technique.

FIG. 52 is an appearance view illustrating a television set as an example of an electronic apparatus.

FIGS. 53A and 53B are each an appearance view illustrating a digital camera as an example of the electronic apparatus.

FIG. 54 is an appearance view illustrating a notebook-type personal computer as an example of the electronic apparatus.

FIG. 55 is an appearance view illustrating a video camera as an example of the electronic apparatus.

FIG. 56 is an appearance view illustrating a mobile terminal device as an example of the electronic apparatus.

FIG. 57A is a plan view illustrating a portion of an X electrode portion in Example 1-1 in an enlarged manner. FIG. 57B is a plan view illustrating a portion of an insulating portion in Example 1-1 in an enlarged manner. FIG. 57C is a plan view illustrating a portion of a boundary portion between the X electrode portion and the insulating portion in Example 1-1 in an enlarged manner. FIG. 58A is a plan view illustrating a portion of an X electrode portion in Example 2-1 in an enlarged manner. FIG. 58B is a plan view illustrating a portion of an insulating portion in Example 2-1 in an enlarged manner. FIG. 58C is a plan view illustrating a portion of a boundary portion between the X electrode portion and the insulating portion in Example 2-1 in an enlarged manner.

FIG. 59A is a plan view illustrating a portion of an X electrode portion in Example 3-1 in an enlarged manner. FIG. 59B is a plan view illustrating a portion of an insulating portion in Example 3-1 in an enlarged manner. FIG. 59C is a plan view illustrating a portion of a boundary portion between the X electrode portion and the insulating portion in Example 3-1 in an enlarged manner.

FIG. 60A is a plan view illustrating a portion of a boundary portion between an X electrode portion and an insulating portion in Comparative Example 1-1 in an enlarged manner. FIG. 60B is a plan view illustrating a portion of a boundary portion between an X electrode portion and an insulating portion in Comparative Example 3-1 in an enlarged manner.

FIG. 61A is a plan view illustrating a portion of an insulating portion according to Example 7 in an enlarged manner. FIG. 61B is a plan view illustrating a portion of an insulating portion according to Example 8 in an enlarged manner. FIG. 61C is a plan view illustrating a portion of an insulating portion according to Example 9 in an enlarged manner.

FIG. 62A is a plan view illustrating a portion of an X electrode portion according to Example 10 in an enlarged manner. FIG. 62B is a plan view illustrating a portion of an X electrode portion according to Example 11 in an enlarged manner. FIG. 62C is a plan view illustrating a portion of an X electrode portion according to Example 12 in an enlarged manner.

FIG. 63A is a cross-sectional view illustrating a modification of the first transparent conductive element according to the first embodiment of the present technique. FIG. 63B is a cross-sectional view illustrating a modification of the information input device according to the first embodiment of the present technique.

### DESCRIPTION OF EMBODIMENTS

Embodiments of the present technique will be described in the following order with reference to the drawings.

1. First embodiment (an example in which regular patterns are provided in a transparent electrode portion and a transparent insulating portion)
2. Second embodiment (an example in which a continuous film is provided in a transparent electrode portion)
3. Third embodiment (an example in which a random pattern is provided in a transparent insulating portion)
4. Fourth embodiment (an example in which a random pattern is provided in a transparent electrode portion)
5. Fifth embodiment (an example in which a mesh-shaped groove portion is provided in a transparent insulating portion)
6. Sixth embodiment (an example in which a mesh-shaped conductive portion is provided in a transparent electrode portion)
7. Seventh embodiment (an example in which a transparent electrode portion is provided with a shape such that pad portions are connected together)
8. Eighth embodiment (an example in which a transparent electrode portion is provided on both surfaces of a substrate)
9. Ninth embodiment (an example in which transparent electrode portions are provided in a crossing manner on one principal surface of a substrate)
10. Tenth embodiment (an example in which a transparent conductive element is produced with a printing method)
11. Eleventh embodiment (an application example to an electronic apparatus)

### 1. First Embodiment

### Configuration of Information Input Device

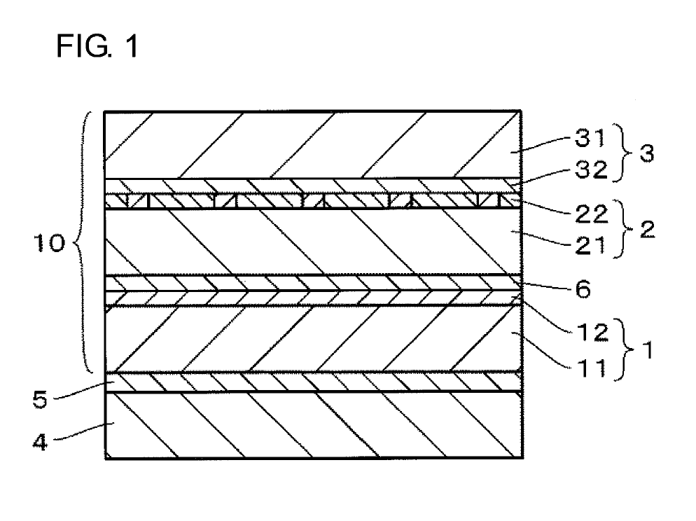

FIG. 1 is a cross-sectional view illustrating a configuration example of an information input device according to the first embodiment of the present technique. As illustrated in FIG. 1, an information input device 10 is provided above a display surface of a display device 4. The information input device 10 is adhered to the display surface of the display device 4 with an adhering layer 5, for example.

### (Display Device)

Examples of the display device 4 to which the information input device 10 is applied may include, but are not particularly limited to, various display devices such as a liquid crystal display, a CRT (Cathode Ray Tube) display, a PDP (Plasma Display Panel), an EL (Electro Luminescence) display, and an SED (Surface-conduction Electron-emitter Display).

### (Optical Layer)

An optical layer 3 includes a substrate 31 and an adhering layer 32 provided between the substrate 31 and a second transparent conductive element 2, for example. The substrate 31 is adhered to a surface of the second transparent conductive element 2 via the adhering layer 32. The optical layer 3 is not limited to this example and may be a ceramic coat (overcoat) such as SiO₂.

### (Information Input Device)

The information input device 10 is what is called a projected capacitive touch panel and includes a first transparent conductive element 1 and the second transparent conductive element 2 provided on the surface of the first transparent conductive element 1. The first transparent conductive element 1 and the second transparent conductive element 2 are adhered to each other via an adhering layer 6. The optical layer 3 may be further provided on the surface of the second transparent conductive element 2 if necessary.

### (First Transparent Conductive Element)

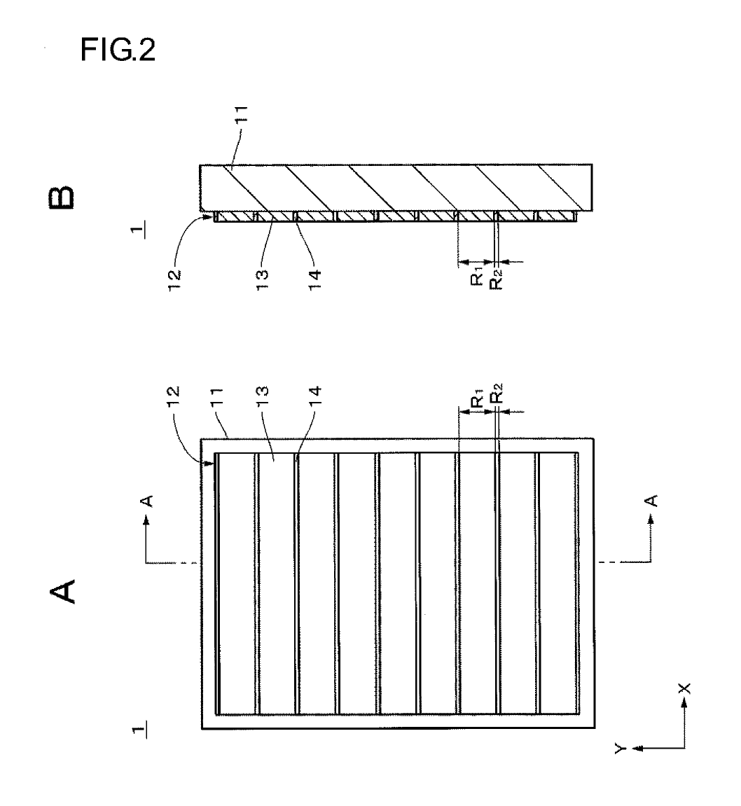

FIG. 2A is a plan view illustrating a configuration example of the first transparent conductive element according to the first embodiment of the present technique. FIG. 2B is a cross-sectional view taken along line A-A illustrated in FIG. 2A. Herein, two directions perpendicular to each other within a plane of the first transparent conductive element 1 are defined as an X-axis direction and a Y-axis direction.

As illustrated in FIGS. 2A and 2B, the first transparent conductive element 1 includes a substrate 11 having a surface and a transparent conductive layer 12 provided on this surface. The transparent conductive layer 12 includes transparent electrode portions (transparent conductive portions) 13 and transparent insulating portions 14. The transparent electrode portion 13 is an X electrode portion extended in the X-axis direction. The transparent insulating portion 14 is a so-called dummy electrode portion, and is an insulating portion extended in the X-axis direction and interposed between the transparent electrode portions 13 so as to provide insulation between adjacent transparent electrode portions 13. These transparent electrode portions 13 and the transparent insulating portions 14 are alternately and adjacently provided in a planar manner on the surface of the substrate 11 in the Y-axis direction. In FIGS. 2A and 2B, a first region R₁ indicates a region where the transparent electrode portion 13 is formed and a second region R₂ indicates a region where the transparent insulating portion 14 is formed.

### (Transparent Electrode Portion, Transparent Insulating Portion)

It is preferred to appropriately select shapes of the transparent electrode portion 13 and the transparent insulating portion 14 depending on a screen shape, a drive circuit, and the like. Examples of such a shape may include a linear shape and a shape such that a plurality of rhomboid shapes (diamond shapes) are linearly connected, although it is not particularly limited to these shapes. FIGS. 2A and 2B illustrate a configuration in which the transparent electrode portion 13 and the transparent insulating portion 14 each have a linear shape.

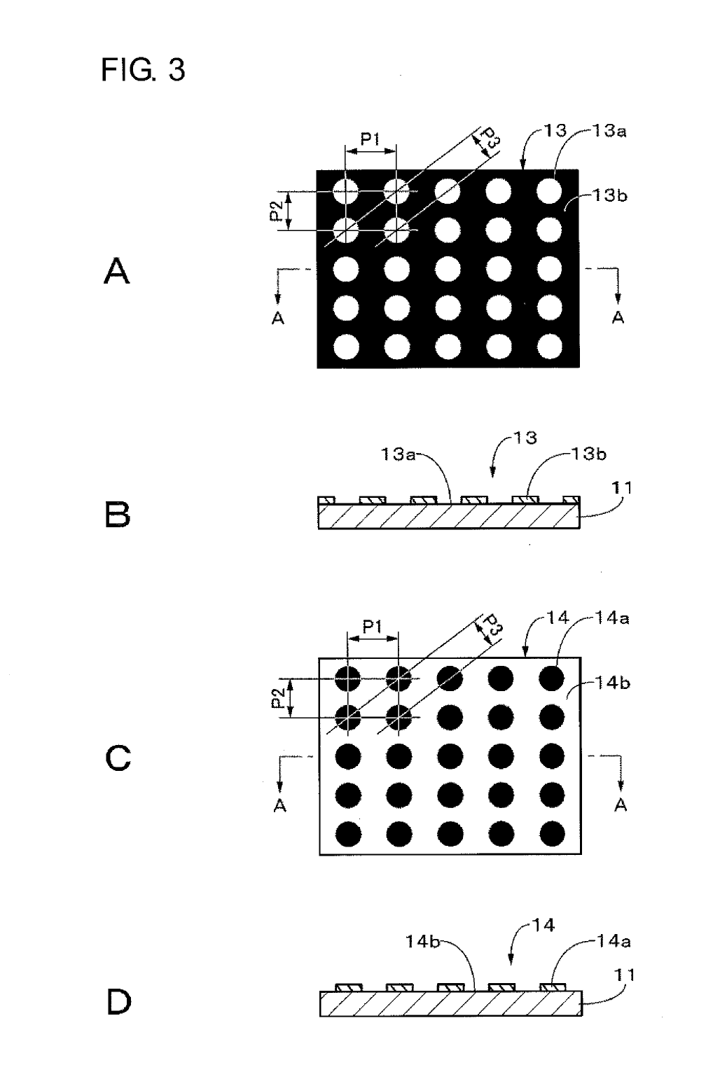

FIG. 3A is a plan view illustrating a configuration example of the transparent electrode portion 13 in the first transparent conductive element 1. FIG. 3B is a cross-sectional view taken along line A-A illustrated in FIG. 3A. FIG. 3C is a plan view illustrating a configuration example of the transparent insulating portion 14 in the first transparent conductive element 1. FIG. 3D is a cross-sectional view taken along line A-A illustrated in FIG. 3C. Both of the transparent electrode portion 13 and the transparent insulating portion 14 are the transparent conductive layers 12 having regular patterns therein. The pattern in the transparent conductive portion 13 is a pattern of a plurality of hole portions 13a, and the pattern in the transparent insulating portion 14 is a pattern of a plurality of island portions 14a. Both of the pattern of the plurality of hole portions 13a and the pattern of the plurality of island portions 14a are regular patterns.

As illustrated in FIGS. 3A and 3B, the transparent electrode portion 13 is the transparent conductive layer 12 having the plurality of hole portions 13a provided with a regular pattern so as to be spaced apart from one another. A conductive portion 13b is interposed between adjacent hole portions 13a. The transparent insulating portion 14, on the other hand, is the transparent conductive layer 12 having the plurality of island portions 14a provided with a regular pattern so as to be spaced apart from one another as illustrated in FIGS. 3C and 3D. A gap portion 14b serving as an insulating portion is interposed between adjacent island portions 14a. The island portion 14a is an island-shaped transparent conductive layer 12 containing a transparent conductive material as a major component, for example. In the gap portion 14b, it is preferable that the transparent conductive layer 12 have been completely removed. However, portion of the transparent conductive layer 12 may be remained in an island shape or in a thin-film shape as long as the gap portion 14b can function as an insulating portion.

The regular pattern herein means that pitches P1, P2, and P3 have regularlity. Thus, even when the shapes or sizes of the hole portions 13a and the island portions 14a are changed randomly, such a pattern is included in the regular pattern as long as the pitches P1, P2, and P3 have regularlity. The “pitches P1, P2, and P3 having regularlity” means that the pitches P1, P2, and P3 each are provided at equal intervals or that even when the pitches P1, P2, and P3 are varied, they are cyclic variations.

The pitches P1, P2, and P3 in all directions (i.e., the minimum pitch of the pitches P1, P2, and P3) of the hole portions 13a and the island portions 14a are preferably greater than 30 μm. If they are greater than 30 μm, the generation of diffracted light can be suppressed. Thus, the visibility of the information input device 10 and the display device 4 can be improved.

A dot shape, for example, may be used as a shape of the hole portion 13a and the island portion 14a. For example, one or more selected from the group consisting of a circular shape, an elliptical shape, a partially-cutaway circular shape, a partially-cutaway elliptical shape, a polygonal shape, a polygonal shape with corners being rounded off, and an indefinite shape can be used as a dot shape. Examples of such a polygonal shape may include, but are not limited to, a triangular shape, a quadrangular shape (for example, a rhombus or the like), a hexagonal shape, and an octagonal shape. The hole portion 13a and the island portion 14a may employ different shapes. Herein, the circular shape includes not only a mathematically-defined perfect circle (true circle) but also a circle with some distortion. The elliptical shape includes not only a mathematically-defined perfect ellipse but also an ellipse with some distortion (for example, an oval, an egg shape, or the like). The polygonal shape includes not only a mathematically-defined perfect polygon but also a polygon with a distorted side, a polygon with corners being rounded off, a polygon with a distorted side and with corners being rounded off, etc. Examples of such a distortion given to a side may include curvature such as a convex shape or a concave shape.

It is preferable that the hole portion 13a and the island portion 14a each have a visually-unrecognizable size. Specifically, the size of the hole portion 13a or the island portion 14a is preferably smaller than or equal to 100 μm, and more preferably smaller than or equal to 60 μm. The size (diameter) herein refers to the maximum one of lengths across the hole portion 13a and the island portion 14a. If the sizes of the hole portion 13a and the island portion 14a are set to be smaller than or equal to 100 μm, the visual recognition of the hole portions 13a and the island portions 14a can be restrained. Specifically, if the hole portion 13a and the island portion 14a each have a circular shape, for example, diameters thereof are preferably smaller than or equal to 100 μm.

In the first region R₁, the plurality of hole portions 13a serve as an exposed region for the surface of the substrate, whereas the conductive portion 13b interposed between the adjacent hole portions 13a serves as a covered region for the surface of the substrate, for example. In the second region R₂, on the other hand, the plurality of island portions 14a serve as a covered region for the surface of the substrate, whereas the gap portion 14b interposed between the adjacent island portions 14a serves as an exposed region for the surface of the substrate. A coverage difference between the first region R₁ and the second region R₂ is set to be smaller than or equal to 60%, preferably smaller than or equal to 40%, and more preferably smaller than or equal to 30%, and it is preferable that the portions of the hole portions 13a and the island portions 14a be formed to have visually-unrecognizable sizes. When the transparent electrode portion 13 is visually compared to the transparent insulating portion 14, it is felt that the transparent conductive layer 12 in the first region R₁ and that in the second region R₂ are being covered similarly. Thus, the visual recognition of the transparent electrode portion 13 and the transparent insulating portion 14 can be restrained.

It is preferred to increase a percentage of the covered area by the conductive portion 13b in the first region R₁. This is because of the following reason. In order to give the same conductivity, a thickness of the conductive portion 13b needs to be increased as the coverage decreases. In view of performing etching, however, it is necessary to increase a thickness at the time of the initial whole surface film forming, thereby leading to an increase in the cost in inverse proportion to the coverage. For example, if the coverage is 50%, the material cost doubles. If the coverage is 10%, the material cost decuples. In addition, an increase in the film thickness of the conductive portion 13b leads to problems such as deterioration in the optical property and degradation in the printing performance when a conductive material is manufactured into a coating material and a fine pattern is printed therewith. If the coverage becomes too small, the probability of insulation increases. In view of the above-described points, the coverage is preferably at least greater than or equal to 10%. The upper limit of the coverage is not particularly limited.

If the coverage by the island portions 14a in the second region R₂ is too high, the generation of a random pattern itself becomes difficult and the island portions 14a are positioned closer to each other, possibly resulting in short circuit. Thus, the coverage by the island portions 14a is preferably set to be smaller than or equal to 95%. Depending on a method for producing the first transparent conductive element 1, the thickness of the transparent conductive layer 12 may not be uniform. In such a case, the above-described “coverage” may be defined by a volume of the conductive material per unit area.

The absolute value of a difference between a reflection L value in the transparent electrode portion 13 and that in the transparent insulating portion 14 is preferably smaller than 0.3. This is because the visual recognition of the transparent electrode portion 13 and the transparent insulating portion 14 can be restrained. Herein, the absolute value of a difference between the reflection L values is a value evaluated in accordance with JIS 28722.

An average boundary line length La in the transparent electrode portion 13 provided in the first region (electrode region) R₁ and an average boundary line length Lb in the transparent insulating portion 14 provided in the second region (insulating region) R₂ preferably fall within a range of 0<La, Lb≦20 mm/mm². Note that the average boundary line length La is an average length of a boundary line between the hole portion 13a and the conductive portion 13b provided in the transparent electrode portion 13 and the average boundary line length Lb is an average length of a boundary line between the island portion 14a and the gap portion 14b provided in the transparent insulating portion 14.

By setting the average boundary line lengths La and Lb within the above-described range, a boundary between a portion where the transparent conductive layer 12 is formed and a portion where the transparent conductive layer 12 is not formed can be reduced on the surface of the substrate 11, thereby reducing the amount of light scattering at that boundary. Thus, the above-described absolute value of the reflection L value can be made smaller than 0.3 regardless of a ratio of the average boundary line lengths (La/Lb) to be described later. In other words, the visual recognition of the transparent electrode portion 13 and the transparent insulating portion 14 can be restrained.

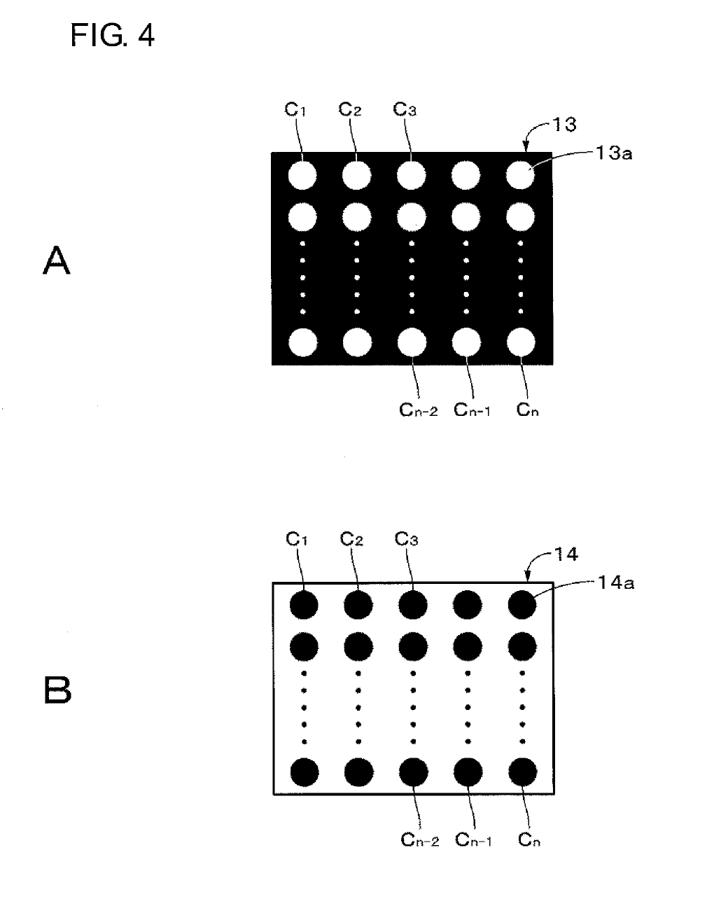

With reference to FIGS. 4A and 4B, how to obtain the average boundary line length La in the transparent electrode portion 13 and the average boundary line length Lb in the transparent insulating portion 14 will be described.

The average boundary line length La in the transparent electrode portion 13 is obtained as follows. First, the transparent electrode portion 13 is observed with a digital microscope (manufactured by KEYENCE CORPORATION, product name: VHX-900) at 100 to 500-fold observation magnification and the observed image is saved. Next, a boundary line (ΣCᵢ=C₁+ . . . +Cₙ) is measured from the saved observed image by means of image analysis to obtain a boundary line length L₁ [mm/mm²]. Such a measurement is performed on 10 views randomly selected from the transparent electrode portion 13 to obtain boundary line lengths L₁, . . . , L₁₀. Next, the obtained boundary line lengths L₁, . . . , L₁₀ are simply averaged (arithmetic average) to obtain the average boundary line length La in the transparent electrode portion 13.

The average boundary line length Lb in the transparent insulating portion 14 is obtained as follows. First, the transparent insulating portion 14 is observed with the digital microscope (manufactured by KEYENCE CORPORATION, product name: VHX-900) at 100 to 500-fold observation magnification and the observed image is saved. Next, a boundary line (ΣCᵢ=C₁+ . . . +Cₙ) is measured from the saved observed image by means of image analysis to obtain a boundary line length L₁ [mm/mm²]. Such a measurement is performed on 10 views randomly selected from the transparent insulating portion 14 to obtain boundary line lengths L₁, . . . , L₁₀. Next, the obtained boundary line lengths L₁, . . . , L₁₀ are simply averaged (arithmetic average) to obtain the average boundary line length Lb in the transparent insulating portion 14.

An average boundary line length ratio (La/Lb) between the average boundary line length La in the transparent electrode portion 13 provided in the first region (electrode region) R₁ and the average boundary line length Lb in the transparent insulating portion 14 provided in the second region (insulating region) R₂ is preferably in the range of from 0.75 or higher and 1.25 or lower. If the average boundary line length ratio (La/Lb) falls outside the above-described range, in a case where the average boundary line length La in the transparent electrode portion 13 and the average boundary line length Lb in the transparent insulating portion 14 are not set to be smaller than or equal to 20 mm/mm², the transparent electrode portion 13 and the transparent insulating portion 14 are visually recognized even when the coverage difference between the transparent electrode portion 13 and the transparent insulating portion 14 is the same. This is due to a difference between a refractive index in the portion with the transparent conductive layer 12 and a refractive index in the portion without the transparent conductive layer 12 on the surface of the substrate 11, for example. If the refractive index difference between the portion with the transparent conductive layer 12 and the portion without the transparent conductive layer 12 is large, light scattering occurs in a boundary portion between the portions with and without the transparent conductive layer 12. As a result, one of the regions of the transparent electrode portion 13 and the transparent insulating portion 14 having a longer boundary line length appears whiter and the electrode pattern of the transparent electrode portion 13 is therefore visually recognized regardless of the coverage difference. Quantitatively, the absolute value of the reflection L value difference between the transparent electrode portion 13 and the transparent insulating portion 14 evaluated in accordance with JIS Z8722 becomes greater than or equal to 0.3.

### (Boundary Portion)

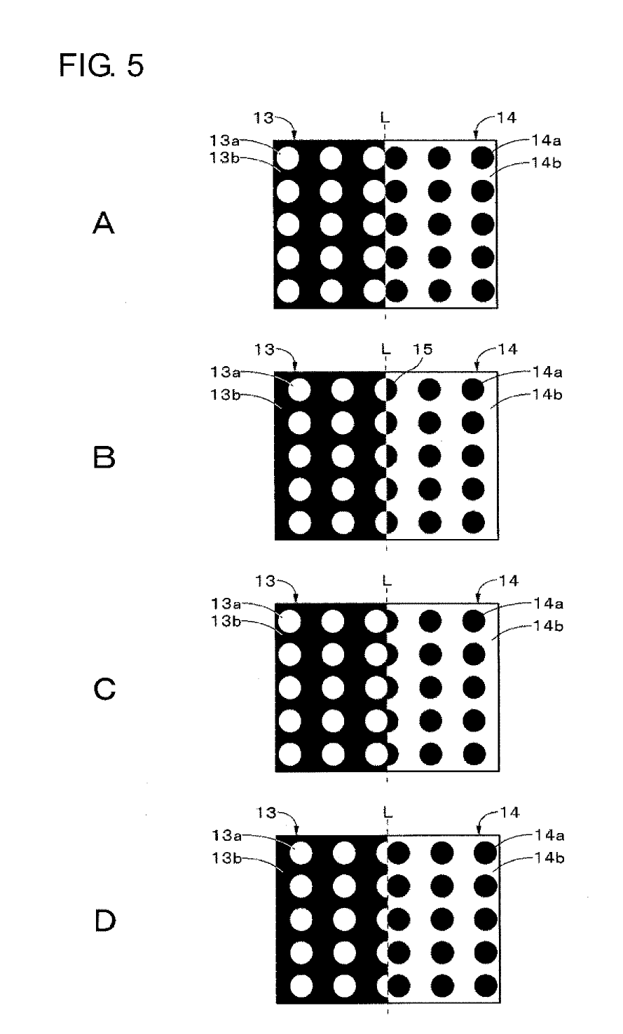

FIGS. 5A to 8B are each a plan view illustrating an exemplary shape pattern in the boundary portion. A regular shape pattern is provided in the boundary portion between the transparent electrode portion 13 and the transparent insulating portion 14. By providing a regular shape pattern in the boundary portion in this manner, the visual recognition of the boundary portion can be restrained. The boundary portion herein refers to a region between the transparent electrode portion 13 and the transparent insulating portion 14. A boundary L refers to a boundary line separating between the transparent electrode portion 13 and the transparent insulating portion 14. Depending on the shape pattern in the boundary portion, the boundary L may be not a solid line but an imaginary line (for example, in FIGS. 5D, 6A, 6D, 7C, and the like).

FIGS. 5B to 6D and FIGS. 7C to 8B illustrate examples where part of the hole portion 13a and part of the island portion 14a correspond to a half of the hole portion 13a and a half of the island portion 14a, respectively. The parts of the hole portion 13a and the island portion 14a are not limited to this example. The size of the parts of the hole portion 13a and the island portion 14a can be selected as desired.

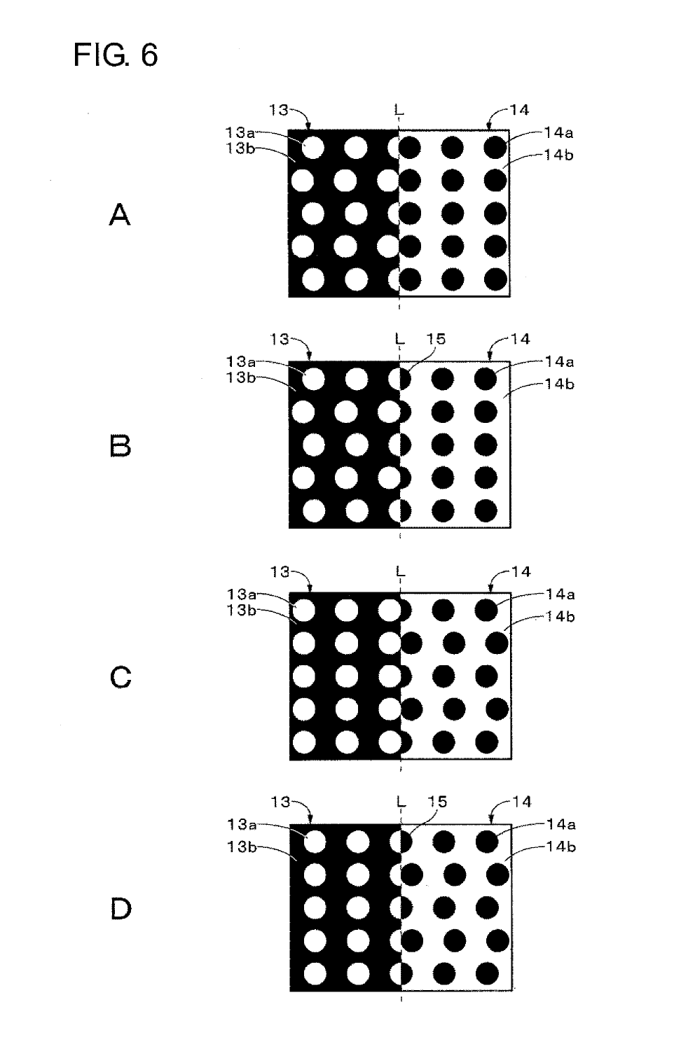

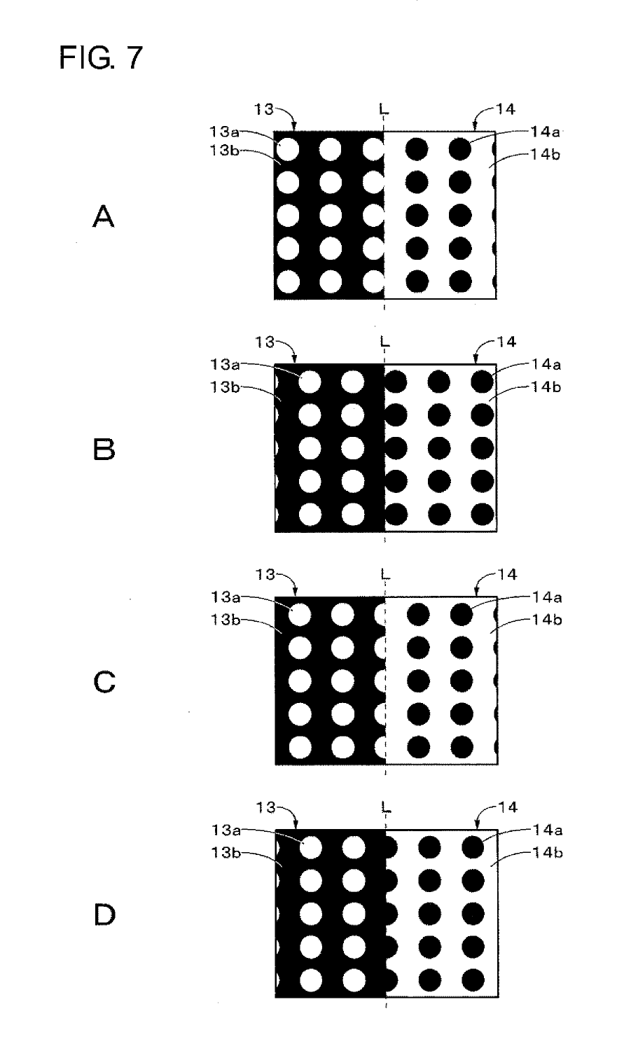

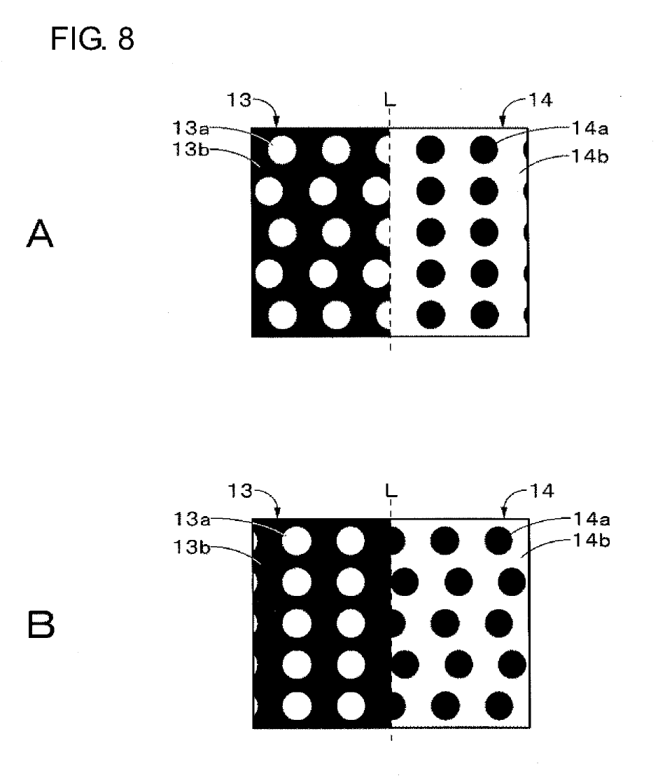

The shape pattern in the boundary portion includes one or more shapes selected from the group consisting of the whole of the hole portion 13a, part of the hole portion 13a, the whole of the island portion 14a, and part of the island portion 14a. Specifically, the shape pattern in the boundary portion, for example, includes: (1) the whole of the hole portion 13a and the whole of the island portion 14a (FIG. 5A); (2) part of the hole portion 13a and part of the island portion 14a (FIG. 5B); (3) the whole of one of the hole portion 13a and the island portion 14a and part of the other one thereof (FIGS. 5C and 5D); (4) both of the whole and part of the hole portion 13a and one of the whole and part of the island portion 14a (FIGS. 6A and 6B); (5) one of the whole and part of the hole portion 13a and both of the whole and part of the island portion 14a (FIGS. 6C and 6D); (6) the whole of one of the hole portion 13a and the island portion 14a (FIGS. 7A and 7B); (7) part of one of the hole portion 13a and the island portion 14a (FIGS. 7C and 7D); (8) both of the whole and part of the hole portion 13a (FIG. 8A); or (9) both of the whole and part of the island portion 14a (FIG. 8B).

The whole of the hole portion 13a included in the shape pattern in the boundary portion is provided in contact with the boundary L on the transparent electrode portion 13 side, for example. The whole of the island portion 14a included in the shape pattern in the boundary portion is provided in contact with the boundary L on the transparent insulating portion 14 side, for example.

Part of the hole portion 13a included in the shape pattern in the boundary portion has a shape such that the hole portion 13a is partially cut by the boundary L, for example. More specifically, part of the hole portion 13a included in the shape pattern in the boundary portion has a shape such that the hole portion 13a is partially cut and the cut edge is provided in contact with the boundary L on the transparent electrode portion 13 side, for example.

Part of the island portion 14a included in the shape pattern in the boundary portion has a shape such that the island portion 14a is partially cut by the boundary L, for example. More specifically, part of the hole portion 13a included in the shape pattern in the boundary portion has a shape such that the island portion 14a is partially cut and the cut edge is provided in contact with the boundary L on the transparent insulating portion 14 side, for example.

The hole portions 13a and the island portions 14a are provided in the boundary L so as to be in synchronization with, or out of synchronization with, each other in an extending direction of the boundary L, for example. When the hole portions 13a and the island portions 14a are provided in synchronization with each other in the extending direction of the boundary L, the hole portion 13a and the island portion 14a may form an inverting portion where the hole portion 13a is inverted into the island portion 14a with the boundary L used as a dividing line. In other words, a plurality of inverting portions may be provided at the boundary L with a regular pattern. The inverting portion is configured by a combination of one of the whole and part of the hole portion 13a and one of the whole and part of the island portion 14a. When the hole portion 13a and the island portion 14a each have a circular shape, the inverting portion is configured by part of the hole portion 13a and part of the island portion 14a, for example. In this case, the shape of the inverting portion is preferably circular.

It is preferable that the whole and part of the hole portion 13a included in the boundary portion be provided with the same regular pattern as that of the hole portions 13a in the transparent electrode portion 13. This eliminates a need to provide only the whole and part of the hole portion 13a included in the boundary portion with a pattern different from that of the transparent electrode portion 13. Therefore, the configuration of the first transparent conductive element 1 can be simplified.

It is also preferable that the whole and part of the island portion 14a included in the boundary portion be provided with the same arrangement pattern as that of the island portions 14a in the transparent insulating portion 14. This eliminates a need to provide only the whole and part of the island portion 14a included in the boundary portion with a pattern different from that of the transparent insulating portion 14. Therefore, the configuration of the first transparent conductive element 1 can be simplified.

With reference to FIGS. 5A to 8B, specific examples of the above-described shape patterns (1) to (9) will be sequentially described below.

### (1) Whole of Hole Portion 13a and Whole of Island Portion 14a

FIG. 5A illustrates an example in which the shape pattern in the boundary portion includes the whole of the hole portion 13a and the whole of the island portion 14a. In this example, the hole portion 13a included in the boundary portion is provided in contact with the boundary L on the transparent electrode portion 13 side. The island portion 14a included in the boundary portion, on the other hand, is provided in contact with the boundary L on the transparent insulating portion 14 side.

### (2) Part of Hole Portion 13a and Part of Island Portion 14a

FIG. 5B illustrates an example in which the shape pattern in the boundary portion includes part of the hole portion 13a and part of the island portion 14a. In this example, the part of the hole portion 13a included in the boundary portion has a shape such that the hole portion 13a is partially cut by the boundary L and the cut edge is provided in contact with the boundary L on the transparent electrode portion 13 side. The part of the island portion 14a included in the boundary portion, on the other hand, has a shape such that the island portion 14a is partially cut by the boundary L and the cut edge is provided in contact with the boundary L on the transparent insulating portion 14 side.

The hole portions 13a and the island portions 14a are provided in the boundary L so as to be in synchronization with each other in the extending direction of the boundary L. More specifically, a plurality of inverting portions 15 are provided on the boundary L with regularity so as to be spaced apart from one another. The inverting portion 15 includes the hole portion 13a and the island portion 14a and has a configuration in which the hole portion 13a is inverted into the island portion 14a with the boundary L used as a dividing line. By providing the plurality of inverting portions 15 on the boundary L in this manner, the visual recognition of the boundary L can be restrained.

### (3) Whole of One of Hole Portion 13a and Island Portion 14a and Part of the Other One Thereof

FIG. 5C illustrates an example in which the shape pattern in the boundary portion includes the whole of the hole portion 13a and part of the island portion 14a. In this example, the whole of the hole portion 13a included in the boundary portion is provided in contact with the boundary L on the transparent electrode portion 13 side. The part of the island portion 14a included in the boundary portion, on the other hand, has a shape such that the island portion 14a is partially cut by the boundary L and the cut edge is provided in contact with the boundary L on the transparent insulating portion 14 side.

FIG. 5D illustrates an example in which the shape pattern in the boundary portion includes part of the hole portion 13a and the whole of the island portion 14a. In this example, the part of the hole portion 13a included in the boundary portion has a shape such that the hole portion 13a is partially cut by the boundary L and the cut edge is provided in contact with the boundary L on the transparent electrode portion 13 side. The whole of the island portion 14a included in the boundary portion, on the other hand, is provided in contact with the boundary L on the transparent insulating portion 14 side.

### (4) Both of Whole and Part of Hole Portion 13a and One of Whole and Part of Island Portion 14a

FIG. 6A illustrates an example in which the shape pattern in the boundary portion includes both of the whole and part of the hole portion 13a and the whole of the island portion 14a. In this example, the whole of the hole portion 13a included in the boundary portion is provided in contact with the boundary L on the transparent electrode portion 13 side. The part of the hole portion 13a included in the boundary portion has a shape such that the hole portion 13a is partially cut by the boundary L and the cut edge is provided in contact with the boundary L on the transparent electrode portion 13 side. The whole of the island portion 14a included in the boundary portion, on the other hand, is provided in contact with the boundary L on the transparent insulating portion 14 side.

FIG. 6B illustrates an example in which the shape pattern in the boundary portion includes both of the whole and part of the hole portion 13a and part of the island portion 14a. In this example, the whole of the hole portion 13a included in the boundary portion is provided in contact with the boundary L on the transparent electrode portion 13 side. The part of the hole portion 13a included in the boundary portion has a shape such that the hole portion 13a is cut by the boundary L and the cut edge is provided in contact with the boundary L on the transparent electrode portion 13 side. The part of the island portion 14a included in the boundary portion, on the other hand, has a shape such that the island portion 14a is partially cut by the boundary L and the cut edge is provided in contact with the boundary L on the transparent insulating portion 14 side.

### (5) One of Whole and Part of Hole Portion 13a and Both of Whole and Part of Island Portion 14a

FIG. 6C illustrates an example in which the shape pattern in the boundary portion includes the whole of the hole portion 13a and both of the whole and part of the hole portion 13a. In this example, the whole of the hole portion 13a included in the boundary portion is provided in contact with the boundary L on the transparent electrode portion 13 side. The whole of the island portion 14a included in the boundary portion, on the other hand, is provided in contact with the boundary L on the transparent insulating portion 14 side. The part of the island portion 14a included in the boundary portion has a shape such that the island portion 14a is partially cut by the boundary L and the cut edge is provided in contact with the boundary L on the transparent insulating portion 14 side.

FIG. 6D illustrates an example in which the shape pattern in the boundary portion includes part of the hole portion 13a and both of the whole and part of the island portion 14a. In this example, the part of the hole portion 13a included in the boundary portion has a shape such that the hole portion 13a is partially cut by the boundary L and the cut edge is provided in contact with the boundary L on the transparent electrode portion 13 side. The whole of the island portion 14a included in the boundary portion, on the other hand, is provided in contact with the boundary L on the transparent insulating portion 14 side. The part of the island portion 14a included in the boundary portion has a shape such that the island portion 14a is partially cut by the boundary L and the cut edge is provided in contact with the boundary L on the transparent insulating portion 14 side.

### (6) Whole of One of Hole Portion 13a and Island Portion 14a

FIG. 7A illustrates an example in which the shape pattern in the boundary portion includes only the whole of the hole portion 13a. In this example, the whole of the hole portion 13a included in the boundary portion is provided in contact with the boundary L on the transparent electrode portion 13 side.

FIG. 7B illustrates an example in which the shape pattern in the boundary portion includes only the whole of the island portion 14a. In this example, the whole of the island portion 14a included in the boundary portion is provided in contact with the boundary L on the transparent insulating portion 14 side.

### (7) Part of One of Hole Portion 13a and Island Portion 14a

FIG. 7C illustrates an example in which the shape pattern in the boundary portion includes only part of the hole portion 13a. In this example, the part of the hole portion 13a included in the boundary portion has a shape such that the hole portion 13a is partially cut by the boundary L and the cut edge is provided in contact with the boundary L on the transparent electrode portion 13 side.

FIG. 7D illustrates an example in which the shape pattern in the boundary portion includes only part of the island portion 14a. In this example, the part of the island portion 14a included in the boundary portion has a shape such that the island portion 14a is partially cut by the boundary L and the cut edge is provided in contact with the boundary L on the transparent insulating portion 14 side.

### (8) Both of Whole and Part of Hole Portion 13a

FIG. 8A illustrates an example in which the shape pattern in the boundary portion includes only both of the whole and part of the hole portion 13a. In this example, the whole of the hole portion 13a included in the boundary portion is provided in contact with the boundary L on the transparent electrode portion 13 side. The part of the hole portion 13a included in the boundary portion has a shape such that the hole portion 13a is partially cut by the boundary L and the cut edge is provided in contact with the boundary L on the transparent electrode portion 13 side.

### (9) Both of Whole and Part of Island Portion 14a

FIG. 8B illustrates an example in which the shape pattern in the boundary portion includes only both of the whole and part of the island portion 14a. In this example, the whole of the island portion 14a included in the boundary portion is provided in contact with the boundary L on the transparent insulating portion 14 side. The part of the island portion 14a included in the boundary portion has a shape such that the island portion 14a is partially cut by the boundary L and the cut edge is provided in contact with the boundary L on the transparent insulating portion 14 side.

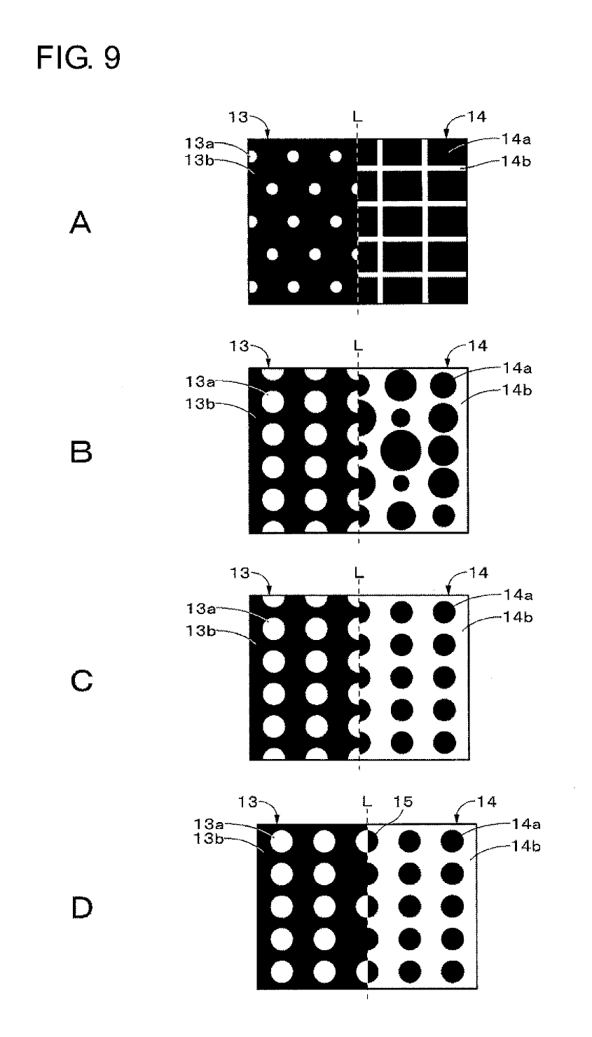

The specific examples of the above-described shape patterns (1) to (9) each describe, as an example, the configuration in which the hole portion 13a and the island portion 14a are provided with the same shape, size, and pattern. However, they may be different from each other as illustrated in FIG. 9A. Although FIG. 9A illustrates an example in which all of the shapes, sizes, and patterns of the hole portion 13a and the island portion 14a are different from each other, at least one of them may be different from each other.

As illustrated in FIG. 9B, the sizes of the hole portion 13a and the island portion 14a may be changed with regularity or randomly. When such a configuration is employed, the generation of moire can be suppressed. Although not illustrated in the figure, the shapes of the hole portion 13a and the island portion 14a may be changed with regularity or randomly. Also when such a configuration is employed, the generation of moire can be suppressed.

Although the configuration in which the hole portion 13a and the island portion 14a are provided in synchronization with each other in the extending direction of the boundary L has been described as an example, they may be provided out of synchronization with each other in the extending direction of the boundary L as illustrated in FIG. 9C.

Although the configuration in which the hole portions 13a and the island portions 14a form columns and all of the hole portions 13a and the island portions 14a positioned at one end of the columns are included in the shape pattern in the boundary portion has been described as an example, part of the hole portions 13a and the island portions 14a positioned at one end of the columns may be included in the shape pattern in the boundary portion.

### (Substrate)

A glass, a plastic, or the like, for example, can be used as a material for the substrate 11. A known glass, for example, can be used as a glass. Specific examples of such a known glass may include a soda-lime glass, a lead glass, a hard glass, a silica glass, and a liquid crystal glass. A known macromolecular material, for example, can be used as a plastic. Specific examples of such a known macromolecular material may include triacetylcellulose (TAC), polyester, polyethylene terephthalate (PET), polyethylene naphthalate (PEN), polyimide (PI), polyamide (PA), aramid, polyethylene (PE), polyacrylate, polyethersulfone, polysulfone, polypropylene (PP), diacetylcellulose, polyvinyl chloride, acrylic resins (PMMA), polycarbonate (PC), epoxy resins, urea resins, urethane resins, melamine resins, cyclic olefin polymers (COP), and norbornene-based thermoplastic resins.

The thickness of the glass substrate is preferably in the range of 20 μm to 10 mm, although it is not particularly limited to this range. The thickness of the plastic substrate is preferably in the range of 20 μm to 500 μm, although it is not particularly limited to this range.

### (Transparent Conductive Layer)

As a material for the transparent conductive layer 12, one or more selected from the group consisting of a metal-oxide material, a metallic material, a carbon material, a conductive polymer, and the like having electrical conductivity, for example, can be used. Examples of such a metal-oxide material may include indium tin oxide (ITO), zinc oxide, indium oxide, antimony-doped tin oxide, fluoridated tin oxide, aluminum-doped zinc oxide, gallium-doped zinc oxide, silicon-doped zinc oxide, zinc oxide-tin oxide series, indium oxide-tin oxide series, and zinc oxide-indium oxide-magnesium oxide series. A metal nanoparticle, a metal wire, or the like, for example, can be used as a metallic material. Examples of specific materials thereof may include metals such as copper, silver, gold, platinum, palladium, nickel, tin, cobalt, rhodium, iridium, iron, ruthenium, osmium, manganese, molybdenum, tungsten, niobium, tantalum, titanium, bismuth, antimony, and lead, and alloys thereof. Examples of the carbon material may include carbon black, carbon fiber, fullerene, graphene, carbon nanotube, carbon microcoil, and nanohorn. Examples of the conductive polymer which can be used may include substituted or unsubstituted polyaniline, polypyrrole, polythiophene, and (co)polymers made of one or more kinds selected from these.

As a method for forming the transparent conductive layer 12, a PVD method such as a sputtering method, a vacuum vapor deposition method, or an ion plating method, a CVD method, a coating method, a printing method, or the like, for example, can be used. It is preferable that the thickness of the transparent conductive layer 12 be appropriately selected so that the surface resistance thereof in a state before patterning (a state in which the transparent conductive layer 12 is formed on the entire surface of the substrate 11) is smaller than or equal to 1000Ω/□.

### (Second Transparent Conductive Element)

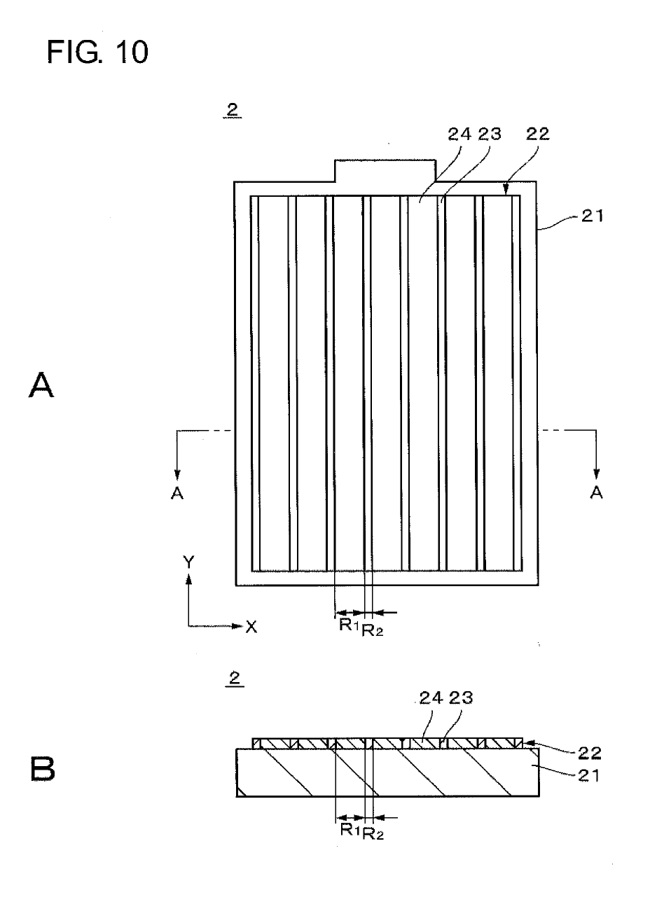

FIG. 10A is a plan view illustrating a configuration example of the second transparent conductive element 2 according to the first embodiment of the present technique. FIG. 10B is a cross-sectional view taken along line A-A illustrated in FIG. 10A. Herein, two directions perpendicular to each other within a plane of the second transparent conductive element 2 are defined as an X-axis direction and a Y-axis direction.

As illustrated in FIGS. 10A and 10B, the second transparent conductive element 2 includes a substrate 21 having a surface and a transparent conductive layer 22 provided on this surface. The transparent conductive layer 22 includes transparent electrode portions (transparent conductive portions) 23 and transparent insulating portions 24. The transparent electrode portion 23 is a Y electrode portion extended in the Y-axis direction. The transparent insulating portion 24 is a so-called dummy electrode portion, and is an insulating portion extended in the Y-axis direction and interposed between the transparent electrode portions 23 so as to provide insulation between adjacent transparent electrode portions 23. These transparent electrode portions 23 and the transparent insulating portions 24 are alternately and adjacently provided on the surface of the substrate 21 in the X-axis direction. The transparent electrode portions 13 and the transparent insulating portions 14 included in the first transparent conductive element 1 and the transparent electrode portions 23 and the transparent insulating portions 24 included in the second transparent conductive element 2 have a relationship perpendicular to each other, for example. In FIGS. 10A and 10B, a first region R₁ indicates a region for forming the transparent electrode portion 23 and a second region R₂ indicates a region where the transparent insulating portion 24 is formed.

In the second transparent conductive element 2, those excluding the above are the same as those in the transparent conductive element 1.

(Relationship between Coverages of Both Elements)

In order to further improve the non-visibility of the information input device 10, it is preferred to set a relationship between coverages of the first transparent conductive element 1 (X electrode) and the transparent conductive element 2 (Y electrode) in a state where both the elements are overlapped with each other. A specific method for setting a relationship between coverages of the first transparent conductive element 1 and the second transparent conductive element 2 will be described below.

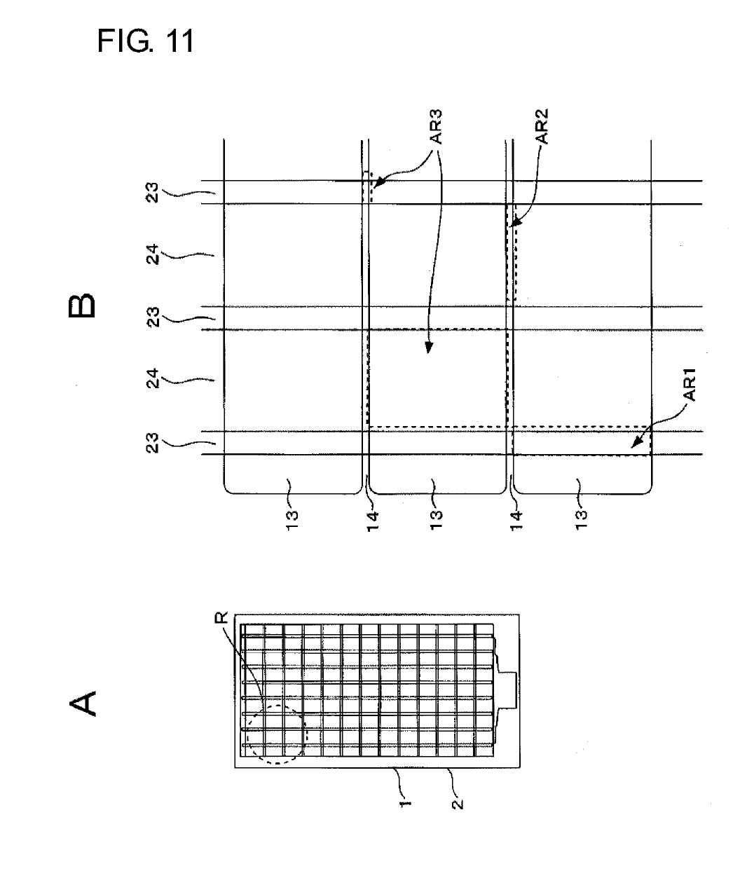

FIG. 11A is a plan view illustrating the first transparent conductive element 1 and the second transparent conductive element 2 in the state illustrated in FIG. 1. FIG. 11B is a plan view illustrating a region R shown in FIG. 11A in an enlarged manner. The first transparent conductive element 1 and the second transparent conductive element 2 are disposed in an overlapping manner so that the transparent electrode portions 13 and the transparent electrode portions 23 are perpendicular to each other. When the first transparent conductive element 1 and the second transparent conductive element 2 thus disposed in such an overlapping manner are viewed from an input surface side where a touch operation is made by a user, all of portions where they are overlapped with each other (input surface forming portions) can be classified into any of regions AR1, AR2, and AR3. The region AR1 is a region where the transparent electrode portion 13 and the transparent electrode portion 23 are overlapped with each other. The region AR2 is a region where the transparent insulating portion 14 and the transparent insulating portion 24 are overlapped with each other. The region AR3 is a region where the transparent electrode portion 13 and the transparent insulating portion 24 are overlapped with each other or the transparent insulating portion 14 and the transparent electrode portion 23 are overlapped with each other.

In a state where the first transparent conductive element 1 and the second transparent conductive element 2 are overlapped with each other, a difference between added values of the coverage by the transparent conductive layer 12 in the first transparent conductive element 1 and the coverage by the transparent conductive layer 22 in the second transparent conductive element 2 is preferably in the range of from 0% or higher and 60% or lower in all of the regions AR1, AR2, and AR3 as viewed from the input surface direction. This makes it possible to restrain the visual recognition of the regions AR1, AR2, and AR3, thereby further improving the visibility of the information input device 10.

Assume that the coverage by the transparent conductive layers 12 and 22 (conductive portions 13b and 23b) in the transparent electrode portions 13 and 23 is 80%, for example. Also, assume that the coverage by the transparent conductive layers 12 and 22 (island portions 14a and 24a) in the transparent insulating portions 14 and 24 is 50%. In this case, added values of the coverage by the transparent conductive layer 12 in the first transparent conductive element 1 and the coverage by the transparent conductive layer 22 in the second transparent conductive element 2 in the regions AR1, AR2, and AR3 are as follows.

Region AR1: 80%+80%=160%

Region AR2: 50%+50%=100%

Region AR3: 80%+50%=130%

In this example, the added value is the largest in the region AR1 and the smallest in the region AR2, and the difference therebetween is 60%. If the added value difference is smaller than or equal to 60%, the visual recognition of the regions AR1, AR2, and AR3 can be restrained. The reason for using such added values as indicators is to consider the non-visibility of the regions AR1, AR2, and AR3 strictly according to the visual perception of a user. In a macro perspective according to the visual perception of a user, when the first transparent conductive element 1 and the second transparent conductive element 2 are overlapped with each other, an added value of the coverage by the transparent conductive layer 12 in the first transparent conductive element 1 and the coverage by the transparent conductive layer 22 in the second transparent conductive element 2 is regarded as an average coverage in that area. In other words, if the added value difference is large, distinctions among the regions AR1, AR2, and AR3 become more likely to be recognized in a visual sense of a user.

By reducing the added value difference, the non-visibility of the regions AR1, AR2, and AR3 can be restrained more. Speaking of the above-described example, for example, by increasing the added value in the region AR2, the added value difference in each of the regions can be made smaller. For example, assume that the coverage by the transparent conductive layers 12 and 22 (island portions 14a and 24a) in the transparent insulating portions 14 and 24 is 65%. In this case, added values of the coverage by the transparent conductive layer 12 in the first transparent conductive element 1 and the coverage by the transparent conductive layer 22 in the second transparent conductive element 2 in the regions AR1, AR2, and AR3 are as follows.

Region AR1: 80%+80%=160%

Region AR2: 65%+65%=130%

Region AR3: 80%+65%=145%

In this example, the added value difference between the region AR1 and the region AR2 is 30%, thereby making it possible to restrain the non-visibility of the regions AR1, AR2, and AR3 more. Note however that increasing the coverage by the transparent conductive layers 12 and 22 (island portions 14a and 24a) in the transparent insulating portions 14 and 24 correspondingly leads to an increased amount of the conductive material used and therefore to an increase in the material cost in a case where the transparent conductive layers 12 and 22 are formed with a printing method, for example. Thus, the coverage by the transparent conductive layers 12 and 22 (island portions 14a and 24a) in the transparent insulating portions 14 and 24 may be set in consideration of the material cost and the resistance value of the transparent electrode portions 13 and 23 without the added value differences among the regions exceeding 60%.

### [Method for Producing Transparent Conductive Element]

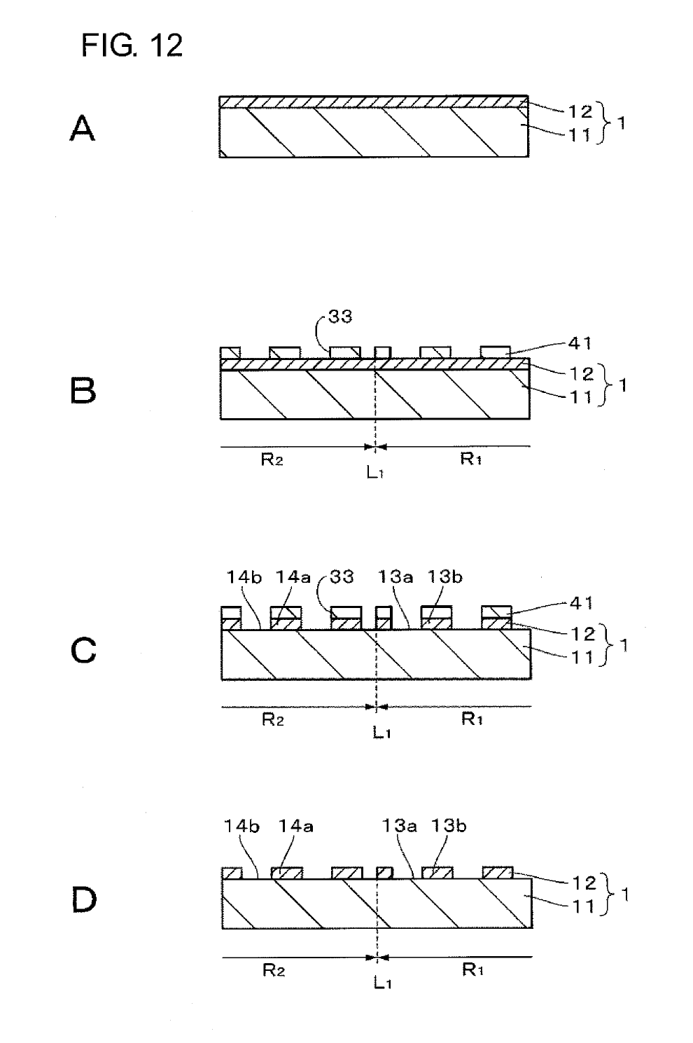

Next, with reference to FIGS. 12A to 12D, an example of a method for producing the thus configured first transparent conductive element 1 will be described. Since the second transparent conductive element 2 can be produced in almost the same manner as the first transparent conductive element 1, a description about a method for producing the second transparent conductive element 2 will be omitted.

### (Film Forming Step for Transparent Conductive Layer)

First, as illustrated in FIG. 12A, the transparent conductive layer 12 is formed on the surface of the substrate 11. When forming the transparent conductive layer 12, the substrate 11 may be heated. In addition to a CVD method (Chemical Vapor Deposition: a technique for depositing a thin film from a vapor phase by utilizing a chemical reaction) such as thermal CVD, plasma CVD, or photo-CVD, a PVD method (Physical Vapor Deposition: a technique for forming a thin film by condensing a physically-vaporized material onto a substrate in a vacuum) such as vacuum vapor deposition, plasma-aided vapor deposition, sputtering, or ion plating may be used as a method for forming the transparent conductive layer 12. Next, the transparent conductive layer 12 is subjected to an annealing treatment if necessary. This turns the transparent conductive layer 12 into, for example, a mixed state of amorphous and polycrystal or a polycrystalline state, thereby improving the conductivity of the transparent conductive layer 12.

### (Film Forming Step for Resist Layer)

Next, as illustrated in FIG. 12B, a resist layer 41 with openings 33 at portions corresponding to the above-described hole portions 13a and the gap portions 14b is formed on the surface of the transparent conductive layer 12 by means of photolithography or the like. As a material for the resist layer 41, any of an organic resist and an inorganic resist may be used, for example. As an organic resist, a novolac-based resist or a metal compound made of one or two or more transition metals can be used, for example.

### (Etching Step)

Next, as illustrated in FIG. 12C, etching treatment is performed for the transparent conductive layer 12 with the resist layer 41 having a plurality of opening 33 formed therein used as an etching mask. As a result, the hole portion 13a and the conductive portion 13b are formed in the transparent conductive layer 12 in the first region R₁, and the island portion 14a and the gap portion 14b are formed in the transparent conductive layer 12 in the second region R₂. Although any of dry etching and wet etching, for example, can be used as such etching, wet etching is preferably used in view of the simple equipment therefor.

### (Stripping Step of Resist Layer)

Next, as illustrated in FIG. 12D, the resist layer 41 formed on the transparent conductive layer 12 is stripped away by means of ashing or the like.

From the above, the intended first transparent conductive element 1 is obtained.

### [Effects]

According to the first embodiment, the first transparent conductive element 1 includes the transparent electrode portions 13 and the transparent insulating portions 14 alternately and adjacently provided in a planar manner on the surface of the substrate 11. The transparent electrode portion 13 is the transparent conductive layer 12 in which the plurality of hole portions 13a are provided, and the transparent insulating portion 14 is the transparent conductive layer 12 having the plurality of island portions. A regular shape pattern is provided in the boundary portion between the transparent electrode portion 13 and the transparent insulating portion 14. Therefore, a reflectance difference between the transparent electrode portion 13 and the transparent insulating portion 14 can be reduced and the visual recognition of the boundary portion can be restrained. Thus, the visual recognition of the transparent electrode portions 13 can be restrained.

Also, the second transparent conductive element 2 includes the transparent electrode portions 23 and the transparent insulating portions 24 alternately and adjacently provided in a planar manner on the surface of the substrate 21. The transparent electrode portion 23 and the transparent insulating portion 24 have the same configurations as those of the transparent electrode portion 13 and the transparent insulating portion 14 in the first transparent conductive element 1. Thus, the visual recognition of the transparent electrode portions 23 can be restrained.

Moreover, if the information input device 10 includes the first transparent conductive element 1 and the second transparent conductive element 2 overlapped with each other, the visual recognition of the transparent electrode portions 13 and the transparent electrode portions 23 can be restrained. Thus, the information input device 10 having superior visibility can be obtained. Furthermore, if this information input device 10 is provided on the display surface of the display device 4, the visual recognition of the information input device 10 can be restrained.

### (Modifications)

Modifications of the first embodiment will be described below.

### (Hard Coat Layer)

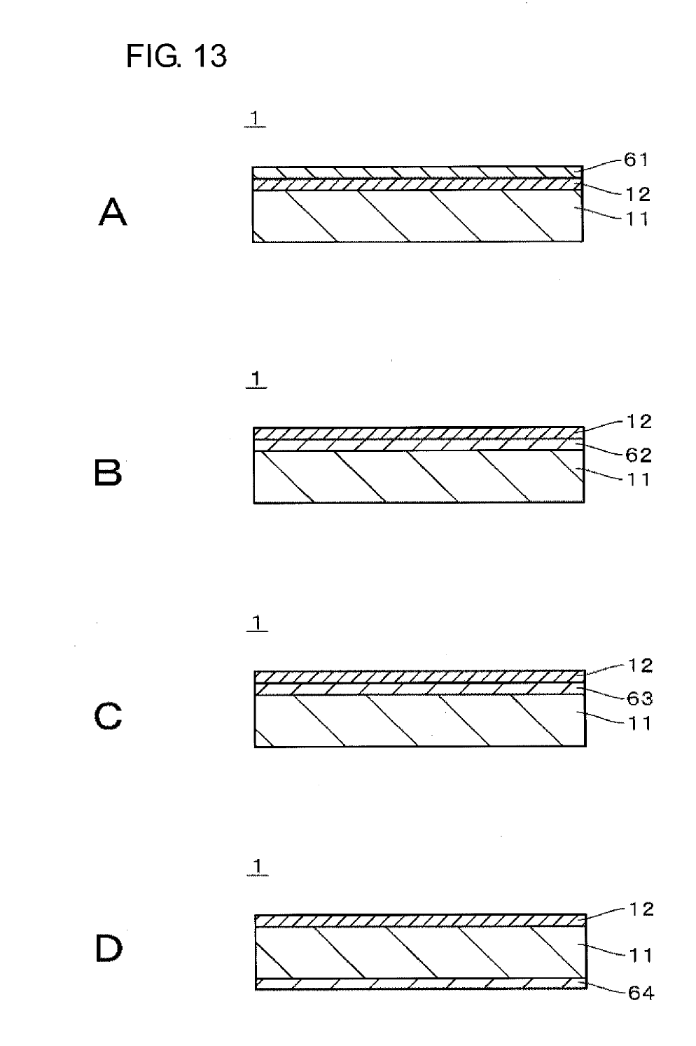

As illustrated in FIG. 13A, a hard coat layer 61 may be provided on at least one surface of both surfaces of the first transparent conductive element 1. As a result, if a plastic substrate is used as the substrate 11, the substrate 11 can be prevented from damaging during steps, chemical resistance can be given thereto, and the deposition of a low-molecular-weight substance such as an oligomer can be prevented. As a hard coat material, an ionizing radiation-curable resin to be cured by light or electron beams or a thermosetting resin to be cured by heat is preferably used. A photosensitive resin to be cured by ultraviolet rays is the most preferable to use. As such a photosensitive resin, acrylate-based resins such as urethane acrylate, epoxy acrylate, polyester acrylate, polyol acrylate, polyether acrylate, and melamine acrylate can be used. For example, a urethane acrylate resin is obtained by allowing polyester polyol to react with an isocyanate monomer or a prepolymer and allowing the thus obtained product to react with an acrylate or methacrylate-based monomer having a hydroxyl group. The thickness of the hard coat layer 61 is preferably in the range of 1 μm to 20 μm, although it is not particularly limited to this range.

The hard coat layer 61 is formed as follows. First, a hard coat coating material is coated on the surface of the substrate 11. A coating method therefor is not particularly limited and a known coating method can be used. Examples of a known coating method may include a micro gravure coating method, a wire-bar coating method, a direct gravure coating method, a die coating method, a dipping method, a spray coating method, a reverse roll coating method, a curtain coating method, a comma coating method, a knife coating method, and a spin coating method. The hard coat coating material, for example, contains a resin raw material such as a monomer and/or oligomer with two or more functional groups, a photopolymerization initiator, and a solvent. Next, if necessary, the hard coat coating material coated on the surface of the substrate 11 is allowed to be dried in order to volatilize the solvent. Next, the hard coat coating material on the surface of the substrate 11 is cured, for example, by the irradiation of ionizing radiation or heating. Note that, in the same manner as the above-described first transparent conductive element 1, the hard coat layer 61 may be provided on at least one surface of both surfaces of the second transparent conductive element 2.

### (Optical Adjustment Layer)

As illustrated in FIG. 13B, an optical adjustment layer 62 is preferably interposed between the substrate 11 and the transparent conductive layer 12 in the first transparent conductive element 1. This can contribute to the non-visibility of the shape pattern of the transparent electrode portion 13. The optical adjustment layer 62 is configured, for example, by a layered body made of two or more layers having different refractive indexes and the transparent conductive layer 12 is formed on the lower refractive index layer side. More specifically, a conventionally-known optical adjustment layer, for example, can be used as the optical adjustment layer 62. As such an optical adjustment layer, those described in Japanese Patent Application Laid-Open No. 2008-98169, Japanese Patent Application Laid-Open No. 2010-15861, Japanese Patent Application Laid-Open No. 2010-23282, or Japanese Patent Application Laid-Open No. 2010-27294, for example, can be used. Note that, in the same manner as the above-described first transparent conductive element 1, the optical adjustment layer 62 may be interposed between the substrate 21 and the transparent conductive layer 22 in the second transparent conductive element 2.

### (Adhesion Assisting Layer)

As illustrated in FIG. 13C, an adhesion assisting layer 63 is preferably provided as an underlayer of the transparent conductive layer 12 in the first transparent conductive element 1. This makes it possible to improve the adhesion of the transparent conductive layer 12 to the substrate 11. Examples of a material for the adhesion assisting layer 63 may include polyacrylic resins, polyamide-based resins, polyamide-imide-based resins, polyester-based resins, and hydrolyzed and dehydration-condensation products such as a chloride, peroxide, or alkoxide of a metal element.

Instead of using the adhesion assisting layer 63, the surface where the transparent conductive layer 12 is provided may be subjected to a discharge treatment irradiating glow discharge or corona discharge thereto. Alternatively, the surface where the transparent conductive layer 12 is provided may be subjected to a chemical treatment in which the layer is treated with an acid or alkali. Alternatively, after providing the transparent conductive layer 12, the adhesion thereof may be improved by calendering. Also in the second transparent conductive element 2, the adhesion assisting layer 63 may be provided in the same manner as the above-described first transparent conductive element 1. The above-described treatments for improving the adhesion may also be performed.

### (Shielding Layer)

As illustrated in FIG. 13D, it is preferred to provide a shielding layer 64 in the first transparent conductive element 1. For example, a film in which the shielding layer 64 is provided may be adhered to the first transparent conductive element 1 via a transparent adhesive layer. If the X electrode and the Y electrode are formed on the same surface side of a single substrate 11, the shielding layer 64 may be directly formed on the opposite side thereto. As a material for the shielding layer 64, the same material as that of the transparent conductive layer 12 may be used. Also, as a method for forming the shielding layer 64, the same method as that for the transparent conductive layer 12 may be used. Note that the shielding layer 64 is used in a state where it is formed over the entire surface of the substrate 11 without being subjected to patterning. Forming the shielding layer 64 in the first transparent conductive element 1 makes it possible to reduce noise resulting from electromagnetic waves emitted from the display device 4 or the like and thereby improve the accuracy of position detection in the information input device 10. Note that, in the same manner as the above-described first transparent conductive element 1, the shielding layer 64 may be provided in the second transparent conductive element 2.

### (Antireflection Layer)

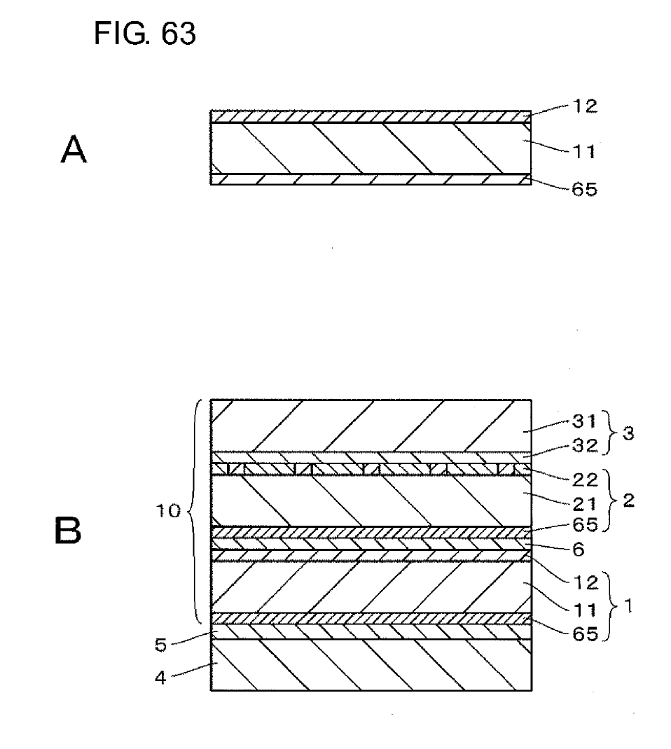

As illustrated in FIG. 63A, it is preferred to further provide an antireflection layer 65 in the first transparent conductive element 1. The antireflection layer 65 is provided, for example, on one principal surface of both principal surfaces of the first transparent conductive element 1 which is opposite to the side where the transparent conductive layer 12 is provided.

As the antireflection layer 65, a low refractive index layer, a moth-eye structure, or the like, may be used for example. If a low refractive index layer is employed as the antireflection layer 65, the hard coat layer 61 may be further provided between the substrate 11 and the antireflection layer 65. Note that, in the same manner as the above-described first transparent conductive element 1, the antireflection layer 65 may be further provided also in the second transparent conductive element 2.

FIG. 63B is a cross-sectional view illustrating an application example in which the first transparent conductive element 1 and the second transparent conductive element 2 each have the antireflection layer 65. As illustrated in FIG. 63B, the first transparent conductive element 1 and the second transparent conductive element 2 are provided on the display device 4 so that one principal surface of both principal surfaces thereof on the side where the antireflection layer 65 is provided faces the display surface of the display device 4. Employing such a configuration makes it possible to improve a transmittance of light from the display surface of the display device 4 and thereby improve the display performance of the display device 4.

### 2. Second Embodiment

### Configuration of Transparent Conductive Element

### (Transparent Electrode Portion, Transparent Insulating Portion)

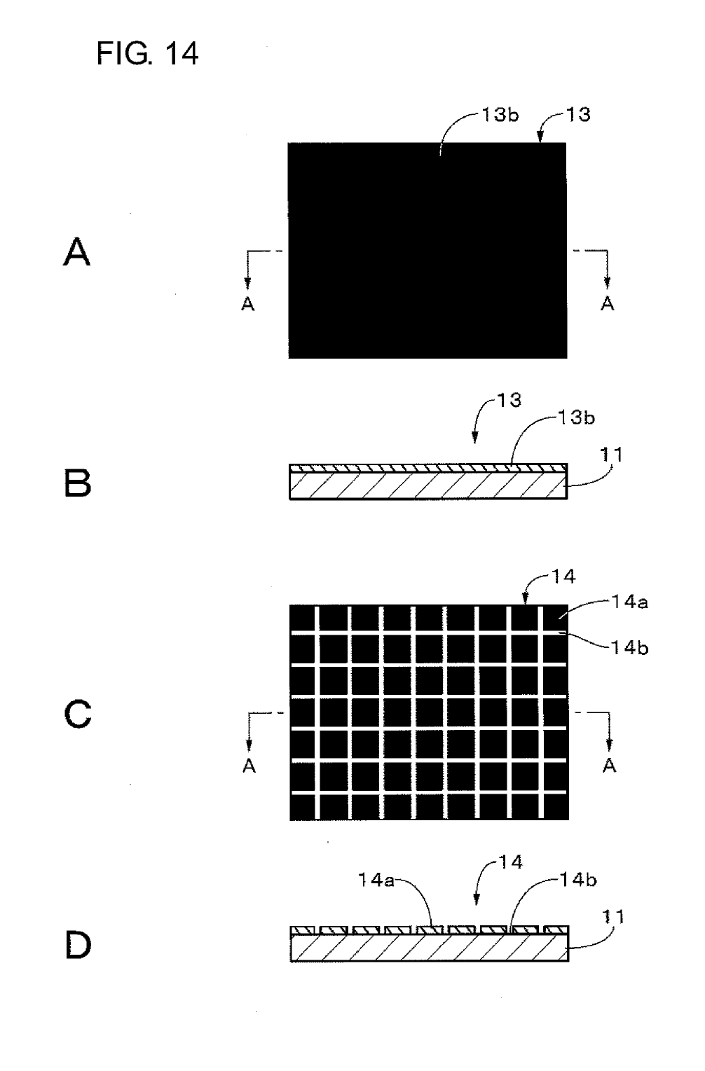

FIG. 14A is a plan view illustrating a configuration example of the transparent electrode portion 13 of the first transparent conductive element 1. FIG. 14B is a cross-sectional view taken along line A-A illustrated in FIG. 14A. FIG. 14C is a plan view illustrating a configuration example of the transparent insulating portion 14 of the first transparent conductive element 1. FIG. 14D is a cross-sectional view taken along line A-A illustrated in FIG. 14C. Of the transparent electrode portion 13 and the transparent insulating portion 14, the transparent electrode portion 13 is the transparent conductive layer 12 continuously provided and the transparent insulating portion 14 is the transparent conductive layer 12 having a regular pattern therein. The pattern in the transparent insulating portion 14 is a pattern of a plurality of island portions 14a. The pattern of the plurality of island portions 14a is a regular pattern.

As illustrated in FIGS. 14A and 14B, the transparent electrode portion 13 is the transparent conductive layer (continuous film) 12 continuously provided without exposing the surface of the substrate 11 by hole portions in the first region (electrode region) R₁. Note however that the boundary portion between the first region (electrode region) R₁ and the second region (insulating region) R₂ is excluded. The transparent conductive layer 12 which is a continuous film preferably has an approximately-uniform film thickness. The transparent insulating portion 14, on the other hand, is the transparent conductive layer 12 having the plurality of island portions 14a provided regularly so as to be spaced apart from one another as illustrated in FIGS. 14C and 14D. The gap portion 14b serving as an insulating portion is interposed between adjacent island portions 14a. Although FIG. 14C illustrates an example in which the island portion 14a has a quadrangular shape, the shape of the island portion 14a is not limited thereto.

### (Boundary Portion)

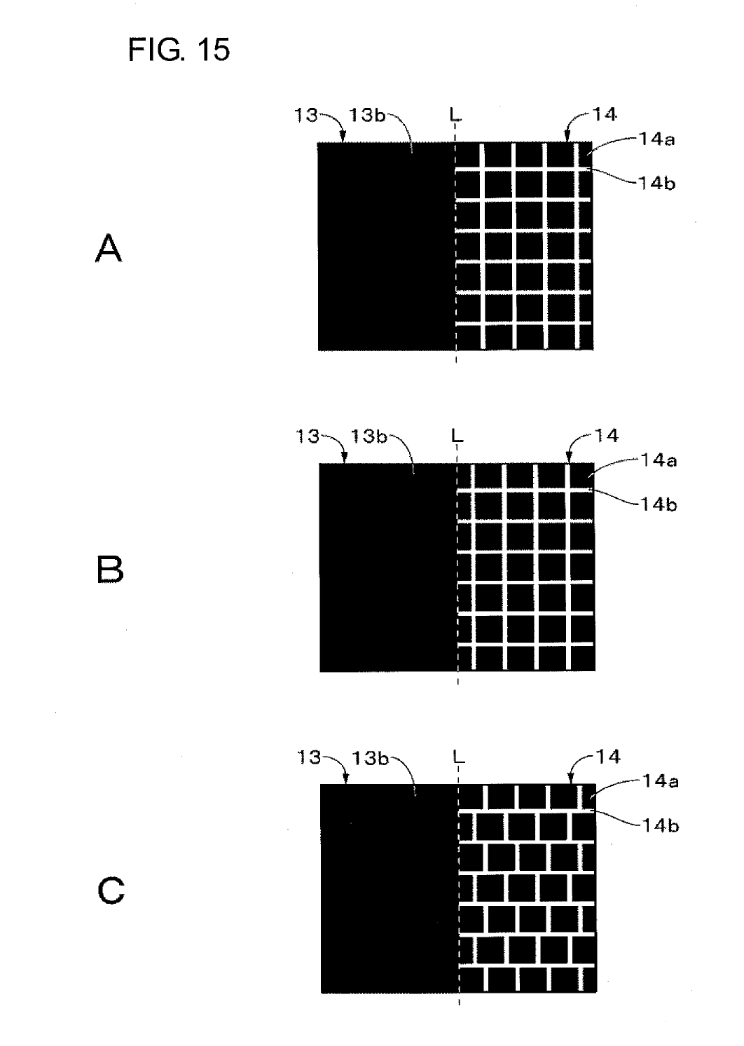

FIGS. 15A to 15C are each a plan view illustrating an exemplary shape pattern in the boundary portion. A regular shape pattern is provided in the boundary portion between the transparent electrode portion 13 and the transparent insulating portion 14. By providing a regular shape pattern in the boundary portion in this manner, the visual recognition of the boundary portion can be restrained.

The shape pattern in the boundary portion includes one or more shapes selected from the group consisting of the whole of the island portion 14a and part of the island portion 14a. Specifically, the shape pattern in the boundary portion, for example, includes: (1) the whole of the island portion 14a (FIG. 15A); (2) part of the island portion 14a (FIG. 15B); or (3) both of the whole and part of the island portion 14a (FIG. 15C).

It is preferable that the whole and part of the island portion 14a included in the boundary portion be provided with the same arrangement pattern as that of the island portions 14a in the transparent insulating portion 14. This eliminates a need to provide only the whole and part of the island portion 14a included in the boundary portion with a pattern different from that of the transparent insulating portion 14. Therefore, the configuration of the first transparent conductive element 1 can be simplified.

With reference to FIGS. 15A to 15C, specific examples of these shape patterns (1) to (3) will be sequentially described below.

### (1) Whole of Island Portion 14a

FIG. 15A illustrates an example in which the shape pattern in the boundary portion includes the whole of the island portion 14a. In this example, the island portion 14a included in the boundary portion is provided in contact with the boundary L on the transparent insulating portion 14 side.

### (2) Part of Island Portion 14a

FIG. 15B illustrates an example in which the shape pattern in the boundary portion includes part of the island portion 14a. In this example, the part of the island portion 14a included in the boundary portion, for example, has a shape such that the island portion 14a is partially cut by the boundary L and the cut edge is provided in contact with the boundary L on the transparent insulating portion 14 side.

### (3) Both of Whole and Part of Island Portion 14a

FIG. 15C illustrates an example in which the shape pattern in the boundary portion includes both of the whole and part of the island portion 14a. In this example, the whole of the island portion 14a included in the boundary portion is provided in contact with the boundary L on the transparent insulating portion 14 side. The part of the island portion 14a, for example, has a shape such that the island portion 14a is partially cut by the boundary L and the cut edge is provided in contact with the boundary L on the transparent insulating portion 14 side.

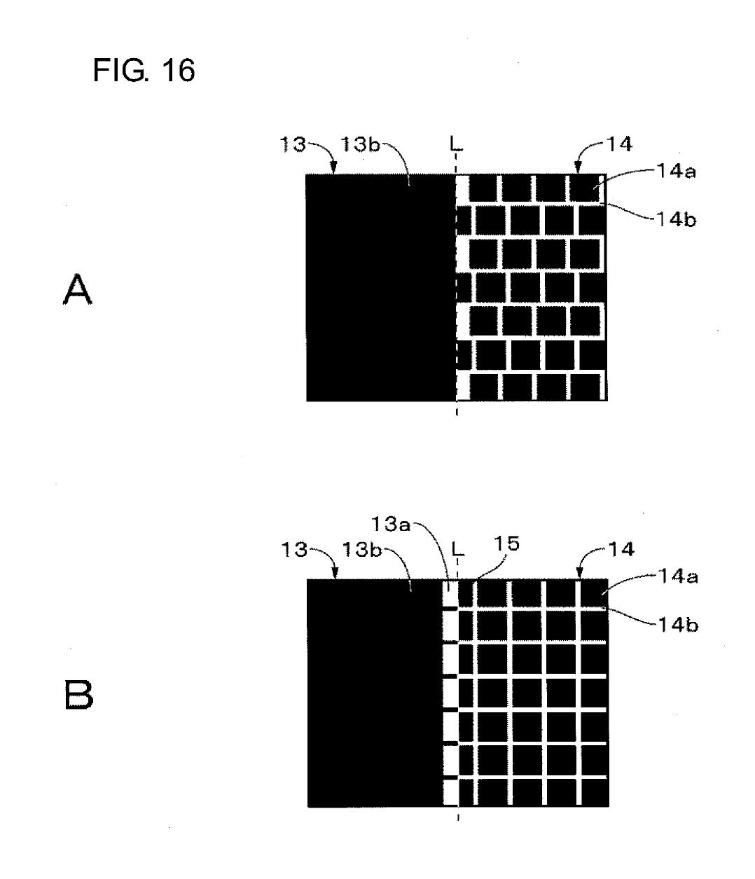

Although the specific examples of the above-described shape patterns (1) to (3) describe, as an example, the configuration in which the island portions 14a form columns and all of the island portions 14a positioned at one end of the columns are included in the shape pattern in the boundary portion, part of the island portions 14a positioned at one end of the columns may be included in the shape pattern in the boundary portion as illustrated in FIG. 16A.

Alternatively, the hole portions 13a and the island portions 14a may be provided in the boundary L so as to be in synchronization with each other in the extending direction of the boundary L as illustrated in FIG. 16B. More specifically, the plurality of inverting portions 15 may be provided on the boundary L with regularity so as to be spaced apart from one another. The inverting portion 15 includes part or the whole of the hole portion 13a and the island portion 14a and has a configuration in which the hole portion 13a is inverted into the island portion 14a with the boundary L used as a dividing line. Of the hole portion 13a and the island portion 14a included in the inverting portion 15, one of them may be provided partially and the other one thereof may be provided as the whole.

In the second embodiment, those excluding the above are the same as those in the first embodiment.

### [Effects]

According to the second embodiment, the same effects as those in the first embodiment can be obtained.

### 3. Third Embodiment

### Configuration of Transparent Conductive Element

(Transparent Electrode Portion, Transparent Insulating Portion)

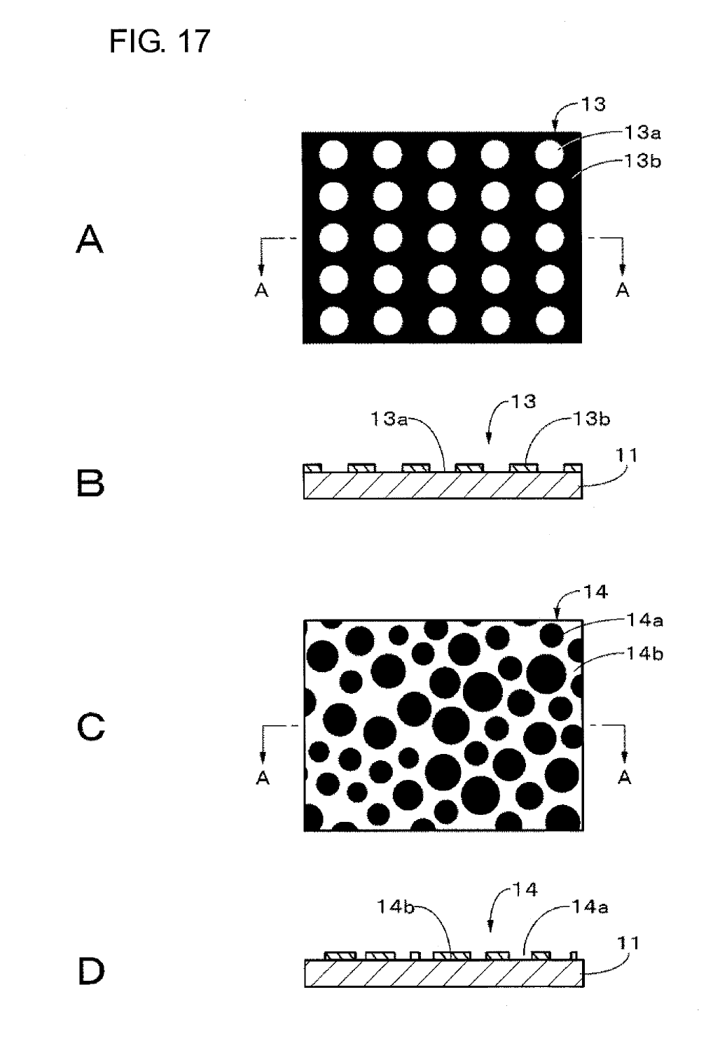

FIG. 17A is a plan view illustrating a configuration example of the transparent electrode portion 13 of the first transparent conductive element 1. FIG. 17B is a cross-sectional view taken along line A-A illustrated in FIG. 17A. FIG. 17C is a plan view illustrating a configuration example of the transparent insulating portion 14 of the first transparent conductive element 1. FIG. 17D is a cross-sectional view taken along line A-A illustrated in FIG. 17C. Of the transparent electrode portion 13 and the transparent insulating portion 14, the transparent electrode portion 13 is the transparent conductive layer 12 having a regular pattern therein and the transparent insulating portion 14 is the transparent conductive layer 12 having a random pattern therein. The pattern in the transparent electrode portion 13 is a pattern of a plurality of hole portions 13a, and the pattern in the transparent insulating portion 14 is a pattern of a plurality of island portions 14a. The pattern of the plurality of hole portions 13a is a regular pattern, whereas the pattern of the plurality of island portions 14a is a random pattern.

As illustrated in FIGS. 17A and 17B, the transparent electrode portion 13 is the transparent conductive layer 12 in which the plurality of hole portions 13a are provided regularly so as to be spaced apart from one another and the conductive portion 13b is interposed between adjacent hole portions 13a. As illustrated in FIGS. 17C and 17D, the transparent insulating portion 14, on the other hand, is the transparent conductive layer 12 having the plurality of island portions 14a provided randomly so as to be spaced apart from one another and the gap portion 14b serving as an insulating portion is interposed between adjacent island portions 14a.

### (Boundary Portion)

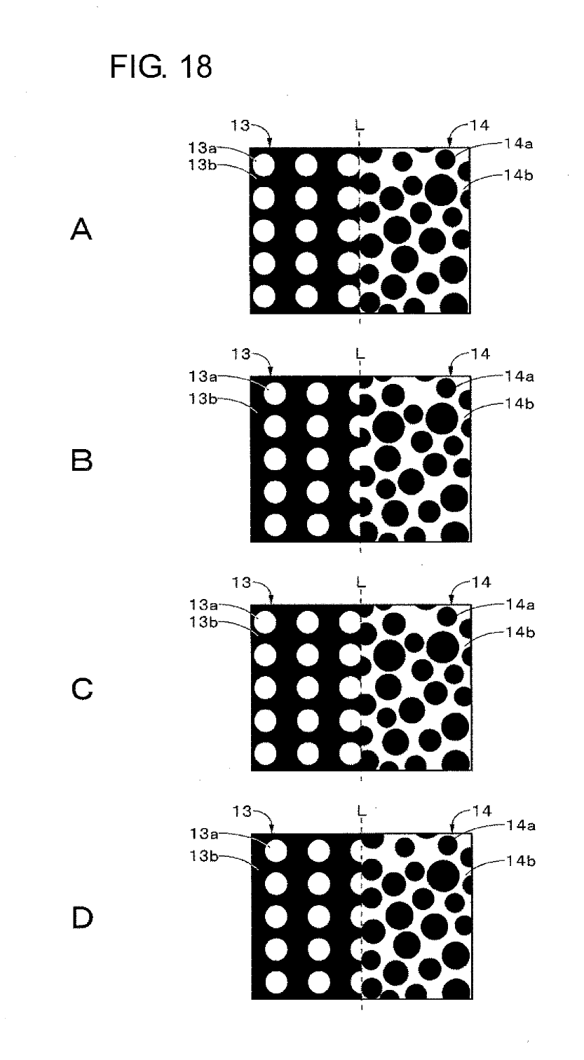

FIGS. 18A to 21B are each a plan view illustrating an exemplary shape pattern in the boundary portion. A regular or random shape pattern is provided in the boundary portion between the transparent electrode portion 13 and the transparent insulating portion 14. By providing a regular or random shape pattern in the boundary portion in this manner, the visual recognition of the boundary portion can be restrained.

The shape pattern in the boundary portion includes one or more shapes selected from the group consisting of the whole of the hole portion 13a, part of the hole portion 13a, the whole of the island portion 14a, and part of the island portion 14a. Preferably, the shape pattern in the boundary portion includes one or more shapes selected from the group consisting of the whole of the hole portion 13a, part of the hole portion 13a, and both of the whole and part of the island portion 14a. This is because such a configuration that the shape pattern in the boundary portion includes both of the whole and part of the island portion 14a can be easily produced in a case where the island portions 14a are provided randomly.

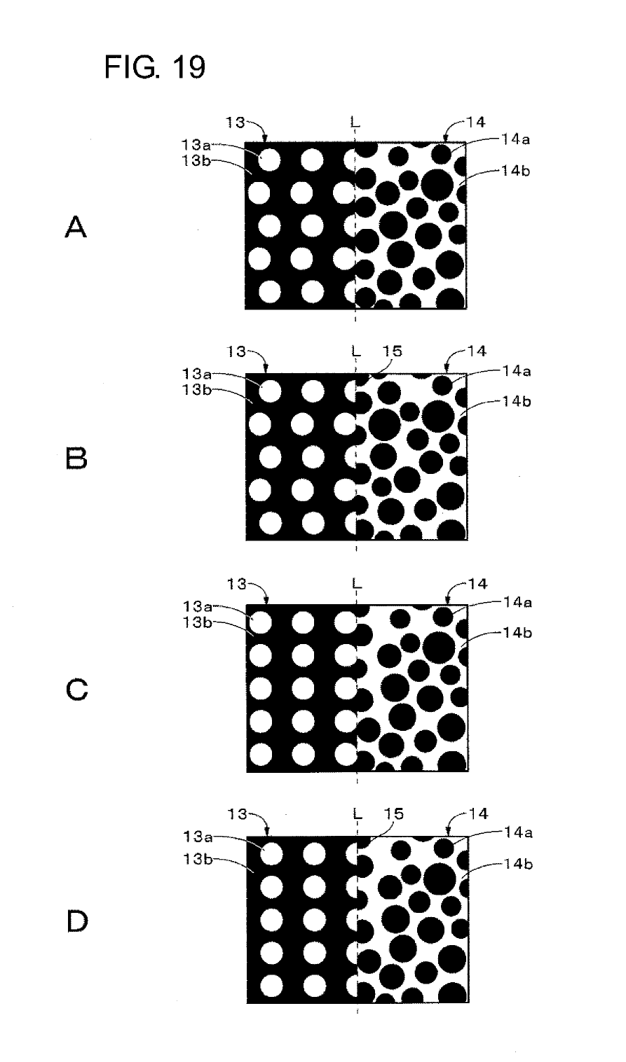

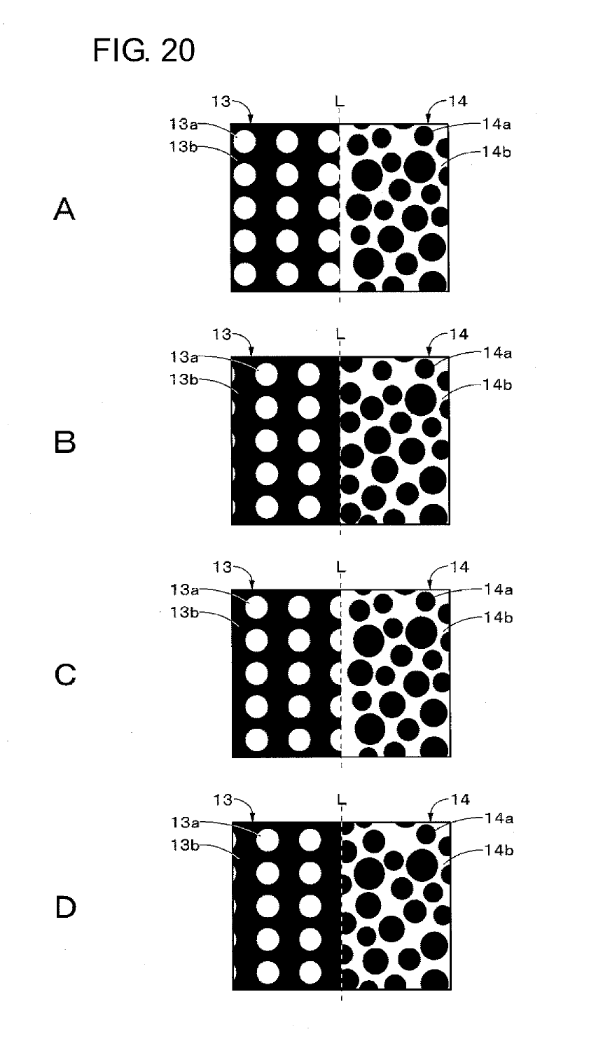

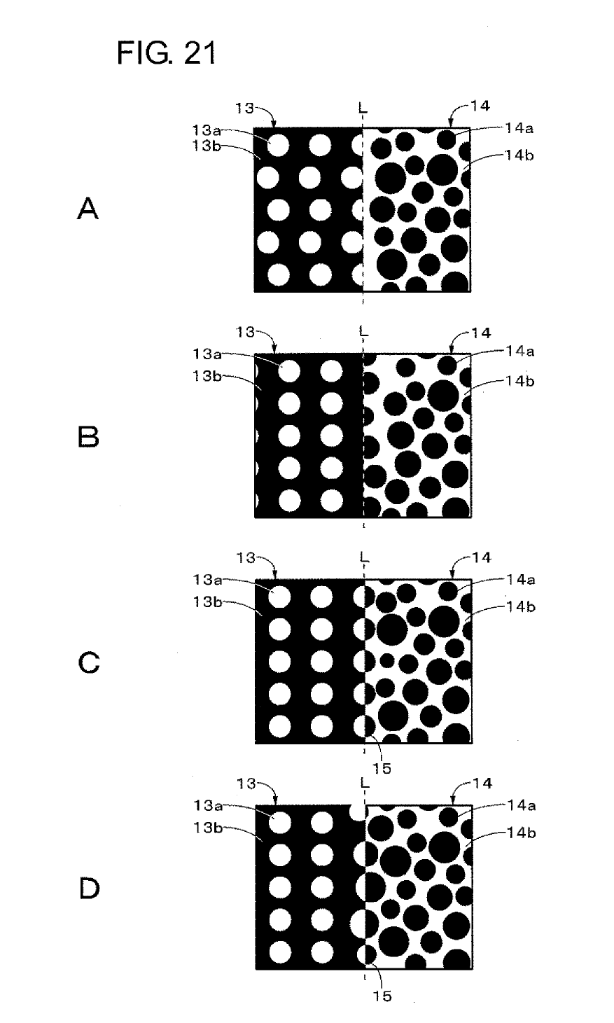

Specifically, the shape pattern in the boundary portion, for example, includes: (1) the whole of the hole portion 13a and the whole of the island portion 14a (FIG. 18A); (2) part of the hole portion 13a and part of the island portion 14a (FIG. 18B); (3) the whole of one of the hole portion 13a and the island portion 14a and part of the other one thereof (FIGS. 18C and 18D); (4) both of the whole and part of the hole portion 13a and one of the whole and part of the island portion 14a (FIGS. 19A and 19B); (5) one of the whole and part of the hole portion 13a and both of the whole and part of the island portion 14a (FIGS. 19C and 19D); (6) the whole of one of the hole portion 13a and the island portion 14a (FIGS. 20A and 20B); (7) part of one of the hole portion 13a and the island portion 14a (FIGS. 20C and 20D); (8) both of the whole and part of the hole portion 13a (FIG. 21A); or (9) both of the whole and part of the island portion 14a (FIG. 21B).

Preferably, the shape pattern in the boundary portion includes: (5) one of the whole and part of the hole portion 13a and both of the whole and part of the island portion 14a (FIGS. 19C and 19D); (6) the whole of the hole portion 13a (FIG. 20A); (7) part of the hole portion 13a (FIG. 20C); (8) both of the whole and part of the hole portion 13a (FIG. 21A); or (9) both of the whole and part of the island portion 14a (FIG. 21B).

If the shape pattern in the boundary portion does not include at least one of the whole and part of the island portion 14a, i.e., if it only includes at least one of the whole and part of the hole portion 13a, the shape pattern in the boundary portion forms a regular shape pattern. On the other hand, if the shape pattern in the boundary portion includes at least one of the whole and part of the island portion 14a, the shape pattern in the boundary portion forms a random shape pattern.

Although the specific examples of the above-described shape patterns (1) to (9) describe, as an example, the configuration in which the hole portions 13a and the island portions 14a are provided in the boundary L so as to be out of synchronization with each other in the extending direction of the boundary L, the shape pattern is not limited to this example. For example, as illustrated in FIGS. 21C and 21D, the hole portions 13a and the island portions 14a may be provided in the boundary L so as to be in synchronization with each other in the extending direction of the boundary L. More specifically, the plurality of inverting portions 15 may be provided on the boundary L with regularity or randomly so as to be spaced apart from one another. The inverting portions 15 are preferably disposed with a regular pattern of the hole portions 13a in the transparent electrode portion 13 or a random pattern of the island portions 14a in the transparent insulating portion 14. Alternatively, the above-described regular pattern and random pattern may be mixed in the boundary L. FIG. 21C illustrates an example in which the inverting portions 15 are provided in the boundary L with a regular pattern of the hole portions 13a in the transparent electrode portion 13. On the other hand, FIG. 21D illustrates an example in which the inverting portions 15 are provided in the boundary L with a random pattern of the island portions 14a in the transparent insulating portion 14.

### [Method for Generating Random Pattern]

A method for generating a random pattern to form the island portions 14a will be described below. Although a case where a circular random pattern is generated is herein described as an example, the shape of the random pattern is not limited thereto.

### (Fundamental Algorithm for Generating Random Pattern)

The radii of circles are randomly varied within a set range and the central coordinates of the circles are calculated and arranged so that adjacent circles are always in contact with each other to thereby generate a pattern satisfying both of arrangement randomness and high-density filling. With the following algorithms, a high-density and uniformly randomly-arranged pattern is obtained with less computational effort.

(1) Circles with their “radii being random within a certain range” are arranged in contact with one another on the X-axis.
(2) “Circles with random radii” are determined and accumulated in order from the bottom so as to be each in contact with existing two circles and not to be overlapped with other circles.

Parameters used when generating a random pattern are listed below.

Xₘₐₓ: the X-coordinate maximum value in a region where a circle is generated
Yₘₐₓ: the Y-coordinate maximum value in a region where a circle is generated
Rₘᵢₙ: the minimum radius of a circle to be generated
Rₘₐₓ: the maximum radius of a circle to be generated
R_{fill}: the minimum radius when a circle is supplementarily set in order to increase a filling rate
Rnd: a random value obtained in a range of 0.0 to 1.0
Pₙ: a circle defined by the X-coordinate value xₙ, the Y-coordinate value Yₙ, and the radius rₙ
(1) Circles with their “radii being random within a certain range” are arranged in contact with one another on the X-axis.

Parameters used are listed below.

Xₘₐₓ: the X-coordinate maximum value in a region where a circle is generated
Y_{w}: setting of the possible Y-coordinate maximum value when a circle is arranged on the X-axis.
Rₘᵢₙ: the minimum radius of a circle to be generated
Rₘₐₓ: the maximum radius of a circle to be generated
Rnd: a random value obtained in a range of 0.0 to 1.0
Pₙ: a circle defined by the X-coordinate value xₙ, the Y-coordinate value yₙ, and the radius rₙ.

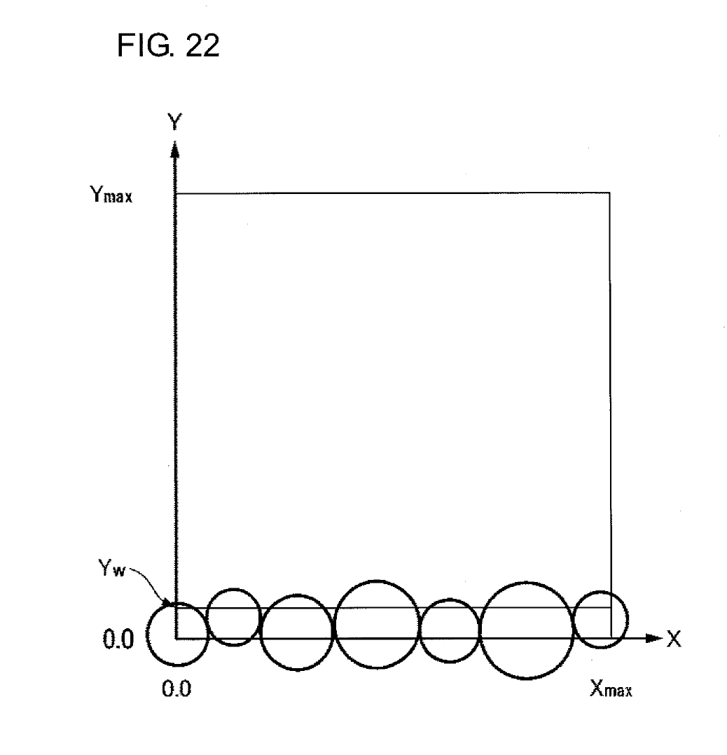

As illustrated in FIG. 22, a circle whose Y-coordinate value is randomly determined in a range of 0.0 on the X-axis to approximately the value of Rₘᵢₙ and whose radius is randomly determined in a range of Rₘᵢₙ to Rₘₐₓ is arranged so as to be in contact with an existing circle. By repeating such a process, a line of circles is randomly arranged on the X-axis.

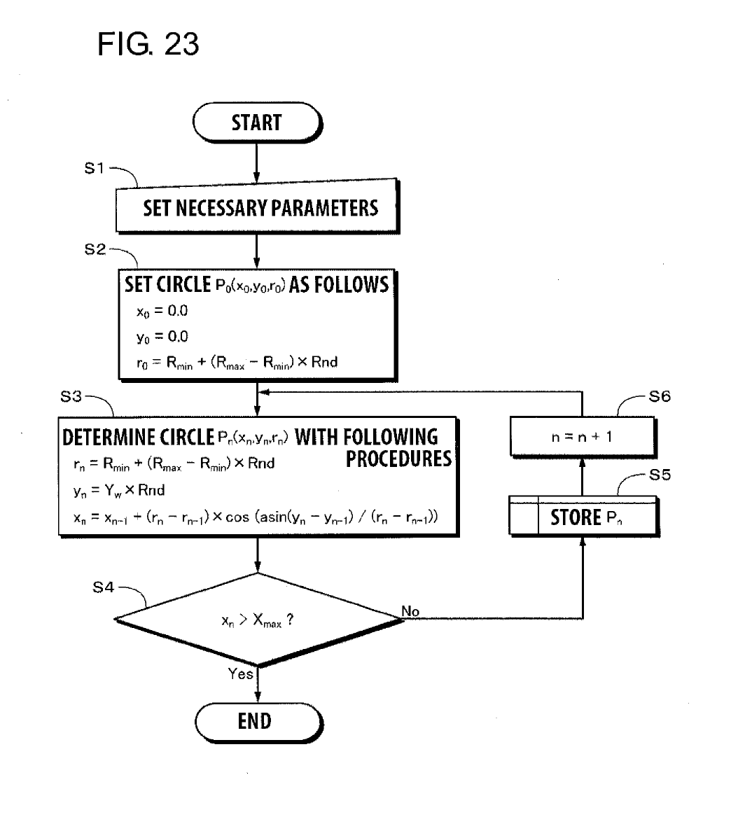

An algorithm will be described below with reference to a flow chart illustrated in FIG. 23.

First, necessary parameters are set in Step S1. Next, a circle P₀ (x₀, y₀, r₀) is set as follows in Step S2.

x₀=0.0

y₀=0.0

r₀=Rₘᵢₙ+(Rₘₐₓ−Rₘᵢₙ)×Rnd

Next, a circle Pₙ (xₙ, yₙ, rₙ) is determined with the following expressions in Step S3.

rₙ=Rₘᵢₙ+(Rₘₐₓ−Rₘᵢₙ)×Rnd

yₙ=Y_{w}×Rnd

xₙ=xₙ₋₁+(rₙ−rₙ₋₁)×cos(a sin(yₙ−yₙ₋₁)/(rₙ−rₙ₋₁))

Next, whether or not xₙ>Xₘₐₓ is determined in Step S4. If it is determined to be xₙ>Xₘₐₓ in Step S4, the process is ended. If it is determined not to be xₙ>Xₘₐₓ in Step S4, the process proceeds to Step S5. The circle Pₙ (xₙ, yₙ, rₙ) is stored in Step S5. Next, the value of n is incremented in Step S6 and the process proceeds to Step S3.

(2) “Circles with random radii” are determined and accumulated in order from the bottom so as to be each in contact with existing two circles and not to be overlapped with other circles.

Parameters used are listed below.

Xₘₐₓ: the X-coordinate maximum value in a region where a circle is generated
Yₘₐₓ: the Y-coordinate maximum value in a region where a circle is generated
Rₘᵢₙ: the minimum radius of a circle to be generated
Rₘₐₓ: the maximum radius of a circle to be generated
R_{fill}: the minimum radius when a circle is supplementarily set in order to increase a filling rate
Rnd: a random value obtained in a range of 0.0 to 1.0
Pₙ: a circle defined by the X-coordinate value xₙ, the Y-coordinate value yₙ, and the radius rₙ

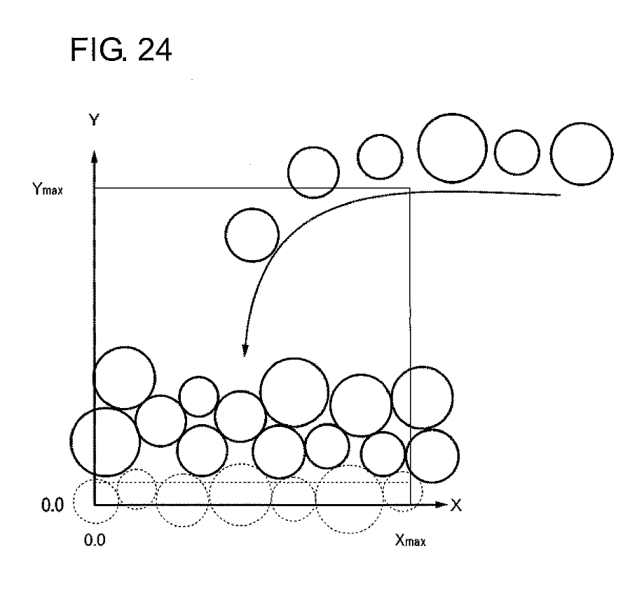

As illustrated in FIG. 24, based on the circles arranged in line on the X-axis which are determined in (1), circles with random radii are determined in a range of Rₘᵢₙ to Rₘₐₓ and in order from a circle with a smaller Y-coordinate, they are arranged and accumulated thereon so as to be in contact with other circles. Also, R_{fill} which is smaller than Rₘᵢₙ is set and only when a gap which cannot be filled by the determined circles is generated, the gap is filled to improve the filling rate. If a circle smaller than Rₘᵢₙ is not used, setting will be R_{fill}=Rₘᵢₙ.

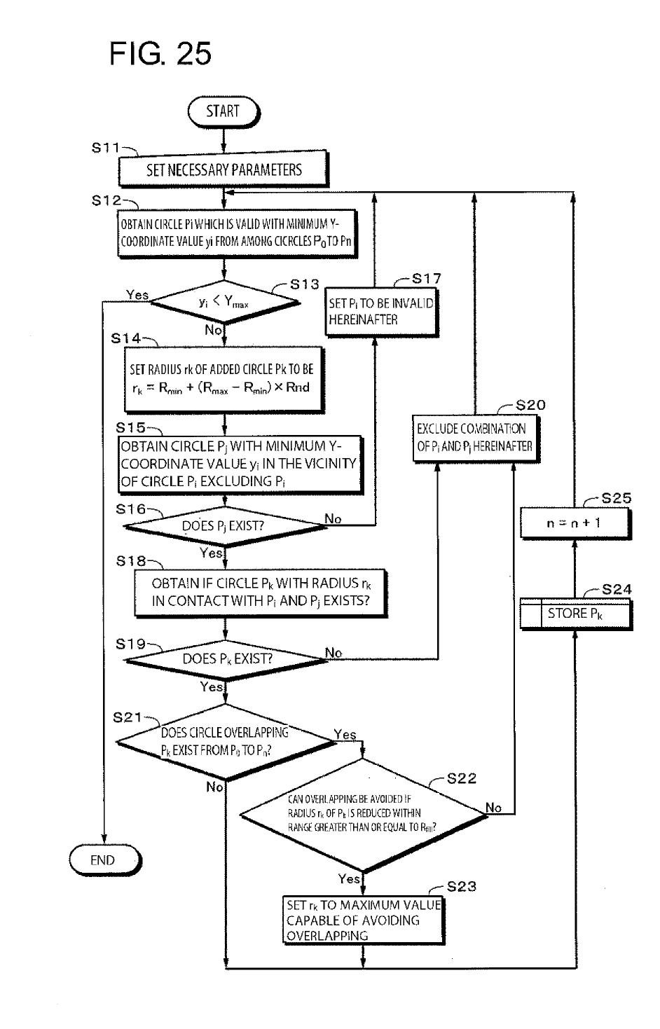

An algorithm will be described below with a flow chart illustrated in FIG. 25.

First, necessary parameters are set in Step S11. Next, a circle Pᵢ with the minimum Y-coordinate value yᵢ is determined from among the circles P₀ to Pₙ in Step S12. Next, whether yᵢ<Yₘₐₓ is satisfied or not is determined in Step S13. If it is determined that yᵢ<Yₘₐₓ is satisfied in Step S13, the process is ended. If it is determined that yᵢ<Yₘₐₓ is not satisfied in Step S13, a radius rₖ of a circle Pₖ to be added is set to be rₖ=Rₘᵢₙ(Rₘₐₓ−Rₘᵢₙ)×Rnd in Step S14. Next, a circle Pⱼ having the minimum Y-coordinate value yᵢ in the vicinity of the circle Pᵢ excluding the circle Pᵢ is determined in Step S15.

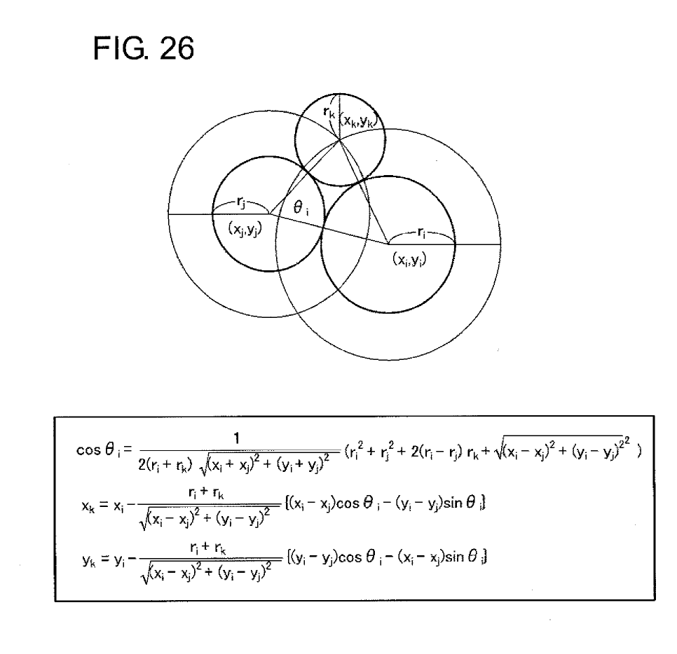

Next, whether or not the minimum circle Pⱼ exists is determined in Step S16. If it is determined that no minimum circle Pⱼ exists in Step S16, Pᵢ is set to be invalid hereinafter in Step S17. If it is determined that the minimum circle Pⱼ exists in Step S16, whether the circle Pₖ with the radius rₖ in contact with the circle Pᵢ and the circle Pⱼ exists or not is determined in Step S18. FIG. 26 shows how to obtain coordinates when a circle with an arbitrary radius is arranged so as to be in contact with the two circles in contact with each other in Step S18.

Next, whether the circle Pₖ with the radius rₖ in contact with the circle Pᵢ and the circle Pⱼ exists or not is determined in Step S19. If it is determined that no circle Pₖ exists in Step S19, the combination of the circle Pᵢ and the circle Pⱼ is excluded hereinafter in Step S20. If it is determined that the circle Pₖ exists in Step S19, whether a circle overlapping the circle Pₖ exists among the circles from P₀ to Pₙ or not is determined in Step S21. If it is determined that no overlapping circle exists in Step S21, the circle Pₖ (xₖ, yₖ, rₖ) is stored in Step S24. Next, the value of n is incremented in Step S25 and the process transitions to Step S12.

If it is determined that the overlapping circle exists in Step S21, whether or not the overlapping can be avoided when the radius rₖ of the circle Pₖ is reduced within a range greater than or equal to R_{fill} is determined in Step S22. If it is determined that the overlapping cannot be avoided in Step S22, the combination of the circle Pᵢ and the circle Pⱼ is excluded hereinafter in Step S20. If it is determined that the overlapping can be avoided in Step S22, the radius rₖ is set to the maximum one of values capable of avoiding the overlapping. Next, the circle Pₖ (xₖ, yₖ, rₖ) is stored in Step S24. Next, the value of n is incremented in Step S25 and the process proceeds to Step S12.

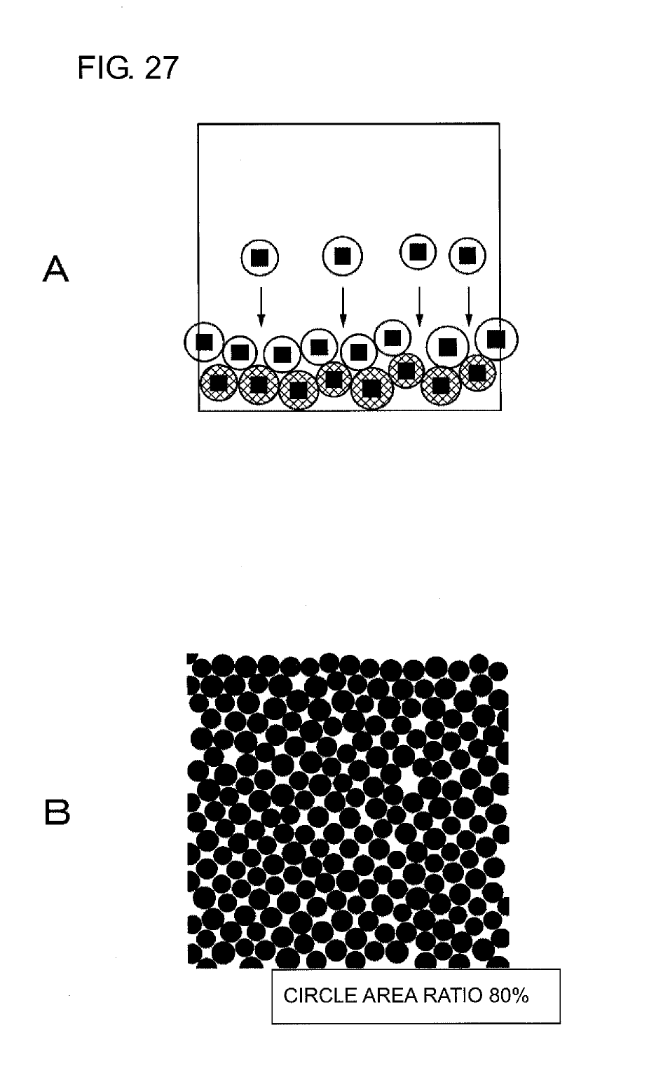

FIG. 27A is a schematic view illustrating an image of the method for generating a random pattern. FIG. 27B is a diagram illustrating an example of random pattern generation with the area ratio of circles set at 80%. As illustrated in FIG. 27A, by randomly varying the radii of circles within a set range and accumulating them, a high-density pattern with no regularity can be generated. Since there is no regularity in the pattern, the generation of moire in the transparent insulating portion 14 of the information input device 10 or the like can be suppressed.

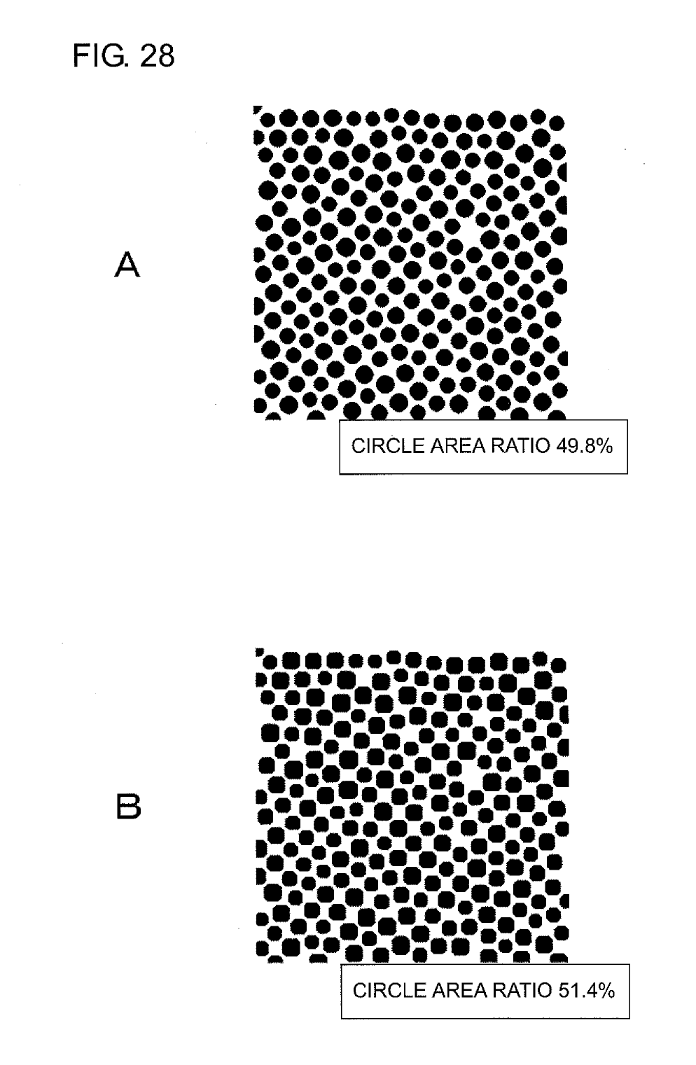

FIG. 28A is a diagram illustrating an example in which circle radii are made smaller than those of the circles in the generated pattern. Drawing, within a generated circle, a circle smaller than that makes it possible to form a pattern with circles spaced apart from one another without being in contact with one another. With the use of such a spaced-apart pattern, the transparent insulating portions 14 and 24 can be formed.

FIG. 28B is a diagram illustrating an example in which the circles in the generated pattern are changed to have a different shape. Drawing, within a generated pattern circle, a figure of a desired shape makes it possible to change the pattern tendency or adjust the area occupancy thereof. Shape examples of a figure drawn within a circle may include a circle, an ellipse, a polygon, a polygon with corners being rounded off, and an indefinite shape. FIG. 28B illustrates an example of a polygon (square) with corners being rounded off.

In the third embodiment, those excluding the above are the same as those in the first embodiment.

### [Effects]

According to the third embodiment, the following effect can be further obtained in addition to the effects in the first embodiment. Specifically, since the transparent insulating portion 14 is configured by the plurality of island portions 14a randomly provided so as to be spaced apart from one another, the generation of moire can be suppressed in the transparent insulating portion 14.

### 4. Fourth Embodiment

### Configuration of Transparent Conductive Element

### (Transparent Electrode Portion, Transparent Insulating Portion)

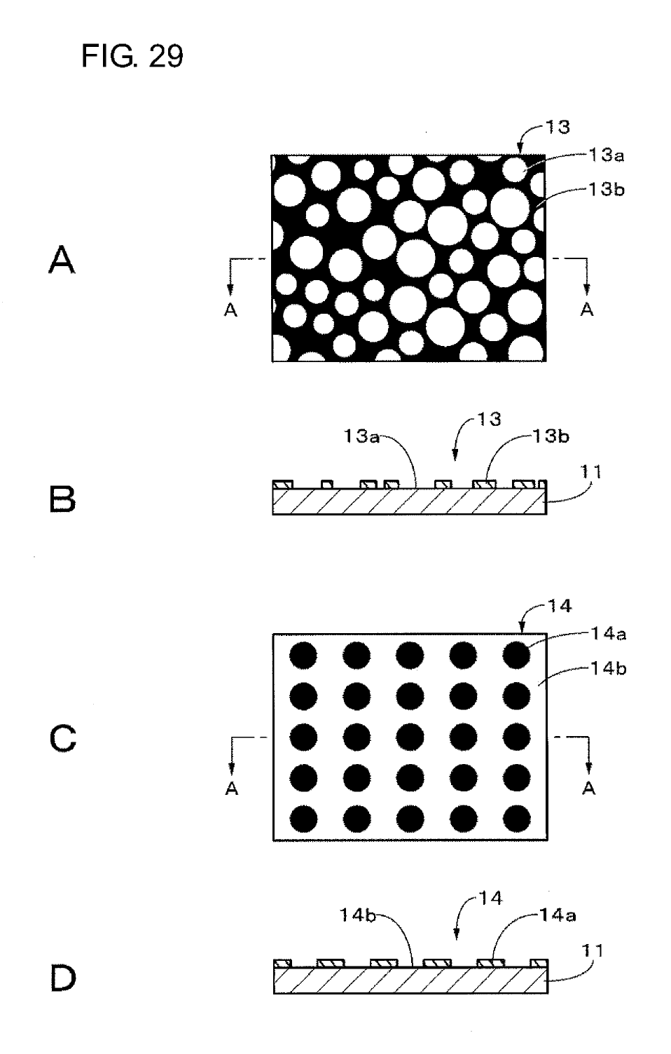

FIG. 29A is a plan view illustrating a configuration example of the transparent electrode portion 13 of the first transparent conductive element 1. FIG. 29B is a cross-sectional view taken along line A-A illustrated in FIG. 29A. FIG. 29C is a plan view illustrating a configuration example of the transparent insulating portion 14 of the first transparent conductive element 1. FIG. 29D is a cross-sectional view taken along line A-A illustrated in FIG. 29C. Of the transparent electrode portion 13 and the transparent insulating portion 14, the transparent electrode portion 13 is the transparent conductive layer 12 having a random pattern therein and the transparent insulating portion 14 is the transparent conductive layer 12 having a regular pattern therein. The pattern in the transparent conductive portion 13 is a pattern of a plurality of hole portions 13a, and the pattern in the transparent insulating portion 14 is a pattern of a plurality of island portions 14a. The pattern of the plurality of hole portions 13a is a random pattern, whereas the pattern of the plurality of island portions 14a is a regular pattern.

As illustrated in FIGS. 29A and 29B, the transparent electrode portion 13 is the transparent conductive layer 12 in which the plurality of hole portions 13a are randomly provided so as to be spaced apart from one another and the conductive portion 13b is interposed between adjacent hole portions 13a. As illustrated in FIGS. 29C and 29D, the transparent insulating portion 14, on the other hand, is the transparent conductive layer 12 having the plurality of island portions 14a provided regularly so as to be spaced apart from one another and the gap portion 14b serving as an insulating portion is interposed between adjacent island portions 14a.

### (Boundary Portion)

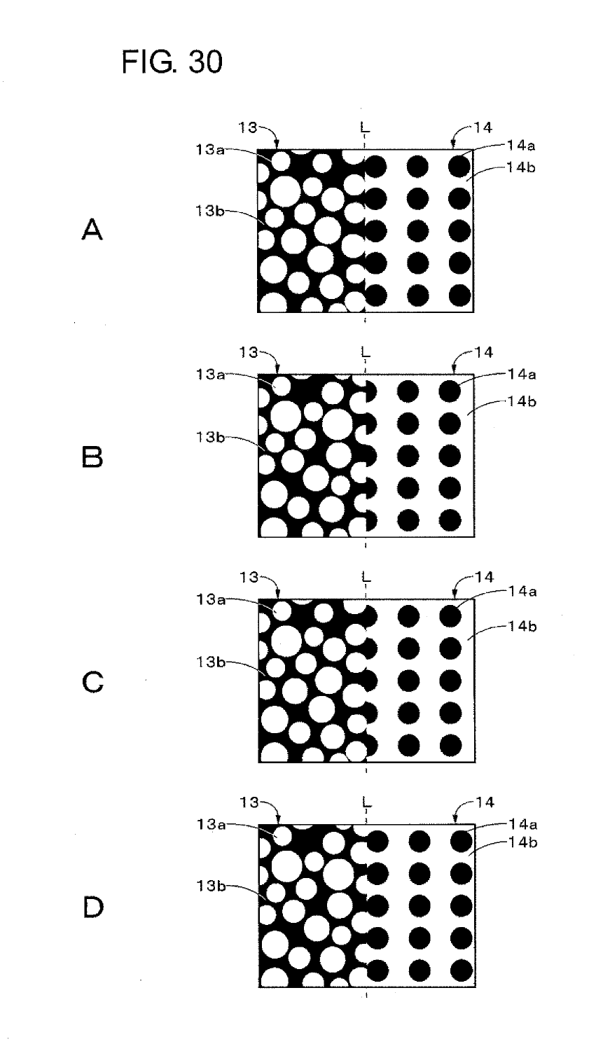

FIGS. 30A to 33B are each a plan view illustrating an exemplary shape pattern in the boundary portion. A regular or random shape pattern is provided in the boundary portion between the transparent electrode portion 13 and the transparent insulating portion 14. By providing a regular or random shape pattern in the boundary portion in this manner, the visual recognition of the boundary portion can be restrained.

The shape pattern in the boundary portion includes one or more shapes selected from the group consisting of the whole of the hole portion 13a, part of the hole portion 13a, the whole of the island portion 14a, and part of the island portion 14a. Preferably, the shape pattern in the boundary portion includes one or more shapes selected from the group consisting of both of the whole and part of the hole portion 13a, the whole of the island portion 14a, and part of the island portion. This is because such a configuration that the shape pattern in the boundary portion includes both of the whole and part of the hole portion 13a can be easily produced in a case where the hole portions 13a are provided randomly.

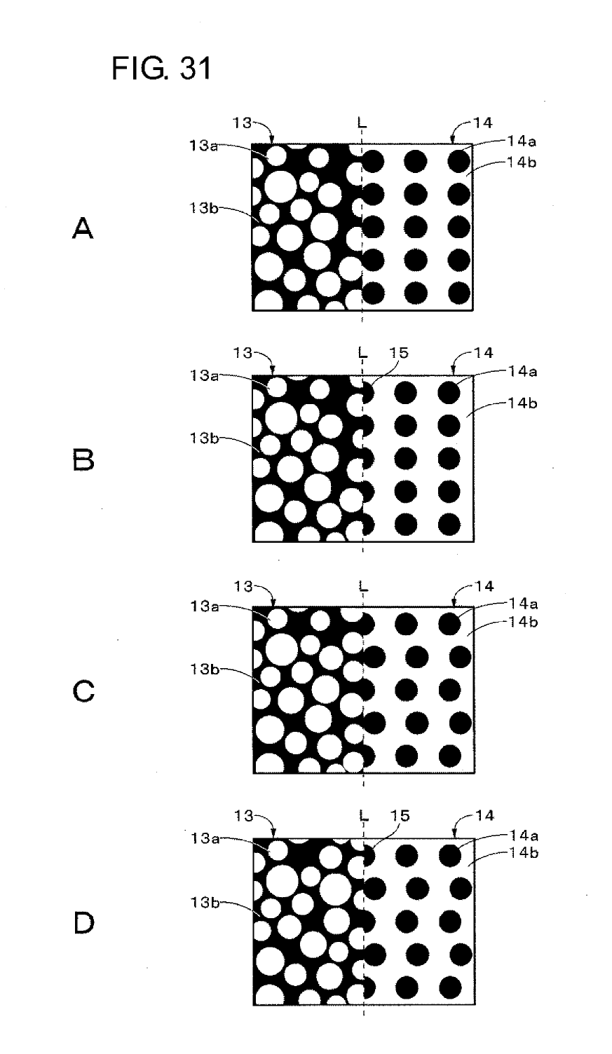

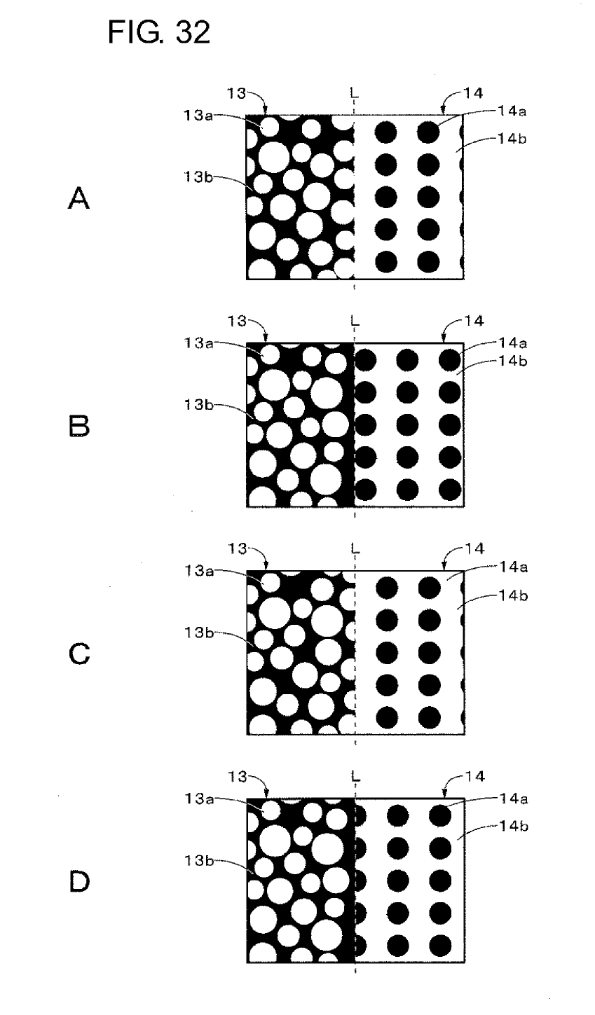

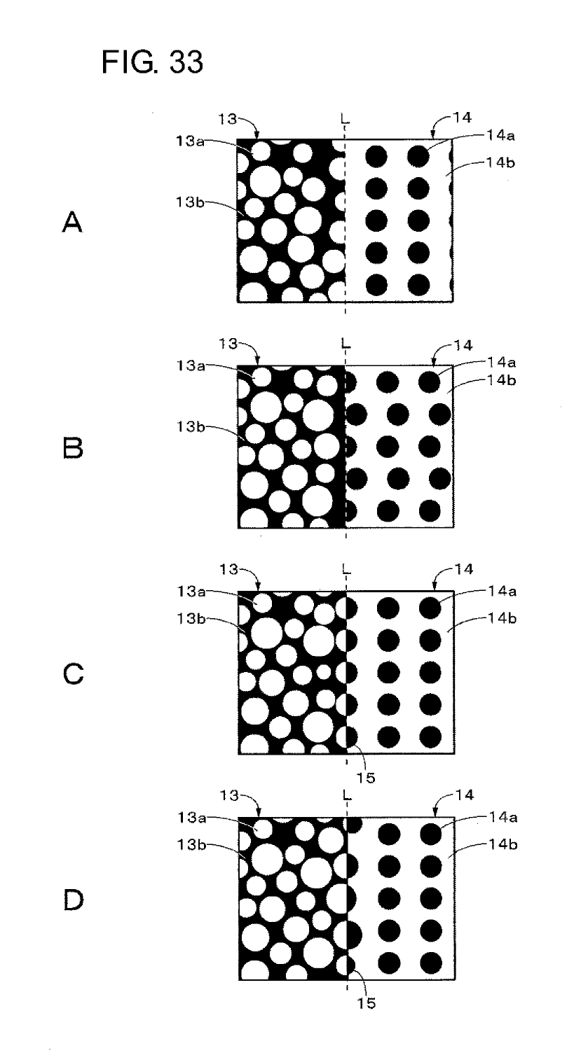

Specifically, the shape pattern in the boundary portion, for example, includes: (1) the whole of the hole portion 13a and the whole of the island portion 14a (FIG. 30A); (2) part of the hole portion 13a and part of the island portion 14a (FIG. 30B); (3) the whole of one of the hole portion 13a and the island portion 14a and part of the other one thereof (FIGS. 30C and 30D); (4) both of the whole and part of the hole portion 13a and one of the whole and part of the island portion 14a (FIGS. 31A and 31B); (5) one of the whole and part of the hole portion 13a and both of the whole and part of the island portion 14a (FIGS. 31C and 31D); (6) the whole of one of the hole portion 13a and the island portion 14a (FIGS. 32A and 32B); (7) part of one of the hole portion 13a and the island portion 14a (FIGS. 32C and 32D); (8) both of the whole and part of the hole portion 13a (FIG. 33A); or (9) both of the whole and part of the island portion 14a (FIG. 33B).

Preferably, the shape pattern in the boundary portion includes: (4) both of the whole and part of the hole portion 13a and one of the whole and part of the island portion 14a (FIGS. 31A and 31B); (6) the whole of the island portion 14a (FIG. 32B); (7) part of the island portion 14a (FIG. 32D); (8) both of the whole and part of the hole portion 13a (FIG. 33A); or (9) both of the whole and part of the island portion 14a (FIG. 33B).

If the shape pattern in the boundary portion does not include at least one of the whole and part of the hole portion 13a, i.e., if it only includes the whole and part of the island portion 14a, the shape pattern in the boundary portion forms a regular shape pattern. On the other hand, if the shape pattern in the boundary portion includes at least one of the whole and part of the hole portion 13a, the shape pattern in the boundary portion forms a random shape pattern.

Although the specific examples of the above-described shape patterns (1) to (9) describe, as an example, the configuration in which the hole portions 13a and the island portions 14a are provided in the boundary L so as to be out of synchronization with each other in the extending direction of the boundary L, the shape pattern is not limited to this example. For example, as illustrated in FIGS. 33C and 33D, the hole portions 13a and the island portions 14a may be provided in the boundary L so as to be in synchronization with each other in the extending direction of the boundary L. More specifically, the plurality of inverting portions 15 may be provided on the boundary L with regularity or randomly so as to be spaced apart from one another. The inverting portions 15 are preferably provided with a random pattern of the hole portions 13a in the transparent electrode portion 13 or a regular pattern of the island portions 14a in the transparent insulating portion 14. The random pattern of the hole portions 13a in the transparent electrode portion 13 and the regular pattern of the island portions 14a in the transparent insulating portion 14 may be mixed in the boundary L. FIG. 33C illustrates an example in which the inverting portions 15 are provided in the boundary L with a regular pattern of the island portions 14a in the transparent insulating portion 14. On the other hand, FIG. 33D illustrates an example in which the inverting portions 15 are provided in the boundary L with a random pattern of the hole portions 13a in the transparent electrode portion 13.

In the fourth embodiment, those excluding the above are the same as those in the third embodiment.

### [Effects]

According to the fourth embodiment, the following effect can be further obtained in addition to the effects in the first embodiment. Specifically, since the transparent electrode portion 13 includes the plurality of hole portions 13a randomly provided so as to be spaced apart from one another, the generation of moire can be suppressed in the transparent electrode portion 13.

### 5. Fifth Embodiment

### Configuration of Transparent Conductive Element

### (Transparent Electrode Portion, Transparent Insulating Portion)

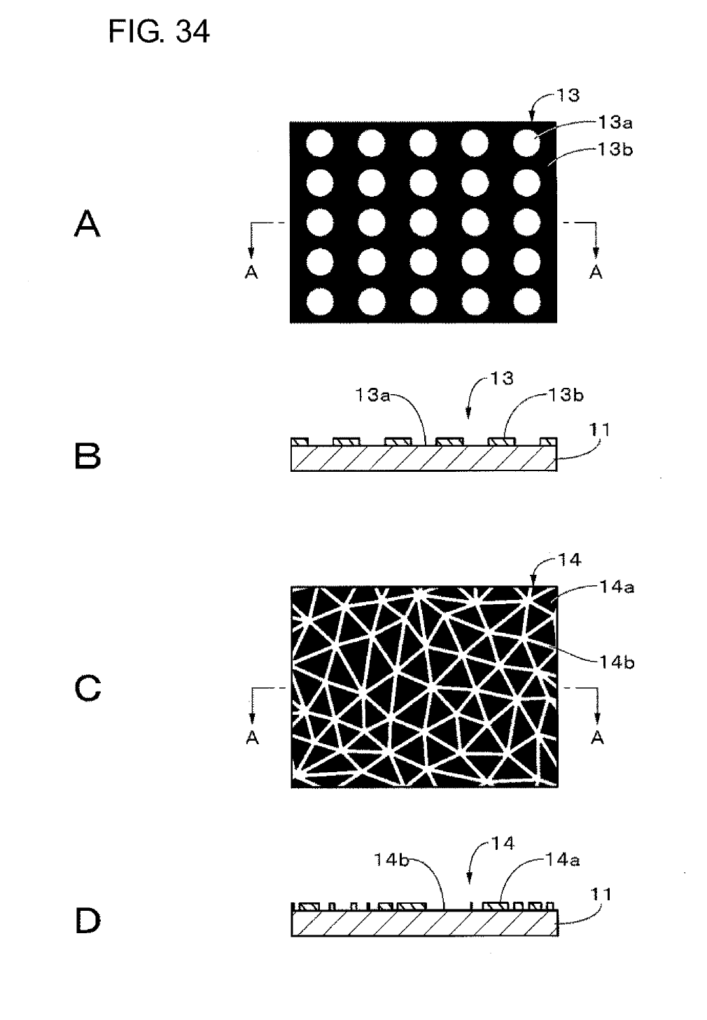

FIG. 34A is a plan view illustrating a configuration example of the transparent electrode portion 13 of the first transparent conductive element 1. FIG. 34B is a cross-sectional view taken along line A-A illustrated in FIG. 34A. FIG. 34C is a plan view illustrating a configuration example of the transparent insulating portion 14 of the first transparent conductive element 1. FIG. 34D is a cross-sectional view taken along line A-A illustrated in FIG. 34C. Of the transparent electrode portion 13 and the transparent insulating portion 14, the transparent electrode portion 13 is the transparent conductive layer 12 having a regular pattern therein and the transparent insulating portion 14 is the transparent conductive layer 12 having a random pattern therein. The pattern in the transparent conductive portion 13 is a pattern of a plurality of hole portions 13a, and the pattern in the transparent insulating portion 14 is a pattern of a plurality of island portions 14a. The pattern of the plurality of hole portions 13a is a regular pattern, whereas the pattern of the plurality of island portions 14a is a random pattern.

As illustrated in FIGS. 34A and 34B, the transparent electrode portion 13 is the transparent conductive layer 12 in which the plurality of hole portions 13a are provided regularly so as to be spaced apart from one another and the conductive portion 13b is interposed between adjacent hole portions 13a.

As illustrated in FIGS. 34C and 34D, the transparent insulating portion 14 is the transparent conductive layer 12 in which the gap portions 14b are provided in a random mesh shape. Specifically, the transparent conductive layer 12 disposed in the transparent insulating portion 14 is divided into the island portions 14a separated by the gap portions 14b each extended in a random direction. In other words, the transparent insulating portion 14 is configured by using the transparent conductive layer 12 and the pattern of the island portions 14a formed by dividing the transparent conductive layer 12 by the gap portions 14b each extended in a random direction is disposed as a random pattern. The pattern of these island portions 14a (i.e., random pattern) is, for example, a pattern being divided into random polygons by the gap portions 14b each extended in a random direction. Note that the gap portions 14b themselves whose extended directions are random also form a random pattern. For example, when the first transparent conductive element 1 is viewed from the surface on the side where the transparent conductive layer 12 is provided, the gap portion 14b has a random linear shape. The gap portion 14b is, for example, a groove portion provided between the island portions 14a.

Here, the respective gap portions 14b provided in the transparent insulating portion 14 are those extended in random directions in the transparent insulating portion 14. A width (referred to as a line width) in the vertical direction with respect to the extended direction is selected to be the same line width, for example. In this transparent insulating portion 14, the coverage by the transparent conductive layer 12 is adjusted by the line width of each of the gap portions 14b. The coverage by the transparent conductive layer 12 in the transparent insulating portion 14 is preferably set in the same level as the coverage by the transparent conductive layer 12 in the transparent electrode portion 13. The same level herein refers to a level at which the transparent electrode portion 13 and the transparent insulating portion 14 cannot be visually recognized as a pattern.

The average boundary line length La in the transparent electrode portion 13 provided in the first region (electrode region) R₁ and the average boundary line length Lb in the transparent insulating portion 14 provided in the second region (insulating region) R₂ preferably fall within a range of 0<La, Lb≦20 mm/mm² as with the above-described first embodiment. By setting the average boundary line lengths La and Lb within the above-described range, the same functional effect as that in the above-described first embodiment can be obtained.

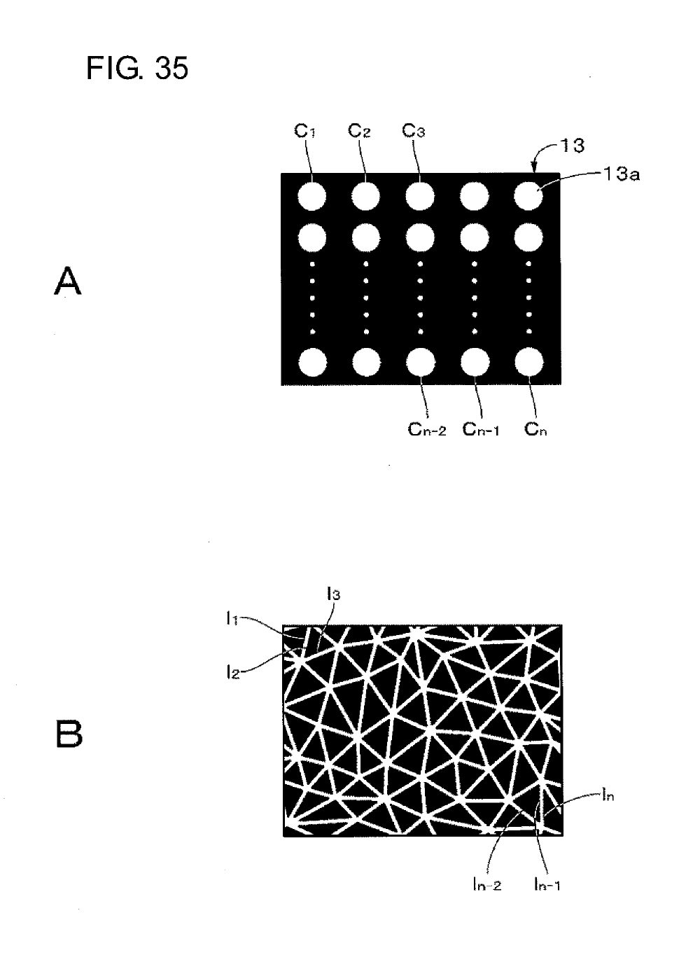

With reference to FIGS. 35A and 35B, how to obtain the average boundary line length La in the transparent electrode portion 13 and the average boundary line length Lb in the transparent insulating portion 14 will be described.

The average boundary line length La in the transparent electrode portion 13 can be obtained in the same manner as that in the above-described first embodiment.

The average boundary line length Lb in the transparent insulating portion 14 in which the mesh-shaped gap portions 14b are provided is obtained as follows. The average boundary line length Lb in the transparent insulating portion 14 can be obtained in the same manner as that in the above-described first embodiment except that a boundary line (Σlᵢ=l₁+ . . . +lₙ) is measured by means of image analysis and boundary line lengths L₁, . . . , L₁₀ [mm/mm²] are obtained. Note however that the boundary line lᵢ (l₁, . . . , lₙ) refers to a boundary line between each island portion 14a and the gap portion 14b.

### (Boundary Portion)

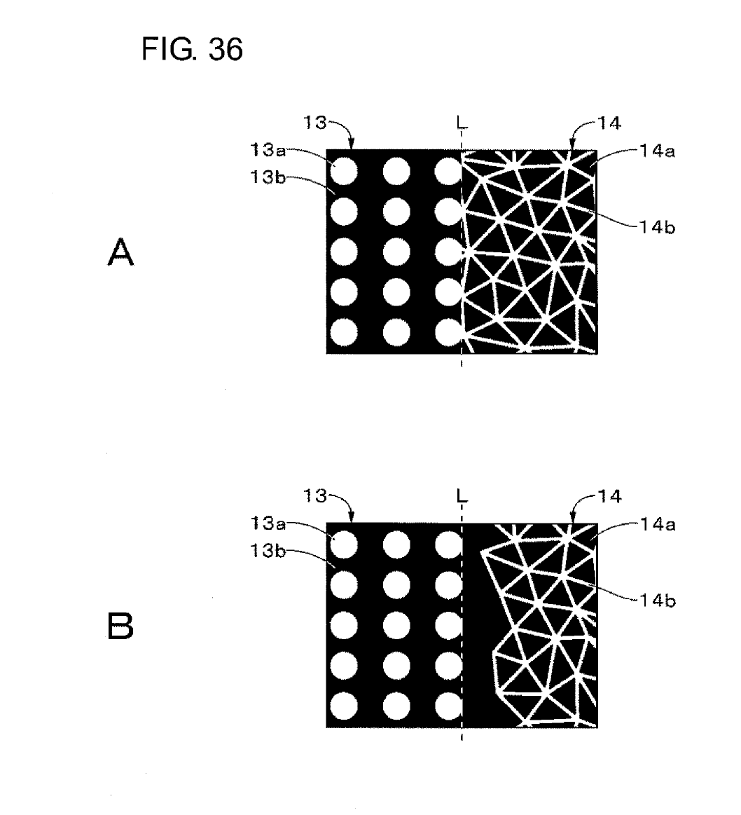

FIGS. 36A and 36B are each a plan view illustrating an exemplary shape pattern in the boundary portion. A regular or random shape pattern is provided in the boundary portion between the transparent electrode portion 13 and the transparent insulating portion 14. By providing a regular or random shape pattern in the boundary portion in this manner, the visual recognition of the boundary portion can be restrained. FIG. 36A illustrates an example of the boundary portion in which a random shape pattern is provided. FIG. 36B, on the other hand, illustrates an example of the boundary portion in which a regular shape pattern is provided.

The shape pattern in the boundary portion is the same as the shape pattern in the boundary portion in the third embodiment except that the shape pattern on the transparent insulating portion 14 side is formed by the above-described random pattern in the transparent insulating portion 14.

### [Method for Producing Transparent Conductive Element]

A method for producing the first transparent conductive element 1 according to the fifth embodiment is the same as the method for producing the first transparent conductive element 1 according to the first embodiment except for a method for generating a random pattern in the transparent insulating portion 14 which is an insulating region. The method for generating a random pattern in the transparent insulating portion 14 will be described below.

### [Method for Generating Random Pattern]

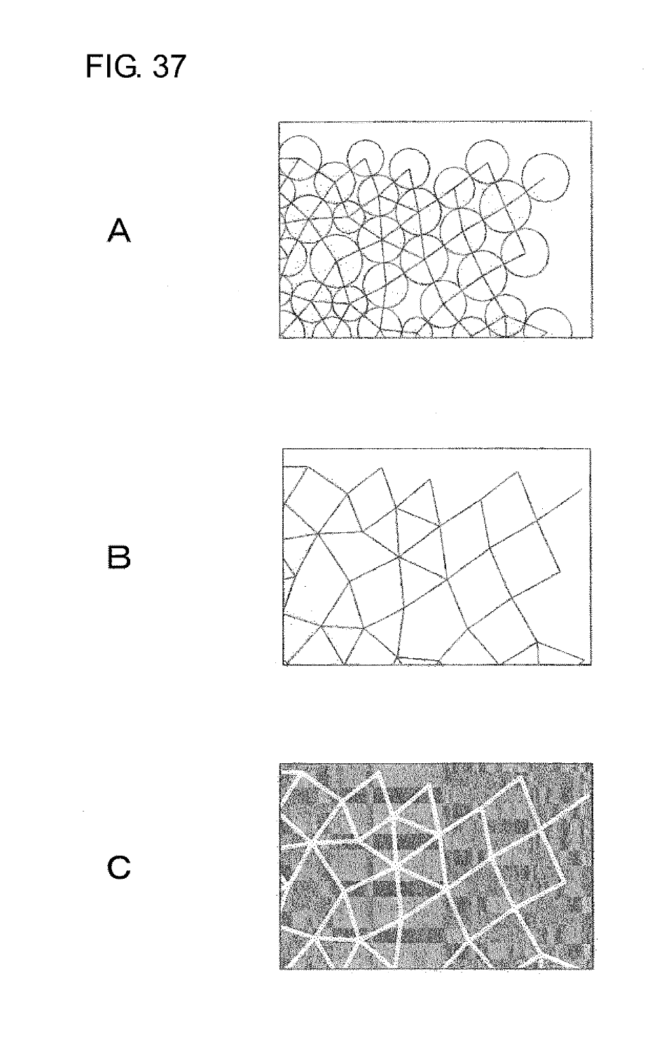

First, a circular random pattern is generated. As a method for generating a circular random pattern, the generation method same as that in the above-described third embodiment can be used. Next, as illustrated in FIG. 37A, in the generated circular random pattern, straight lines each connecting between the centers of circles whose circumferences are in contact with each other are generated. As a result, as illustrated in FIG. 37B, a polygonal random pattern configured by segments extended in random directions is generated. Next, as illustrated in FIG. 37C, the segments configuring the polygonal random pattern are broadened to have a predetermined line width. A random pattern of the gap portions 14b in the transparent insulating portion 14 illustrated in FIG. 34C is thereby obtained.

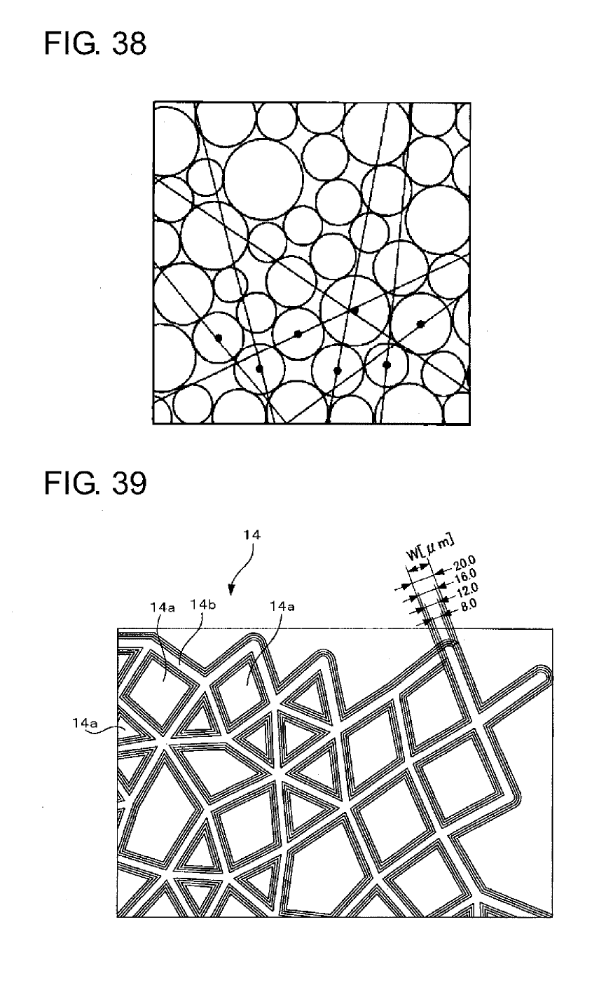

As illustrated in FIG. 38, a mesh pattern may be formed by drawing lines each at a random angle with respect to a random circular pattern. More specifically, the central coordinates of the respective circles are utilized as they are and straight lines passing through the centers of the respective circles are drawn. At this time, a rotation angle of each of the straight lines is randomly determined in a range of 0 degree to 180 degrees to form a line with a random slope as illustrated in FIG. 38. Also by this means, a random mesh pattern can be generated.

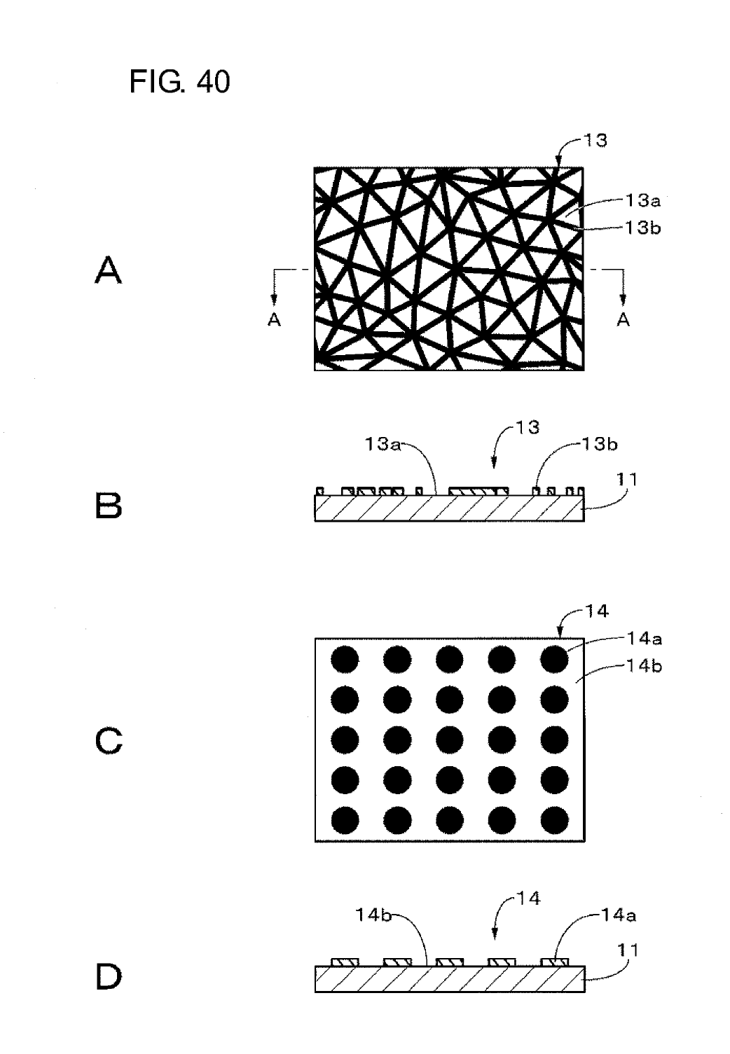

As illustrated in FIG. 39, the gap portion 14b can be changed to have a varied line width W. By changing the line width W of the gap portion 14b, the coverage in the transparent insulating portion 14 by the transparent conductive layer 12 divided by the gap portions 14b can be adjusted in a wide range. The following Table 1 shows results each obtained by calculating a coverage [%] in the transparent insulating portion 14 by the transparent conductive layer 12 for each range (Rₘᵢₙ to Rₘₐₓ) of a radius r of a circle to be generated as a random pattern and each line width W of the gap portion 14b.

TABLE 1

| Line | | | |
|---|---|---|---|
| width | Coverage [%] | | |
| [μm] | r = 25~45 [μm] | r = 20~35 [μm] | r = 20~25 [μm] |
| 8 | 74.9 | 68.9 | 65.5 |
| 12 | 64.0 | 55.8 | 51.2 |
| 16 | 54.0 | 44.4 | 38.8 |
| 20 | 45.1 | 34.6 | 28.5 |

As shown in Table 1 above, in the transparent insulating portion 14 in which the transparent conductive layer 12 is divided by the gap portions 14b, it can be seen that the coverage by the transparent conductive layer 12 can be adjusted in a wide range of 28.5% to 74.9%.

On the other hand, if the inverted pattern of the transparent electrode portion 13 illustrated in FIG. 34A, for example, is used as an insulating region (the case of the transparent electrode portion 13 in the first embodiment (FIG. 3C)), a limit value being about 65% at maximum is derived by the following calculation for the coverage by the transparent conductive layer 12 in this insulating region.

More specifically, when circles are arranged in a given region, a maximum value of the filling rate of the circles reaches its theoretical maximum value of 90.7% if the circles are arranged in a staggered manner. Here, in a case where a radius of the circles is set to be 50 μm, the radius of the circles is reduced to be (50-8/2)=46 μm if a space of 8 μm is provided between the circles in order to arrange the circles independently. The area ratio of the circle in such a state is calculated to be (46×46)/(50×50)=0.846 and the filling rate of the circles to be (90.7%)×(0.846)=76.7%.

Here, if radii of the circles are set to be random, a gap between the circles is further widened and the actual filling rate corresponds to a value between the filling rate (90.7%) in the staggered arrangement and a filling rate (78.5%) in a lattice arrangement. Although this value varies depending on a ratio (distribution) between the maximum radius and the minimum radius of randomly-generated circles, it is approximately about 80% at maximum.

In view of this, a range of the radius r of the circles to be initially generated as a random pattern is set to be Rₘᵢₙ=35 μm to Rₘₐₓ=50 μm and a space of 8 μm is provided between the circles. The filling rate of the circles in this case falls within a range of 80%×(31×31)/(35×35)=62.76% to 80%×(46×46)/(50×50) 67.71%. Even if the distribution of the randomly-generated circles is shifted toward slightly larger circles, a filling rate of about 65% is derived as the limit value. It can be seen that the thus calculated limit value of the filling rate at about 65% is lower than the coverage of 74.9% calculated in the transparent insulating portion 14 where the transparent conductive layer 12 is divided by the gap portions 14b.

In the fifth embodiment, those excluding the above are the same as those in the third embodiment.

### [Effects]

According to the fifth embodiment, the same effects as those in the third embodiment can be obtained.

### 6. Sixth Embodiment

### Configuration of Transparent Conductive Element

### (Transparent Electrode Portion, Transparent Insulating Portion)

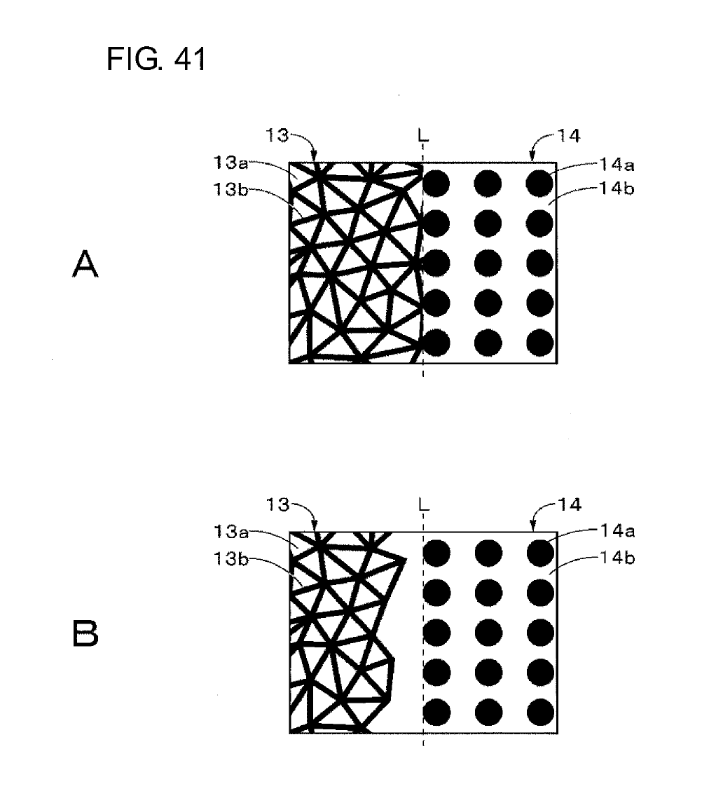

FIG. 40A is a plan view illustrating a configuration example of the transparent electrode portion 13 of the first transparent conductive element 1. FIG. 40B is a cross-sectional view taken along line A-A illustrated in FIG. 40A. FIG. 40C is a plan view illustrating a configuration example of the transparent insulating portion 14 of the first transparent conductive element 1. FIG. 40D is a cross-sectional view taken along line A-A illustrated in FIG. 40C. Of the transparent electrode portion 13 and the transparent insulating portion 14, the transparent electrode portion 13 is the transparent conductive layer 12 having a random pattern therein and the transparent insulating portion 14 is the transparent conductive layer 12 having a regular pattern therein. The pattern in the transparent conductive portion 13 is a pattern of a plurality of hole portions 13a, and the pattern in the transparent insulating portion 14 is a pattern of a plurality of island portions 14a. The pattern of the plurality of hole portions 13a is a random pattern, whereas the pattern of the plurality of island portions 14a is a regular pattern.

As illustrated in FIGS. 40A and 40B, the transparent electrode portion 13 is the transparent conductive layer 12 made of the conductive portions 13h provided in a random mesh shape. The conductive portions 13b are extended in random directions and these extended conductive portions 13b form the hole portions 13a independent of one another. Thus, the plurality of hole portions 13a are randomly provided in the transparent electrode portion 13. For example, when the first transparent conductive element 1 is viewed from the surface on the side where the transparent conductive layer 12 is provided, the conductive portion 13b has a random linear shape.

As illustrated in FIGS. 40C and 40D, the transparent insulating portion 14 is the transparent conductive layer 12 having the plurality of island portions 14a provided with a regular pattern so as to be spaced apart from one another. The gap portion 14b serving as an insulating portion is interposed between adjacent island portions 14a.

### (Boundary Portion)

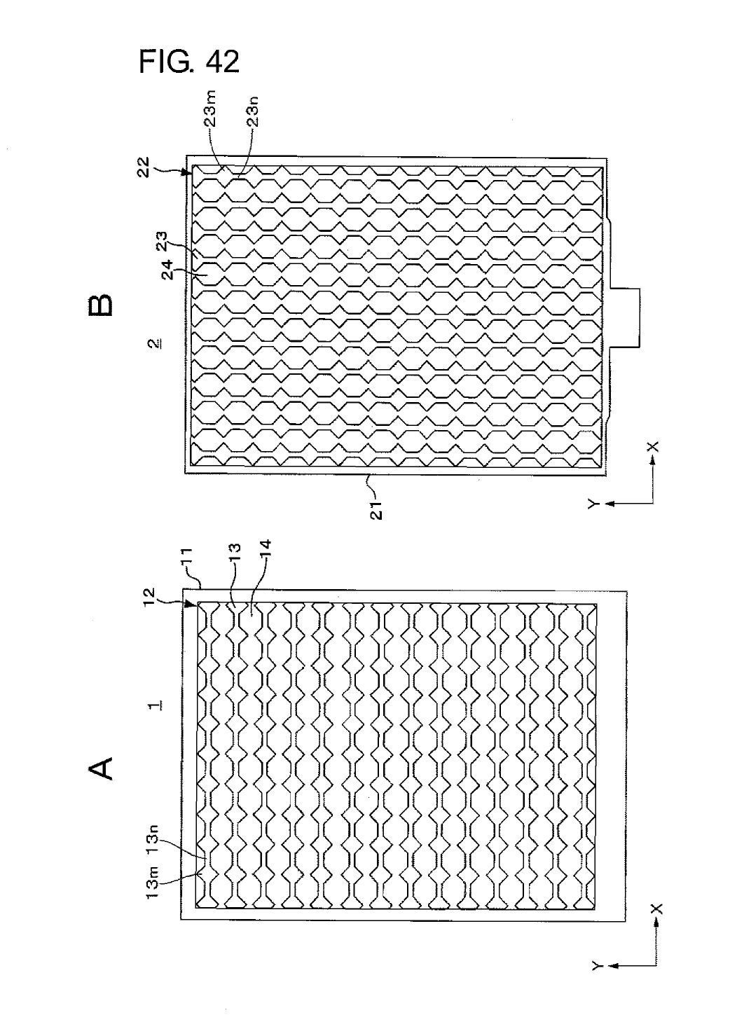

FIGS. 41A and 41B are each a plan view illustrating an exemplary shape pattern in the boundary portion. A regular or random shape pattern is provided in the boundary portion between the transparent electrode portion 13 and the transparent insulating portion 14. By providing a regular or random shape pattern in the boundary portion in this manner, the visual recognition of the boundary portion can be restrained. FIG. 41A illustrates an example of the boundary portion in which a random shape pattern is provided. FIG. 41B, on the other hand, illustrates an example of the boundary portion in which a regular shape pattern is provided.

The shape pattern in the boundary portion is the same as the shape pattern in the boundary portion in the fourth embodiment except that the shape pattern on the transparent electrode portion 13 side is formed by the above-described random pattern in the transparent electrode portion 13.

The random mesh-shaped pattern in the transparent electrode portion 13 can be generated in the same manner as that for the random mesh-shaped pattern in the transparent insulating portion 14 in the above-described fifth embodiment.

In the sixth embodiment, those excluding the above are the same as those in the fourth embodiment.

### [Effects]

According to the sixth embodiment, the same effects as those in the fourth embodiment can be obtained.

### 7. Seventh Embodiment

### [Configuration of Transparent Conductive Element]

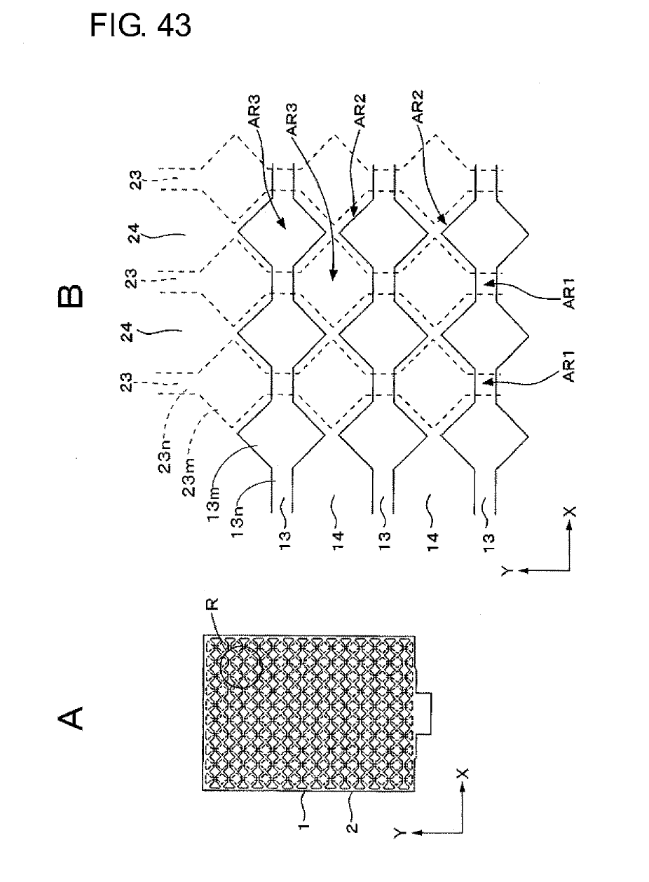

FIG. 42A is a plan view illustrating a configuration example of the first transparent conductive element 1 according to the seventh embodiment of the present technique. FIG. 42B is a plan view illustrating a configuration example of the second transparent conductive element 2 according to the seventh embodiment of the present technique. The seventh embodiment is the same as the first embodiment except for the configurations of the transparent electrode portion 13, the transparent insulating portion 14, the transparent electrode portion 23, and the transparent insulating portion 24.

The transparent electrode portion 13 includes a plurality of pad portions (unit electrode bodies) 13m and a plurality of connecting portions 13n connecting between the plurality of pad portions 13m. The connecting portion 13n is extended in the X-axis direction and connects between end portions of adjacent pad portions 13m. The pad portions 13m and the connecting portions 13n are integrally formed.

The transparent electrode portion 23 includes a plurality of pad portions (unit electrode bodies) 23m and a plurality of connecting portions 23n connecting between the plurality of pad portions 23m. The connecting portion 23n is extended in the Y-axis direction and connects between end portions of adjacent pad portions 23m. The pad portions 23m and the connecting portions 23n are integrally formed.

Examples of a shape of the pad portion 13m and the pad portion 23m may include a polygonal shape such as a rhomboid shape (diamond shape) or a rectangular shape, a star shape, and a cross shape, although it is not limited to these shapes.

Although a rectangular shape can be employed as a shape of the connecting portion 13n and the connecting portion 23n, the shape of the connecting portion 13n and the connecting portion 23n is not particularly limited to a rectangular shape as long as it is a shape capable of connecting between adjacent pad portions 13m and pad portions 23m. Examples of a shape other than a rectangular shape may include a linear shape, an oval shape, a triangular shape, and an indefinite shape.

In order to further improve non-visibility, it is preferred to set a relationship between coverages of the first transparent conductive element (X electrode) 1 and the second transparent conductive element (Y electrode) 2 in a state where both the elements are overlapped with each other. A specific method for setting a relationship between coverages of the first transparent conductive element 1 and the second transparent conductive element 2 will be described below.

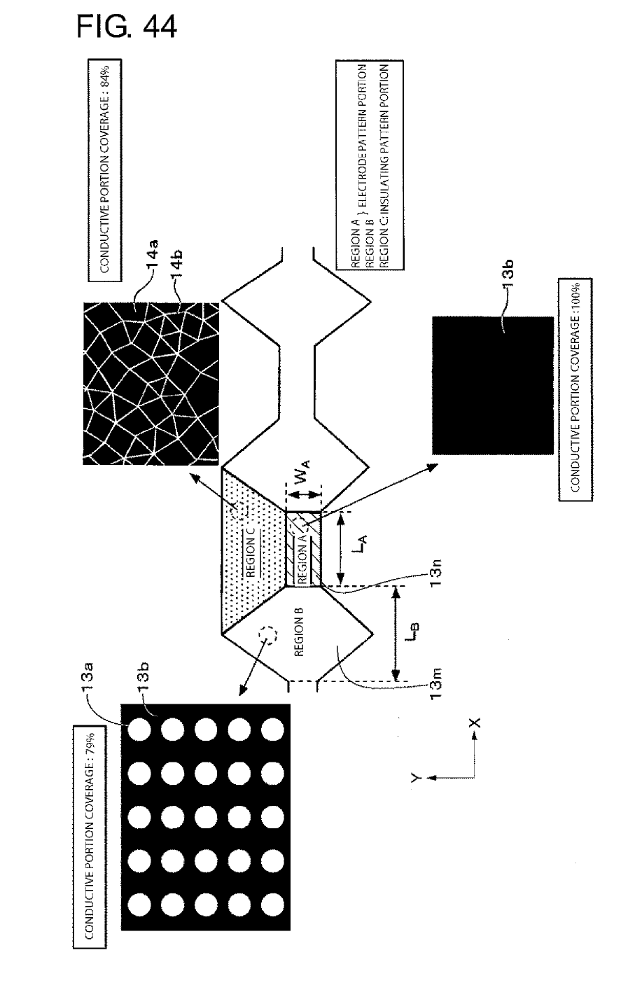

FIG. 43A is a plan view illustrating the first transparent conductive element 1 in the state illustrated in FIG. 1 and the second transparent conductive element 2. FIG. 43B is a plan view illustrating a region R shown in FIG. 43A in an enlarged manner. In FIGS. 43A and 43B, the second transparent conductive element 2 is illustrated with broken lines. The first transparent conductive element 1 and the second transparent conductive element 2 are disposed in an overlapping manner so that the transparent electrode portions 13 and the transparent electrode portions 23 are perpendicular to each other. If the first transparent conductive element 1 and the second transparent conductive element 2 thus disposed in an overlapping manner are viewed from an input surface side where a touch operation is made by a user, all of portions where the first transparent conductive element 1 and the second transparent conductive element 2 are overlapped with each other (input surface forming portions) can be classified into any of regions AR1, AR2, and AR3. The region AR1 is a region where the transparent electrode portions 13 and 23 are overlapped with each other. The region AR2 is a region where the transparent insulating portions 14 and 24 are overlapped with each other. The region AR3 is a region where the transparent electrode portion 13 and the transparent insulating portion 24 are overlapped with each other or the transparent insulating portion 14 and the transparent electrode portion 23 are overlapped with each other.

In a state where the first transparent conductive element 1 and the second transparent conductive element 2 are overlapped with each other, a difference between added values of the coverage by the conductive material portions in the first transparent conductive element 1 and the coverage by the conductive material portions in the second transparent conductive element 2 is preferably in the range of from 0% or higher and 60% or lower in all of the regions AR1, AR2, and AR3 as viewed from the input surface direction. This makes it possible to restrain the visual recognition of the regions AR1, AR2, and AR3, thereby achieving a further non-visibility improvement.

Moreover, if the transparent electrode portions 13 and 23 have the above-described shape, it is preferable that the transparent electrode portions 13 and 23 each have two or more types of regions with different coverages by the conductive material portions. The transparent electrode portions 13 and 23 having such a configuration will be described below taking the transparent electrode portion 13 as an example.

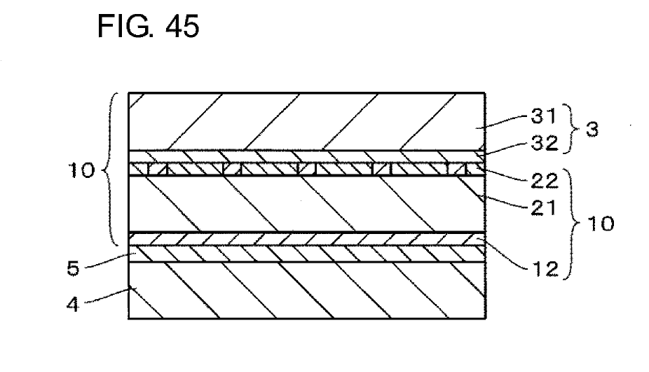

As illustrated in FIG. 44, the transparent electrode portion 13, for example, includes a region A which is the connecting portion 13n and a region B which is the pad portion 13m. Also, the portion corresponding to the transparent insulating portion 14 is defined as a region C. The width of the region A is defined as W_{A} and the length thereof as L_{A}. The width W_{B} of the region B is defined as W_{B}=(an area of the region B)/L_{B}. L_{B} is the length of the region B in the extending direction (X-axis direction) of the transparent electrode portion 13.

If the transparent electrode portion 13 has two or more regions, it is preferable that a coverage by the hole portions 13a be set to be smaller (=a coverage by the conductive portion 13b be set to be greater) in a region having a greater L(x)/W(x) value. This is because in the region having the greater L(x)/W(x) value, the resistance value in that region is large in the first place and an influence of a resistance increase accompanied by an increase in the coverage by the hole portions 13a is therefore greater. As far as the case of FIG. 44 is concerned, the region A has a greater L(x)/W(x) value as compared to the region B and therefore has a greater resistance value in the first place. Thus, as illustrated in FIG. 44, it is conceivable that the coverage by the conductive portion 13b is set at 79% (21% for the hole portions 13a) in the region B and the coverage by the conductive portion 13b is set at 100% (0% for the hole portions 13a) in the region A, etc., for example. Note that these coverages are merely an example.

With regard to the region C, i.e., the transparent insulating portion 14, a coverage by the conductive material portions (island portions 14a) may be set so as to meet the above-described conditions for the coverage added value difference when the X and Y electrodes are overlapped with each other.

By partially controlling the coverages by the conductive material portions as in this example, the amount of the conductive material used can be suppressed (=the material cost can be suppressed) when the electrodes are formed by printing. Also in view of making the pattern visually unrecognizable, a conductive material coverage difference in the regions A to C is preferably set within the range of from 0% or higher and 30% or lower.

In the seventh embodiment, those excluding the above are the same as those in the first embodiment.

### [Effects]

According to the seventh embodiment, the same effects as those in the first embodiment can be obtained.

### 8. Eighth Embodiment

### Configuration of Information Input Device

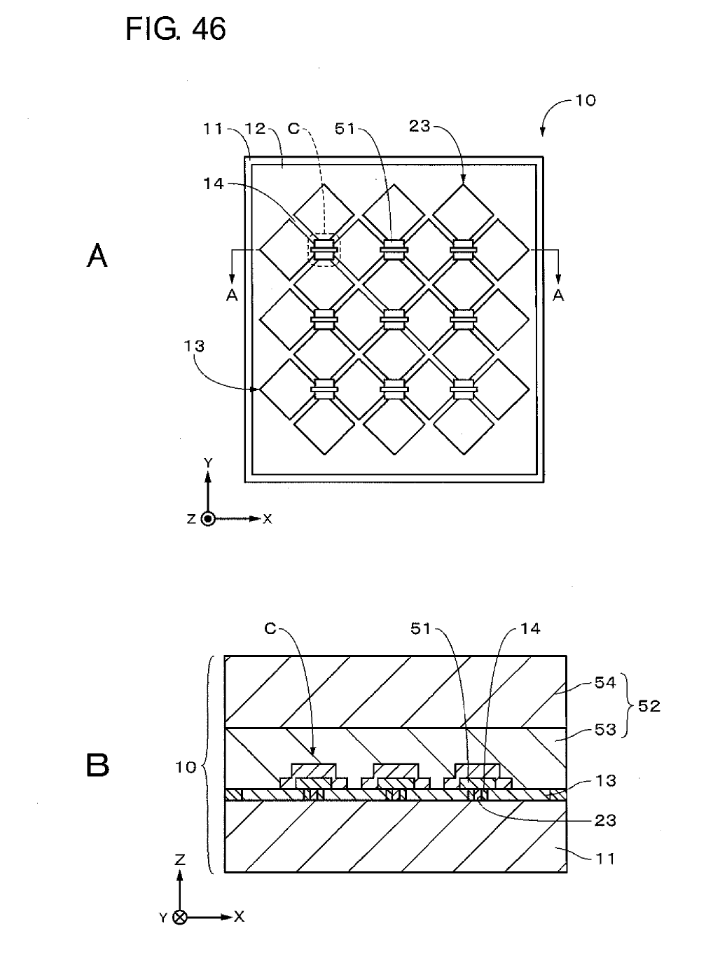

FIG. 45 is a cross-sectional view illustrating a configuration example of an information input device according to the eighth embodiment of the present technique. The information input device 10 according to the eighth embodiment is different from the information input device 10 according to the first embodiment in that it includes the transparent conductive layer 12 on one principal surface (first principal surface) of the substrate 21 and the transparent conductive layer 22 on the other principal surface (second principal surface) thereof. The transparent conductive layer 12 includes transparent electrode portions and transparent insulating portions. The transparent conductive layer 22 includes transparent electrode portions and transparent insulating portions. The transparent electrode portion of the transparent conductive layer 12 is an X electrode portion extended in the X-axis direction. The transparent electrode portion of the transparent conductive layer 22 is a Y electrode portion extended in the Y-axis direction. Therefore, the transparent electrode portions of the transparent conductive layer 12 and the transparent conductive layer 22 have a relationship perpendicular to each other.

In the eighth embodiment, those excluding the above are the same as those in the first embodiment.

### [Effects]

According to the eighth embodiment, the following effects can be further obtained in addition to the effects in the first embodiment. Specifically, since the transparent conductive layer 12 is provided on one principal surface of the substrate 21 and the transparent conductive layer 22 is provided on the other principal surface thereof, the substrate 11 (FIG. 1) in the first embodiment can be omitted. Therefore, the information input device 10 can be made further thinner.

### 9. Ninth Embodiment

### Configuration of Information Input Device

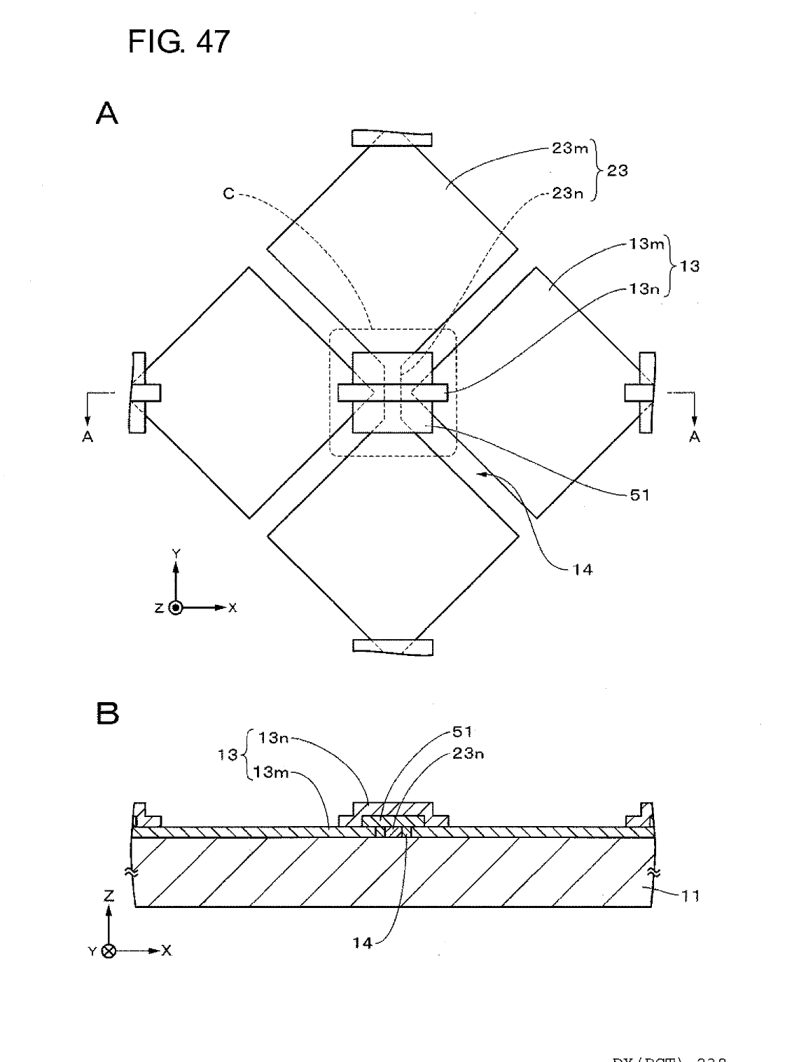

FIG. 46A is a plan view illustrating a configuration example of an information input device according to the ninth embodiment of the present technique. FIG. 46B is a cross-sectional view taken along line A-A illustrated in FIG. 46A. The information input device 10 is what is called a projected capacitive touch panel. As illustrated in FIGS. 46A and 46B, the information input device 10 includes: the substrate 11; the plurality of transparent electrode portions 13 and transparent electrode portions 23; the transparent insulating portions 14; and transparent insulating layers 51. The plurality of transparent electrode portions 13 and transparent electrode portions 23 are provided on the same surface of the substrate 11. The transparent insulating portion 14 is provided between the transparent electrode portion 13 and the transparent electrode portion 23 in an in-plane direction of the substrate 11. The transparent insulating layer 51 is interposed at an intersecting portion between the transparent electrode portion 13 and the transparent electrode portion 23.

Moreover, as illustrated in FIG. 46B, an optical layer 52 may be further provided if necessary on the surface of the substrate 11 where the transparent electrode portions 13 and the transparent electrode portions 23 are formed. In FIG. 46A, the illustration of the optical layer 52 is omitted. The optical layer 52 includes an adhering layer 53 and a base 54. The base 54 is adhered to a surface of the substrate 11 via the adhering layer 53. The information input device 10 is suitable to be applied to a display surface of a display device. The substrate 11 and the optical layer 52 have transparency with respect to visible light, for example, and a refractive index n thereof is preferably in the range of 1.2 or higher and 1.7 or lower. Hereinafter, two directions perpendicular to each other within a plane of the surface of the information input device 10 are defined as an X-axis direction and a Y-axis direction, respectively, and a direction vertical to the surface is referred to as a Z-axis direction.

### (Transparent Electrode Portion)

The transparent electrode portion 13 is extended in the X-axis direction (first direction) on the surface of the substrate 11, whereas the transparent electrode portion 23 is extended toward the Y-axis direction (second direction) on the surface of the substrate 11. Thus, the transparent electrode portion 13 and the transparent electrode portion 23 perpendicularly intersect with each other. At an intersecting portion C where the transparent electrode portion 13 intersects with the transparent electrode portion 23, the transparent insulating layer 51 is interposed for providing insulation between both the electrodes. An extraction electrode is electrically connected to one end of each of the transparent electrode portion 13 and the transparent electrode portion 23. The extraction electrode and a drive circuit are connected with each other via an FPC (Flexible Printed Circuit).

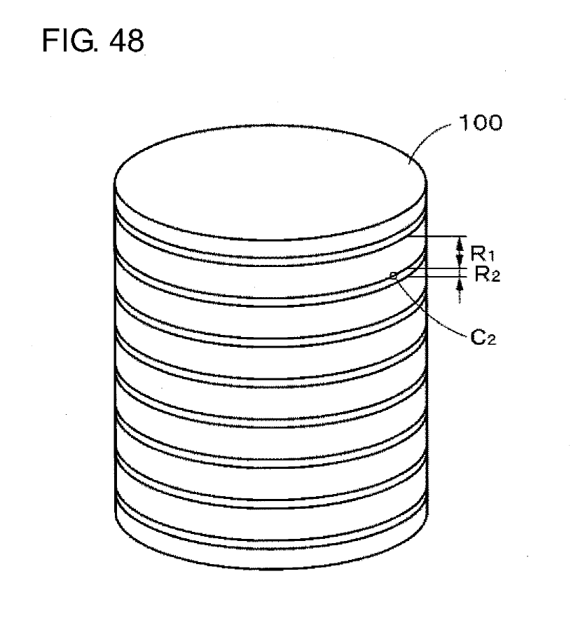

FIG. 47A is a plan view illustrating the vicinity of the intersecting portion C shown in FIG. 46A in an enlarged manner. FIG. 47B is a cross-sectional view taken along line A-A illustrated in FIG. 47A. The transparent electrode portion 13 includes the plurality of pad portions (unit electrode bodies) 13m and the plurality of connecting portions 13n connecting between the plurality of pad portions 13m. The connecting portion 13n is extended in the X-axis direction and connects between end portions of adjacent pad portions 13m. The transparent electrode portion 23 includes the plurality of pad portions (unit electrode bodies) 23m and the plurality of connecting portions 23n connecting between the plurality of pad portions 23m. The connecting portion 23n is extended in the Y-axis direction and connects between end portions of adjacent pad portions 23m.

At the intersecting portion C, the connecting portion 23n, the transparent insulating layer 51, and the connecting portion 13n are layered in this order on the surface of the substrate 11. The connecting portion 13n is formed so as to go across and step over the transparent insulating layer 51. One end of the connecting portion 13n stepping over the transparent insulating layer 51 is electrically connected to one of the adjacent pad portions 13m and the other end of the connecting portion 13n stepping over the transparent insulating layer 51 is electrically connected to the other one of the adjacent pad portions 13m.

The pad portion 23m and the connecting portion 23n are integrally formed, whereas the pad portion 13m and the connecting portion 13n are separately formed. The pad portion 13m, the pad portion 23m, the connecting portion 23n, and the transparent insulating portion 14 are configured, for example, by the single-layered transparent conductive layer 12 provided on the surface of the substrate 11. The connecting portion 13n is made of a conductive layer, for example.

Examples of a shape of the pad portion 13m and the pad portion 23m may include a polygonal shape such as a rhomboid shape (diamond shape) or a rectangular shape, a star shape, and a cross shape, although it is not limited to these shapes.

As the conductive layer constituting the connecting portion 13n, a metal layer or a transparent conductive layer, for example, may be used. The metal layer contains a metal as a major component. A highly-conductive metal is preferably used as the metal. Although examples of such a material may include Ag, Al, Cu, Ti, Nb, and impurity-doped Si, Ag is preferable in view of its high conductivity as well as the film forming performance and printing performance thereof. It is preferable that a width of the connecting portion 13n be made narrower, a thickness thereof thinner, and a length thereof shorter by employing a highly-conductive metal as a material for the metal layer. This makes it possible to improve the visibility.

Although a rectangular shape can be employed as a shape of the connecting portion 13n and the connecting portion 23n, the shape of the connecting portion 13n and the connecting portion 23n is not particularly limited to a rectangular shape as long as the shape is capable of connecting between adjacent pad portions 13m and pad portions 23m. Examples of a shape other than a rectangular shape may include a linear shape, an oval shape, a triangular shape, and an indefinite shape.

### (Transparent Insulating Layer)

The transparent insulating layer 51 preferably has an area larger than the portion where the connecting portion 13n intersects with the connecting portion 23n. For example, the transparent insulating layer 51 has a size such as to cover tips of the pad portions 13m and the pad portions 23m positioned at the intersecting portion C.

The transparent insulating layer 51 contains a transparent insulating material as a major component. A macromolecular material having transparency is preferably used as the transparent insulating material. Examples of such a material may include: (meth)acrylic resins, such as poly(methyl methacrylate), and copolymers of methyl methacrylate with a vinyl monomer such as other alkyl (meth)acrylates and styrene; polycarbonate-based resins such as polycarbonate and diethylene glycol bisallyl carbonate (CR-39); thermosetting (meth)acrylic resins such as a homopolymer or copolymer of (brominated) bisphenol A type di(meth)acrylate and a polymer and a copolymer of urethane modified monomers of (brominated) bisphenol A mono(meth)acrylate; polyesters, especially polyethylene terephthalate, polyethylene naphthalate, and unsaturated polyester, an acrylonitrile-styrene copolymer, polyvinyl chloride, polyurethane, epoxy resins, polyarylate, polyether sulfone, polyether ketone, cycloolefin polymers (product name: Arton, Zeonor), and cycloolefin copolymer. Also, an aramid-based resin may be used in consideration of the heat resistance thereof. Herein, (meth)acrylate refers to acrylate or methacrylate.

Although the shape of the transparent insulating layer 51 is not particularly limited as long as the shape is capable of being interposed between the transparent electrode portion 13 and the transparent electrode portion 23 at the intersecting portion C in order to prevent electrical contact between both the electrodes, examples thereof may include a polygon such as a quadrangle, an ellipse, a circle, etc. Examples of a quadrangle may include a rectangle, a square, a rhombus, a trapezoid, a parallelogram, and a rectangular shape with corners thereof having a curvature R.

In the ninth embodiment, those excluding the above are the same as those in the first embodiment.

### [Effects]

According to the ninth embodiment, the following effects can be further obtained in addition to the effects in the first embodiment. Specifically, since the transparent electrode portions 13 and 23 are provided on one principal surface of the substrate 11, the substrate 21 (FIG. 1) in the first embodiment can be omitted. Therefore, the information input device 10 can be made further thinner.

### 10. Tenth Embodiment

The tenth embodiment according to the present technique is different from the first embodiment in that the first transparent conductive element 1 and the second transparent conductive element 2 are produced with a printing method instead of the etching method. Since the second transparent conductive element 2 can be produced in almost the same manner as the first transparent conductive element 1, a description for the method for producing the second transparent conductive element 2 will be omitted.

### [Master]

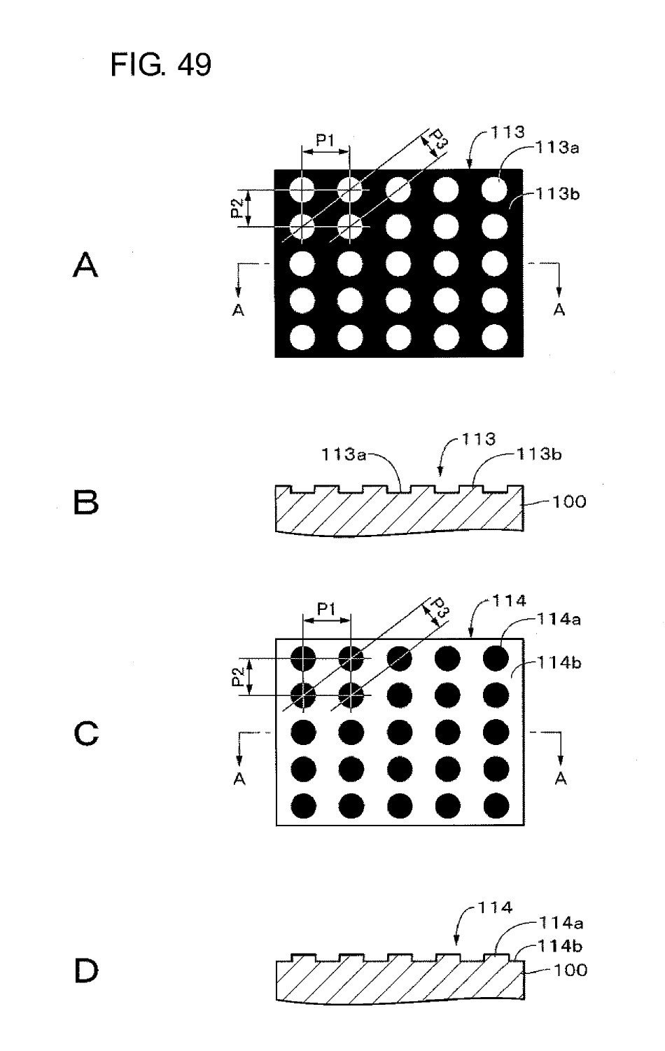

FIG. 48 is a perspective view illustrating an example of a shape of a master for use in a method for producing the first transparent conductive element according to the tenth embodiment of the present technique. A master 100 is, for example, a roll master having a cylindrical surface serving as a transfer surface. A first region R₁ as a transparent conductive portion forming region and a second region R₂ as a transparent insulating portion forming region are alternately and adjacently provided in a planar manner on the cylindrical surface. At least one of the first region R₁ and the second region R₂ has a regular pattern in that region. A shape pattern is provided in a boundary portion between the first region R₁ and the second region R₂.

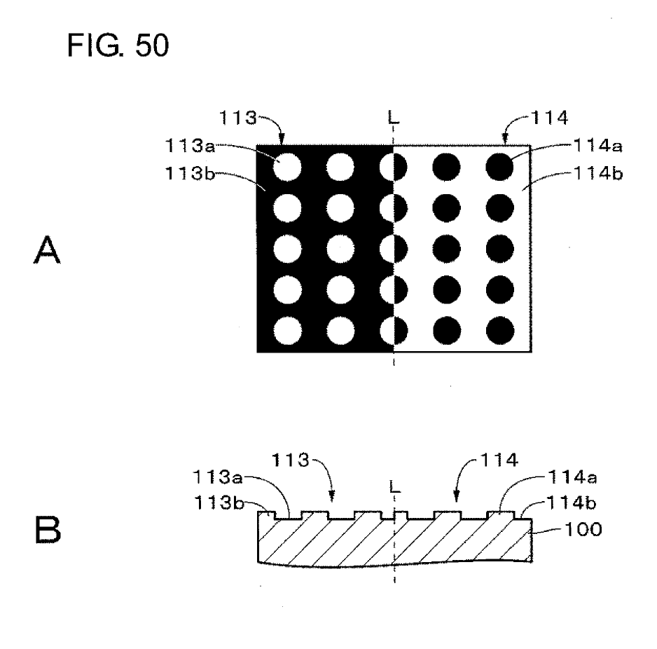

FIG. 49A is a plan view illustrating the first region R₁ of the master 100 in an enlarged manner. FIG. 49B is a cross-sectional view taken along line A-A illustrated in FIG. 49A. FIG. 49C is a plan view illustrating the second region R₂ of the master 100 in an enlarged manner. FIG. 49D is a cross-sectional view taken along line A-A illustrated in FIG. 49C. In the first region R₁, a plurality of hole portions 113a each having a depressed shape are provided regularly so as to be spaced apart from one another. The hole portions 113a are spaced apart from each other by a protruding portion 113b. The hole portion 113a is provided for forming the hole portion 13a of the transparent electrode portion 13 by printing and the protruding portion 113b is provided for forming the conductive portion 13b of the transparent electrode portion 13 by printing. In the second region R₂, a plurality of island portions 114a each having a protruding shape are provided regularly so as to be spaced apart from one another. The island portions 114a are spaced apart from each other by a depressed portion 114b. The island portion 114a is provided for forming the island portion 14a of the transparent insulating portion 14 by printing and the depressed portion 114b is provided for forming the gap portion 14b of the transparent insulating portion 14 by printing.

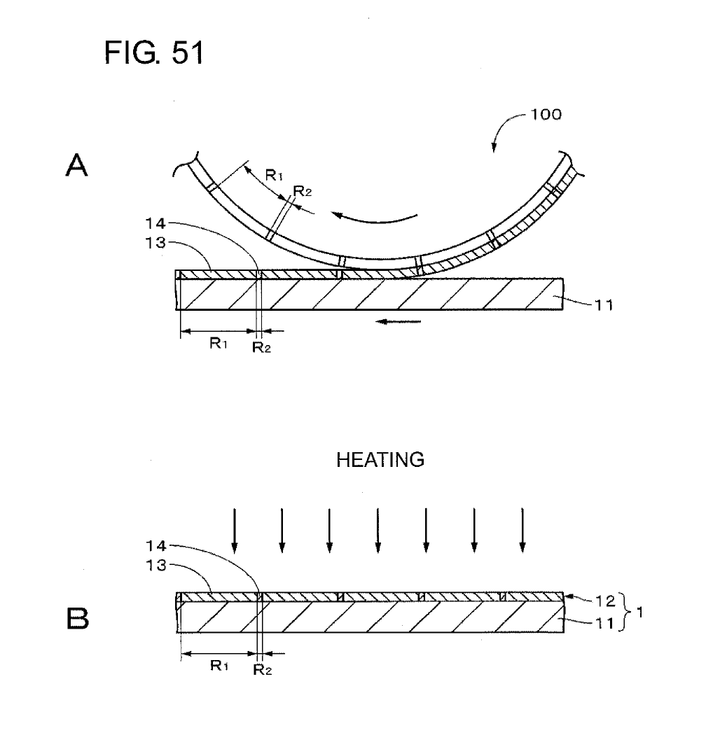

FIG. 50A is a plan view illustrating the boundary portion between the first region R₁ and the second region R₂ in an enlarged manner. FIG. 50B is a cross-sectional view taken along line A-A illustrated in FIG. 50A. A regular shape pattern is provided in the boundary portion between the transparent electrode portion and the transparent insulating portion. This shape pattern is the same as the above-described shape pattern in the first embodiment.

### [Method for Producing Transparent Conductive Element]

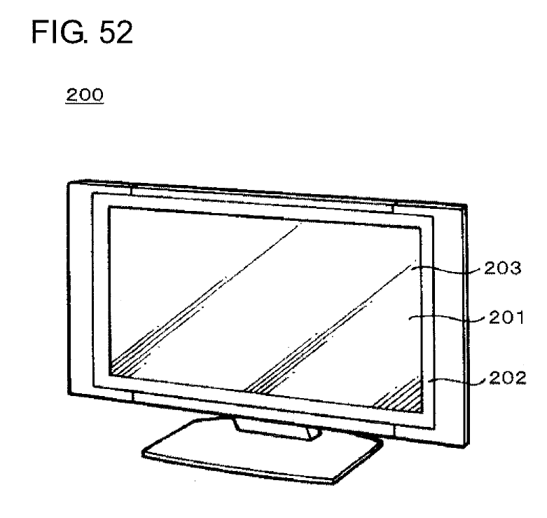

With reference to FIGS. 51A and 51B, an example of the method for producing the first transparent conductive element according to the tenth embodiment of the present technique will be described.

First, as illustrated in FIG. 51A, a conductive ink is applied to the transfer surface of the master 100 and the applied conductive ink is printed on the surface of the substrate 11. As the conductive ink, an ink containing a metal nanoparticle, a metal wire, or the like, can be used for example. As a printing method therefor, screen printing, waterless lithography, flexographic printing, gravure printing, gravure offset printing, reverse offset printing, or the like, can be used. Next, as illustrated in FIG. 51B, the conductive ink printed on the surface of the substrate 11 is heated, if necessary, to dry and/or bake the conductive ink. As a result, the intended first transparent conductive element 1 can be obtained.

Although the method for producing the first transparent conductive element 1 and the second transparent conductive element 2 according to the first embodiment with the printing method has been described here, it is also possible to produce the first transparent conductive element 1 and the second transparent conductive element 2 according to the second to ninth embodiments with the printing method. In this case, it is only necessary to configure the depressed and protruding shapes on the transfer surface of the master 100 so as to be appropriate for the configurations of the first transparent conductive element 1 and the second transparent conductive element 2 according to the second to ninth embodiments. Specifically, it is only necessary to configure the shapes, arrangement, and the like of the transparent electrode portions 13 and 23, the transparent insulating portions 14 and 24, the hole portions 13a and 23a, the conductive portions 13b and 23b, the island portions 14a and 24a, and the gap portions 14b and 24b so as to be appropriate for the first transparent conductive element 1 and the second transparent conductive element 2 according to the second to ninth embodiments.

### [Effects]

According to the tenth embodiment, since the first transparent conductive element 1 and the second transparent conductive element 2 are produced with the printing method, the production steps and production facility therefor can be simplified as compared to the first embodiment.

### 11. Eleventh Embodiment

An electronic apparatus according to the eleventh embodiment includes any of the information input devices 10 according to the first to tenth embodiments in a display unit thereof. An example of the electronic apparatus according to the eleventh embodiment of the present technique will be described below.

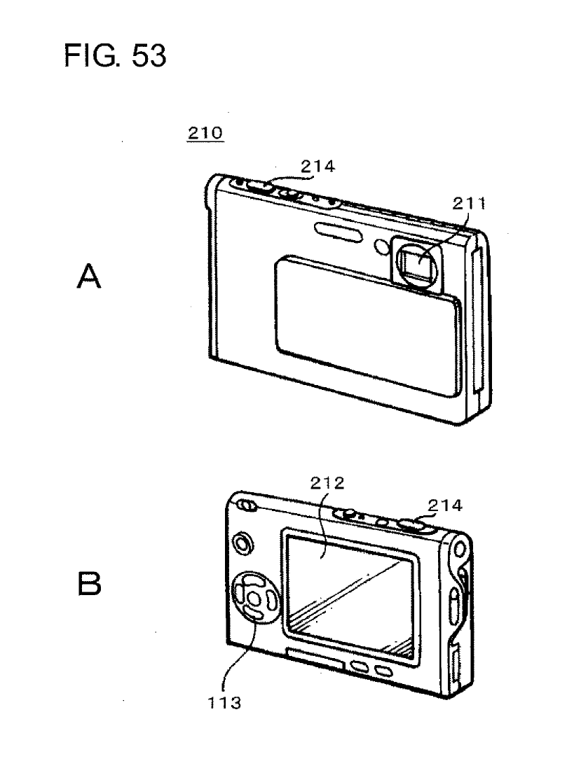

FIG. 52 is an appearance view illustrating a television set 200 as an example of the electronic apparatus. The television set 200 includes a display unit 201 composed of a front panel 202, a filter glass 203, etc. The television set 200 further includes any of the information input devices 10 according to the first to tenth embodiments in the display unit 201.

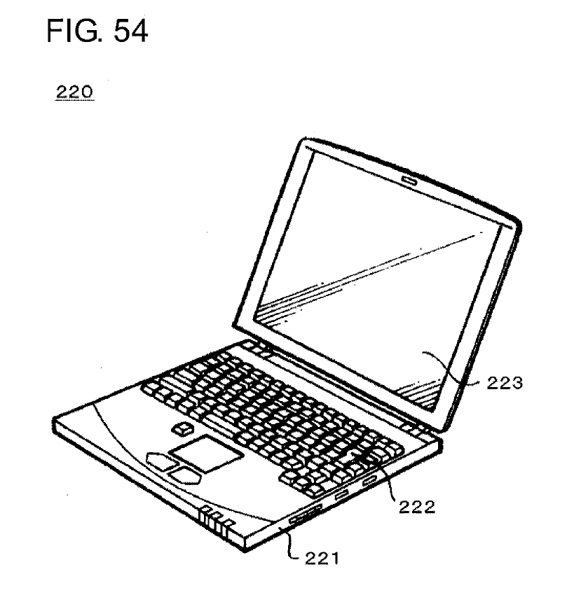

FIGS. 53A and 53B are each an appearance view illustrating a digital camera as an example of the electronic apparatus. FIG. 53A is the appearance view when the digital camera is viewed from the front side thereof. FIG. 53B is the appearance view when the digital camera is viewed from the back side thereof. A digital camera 210 includes a flash light-emitting unit 211, a display unit 212, a menu switch 213, a shutter button 214, etc. The digital camera 210 includes any of the information input devices 10 according to the first to tenth embodiments in the display unit 212.

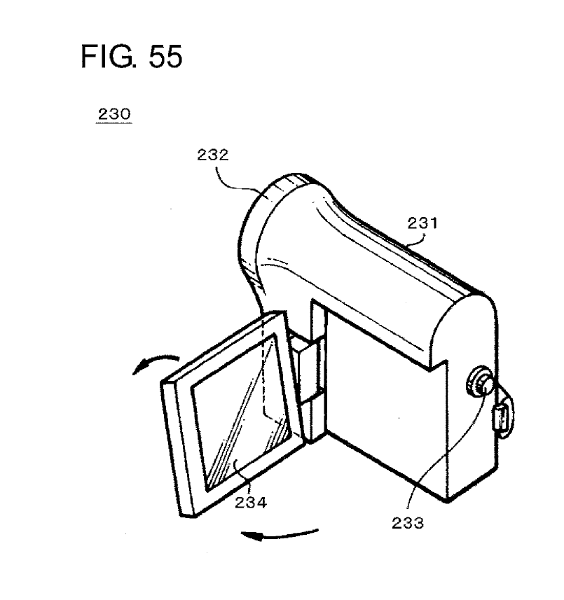

FIG. 54 is an appearance view illustrating a notebook-type personal computer as an example of the electronic apparatus. A notebook-type personal computer 220 includes a main body 221, a keyboard 222 to be operated when inputting characters and the like, a display unit 223 for displaying an image, etc. The notebook-type personal computer 220 includes any of the information input devices 10 according to the first to tenth embodiments in the display unit 223.

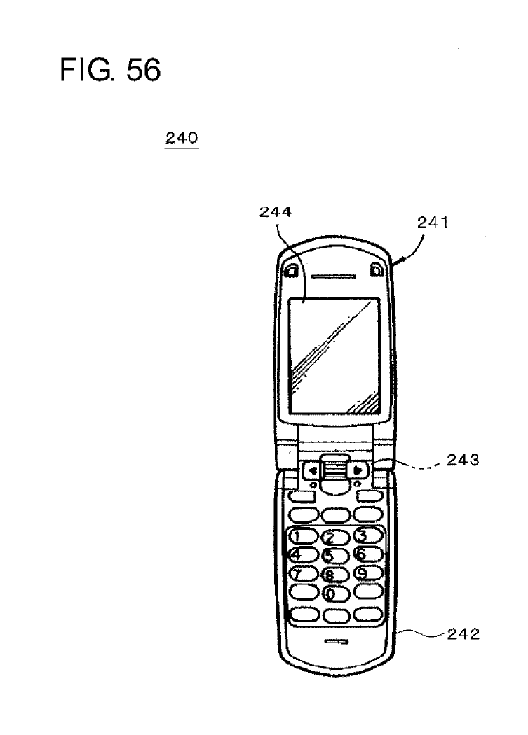

FIG. 55 is an appearance view illustrating a video camera as an example of the electronic apparatus. A video camera 230 includes a main body unit 231, a lens 232 for capturing an object, which is provided on a front-facing side surface, a filming start/stop switch 233, a display unit 234, etc. The video camera 230 includes any of the information input devices 10 according to the first to tenth embodiments in the display unit 234.

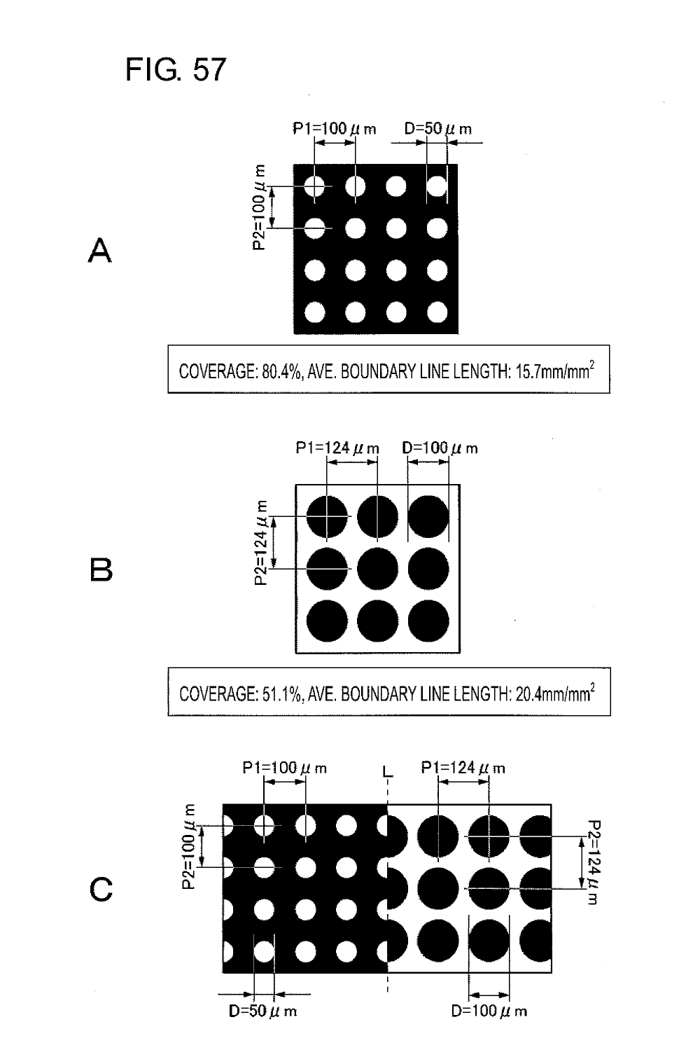

FIG. 56 is an appearance view illustrating a mobile terminal device 240 as an example of the electronic apparatus. The mobile terminal device is a mobile phone, for example, and includes an upper casing 241, a lower casing 242, a coupling unit (herein, hinge unit) 243, and a display unit 244. The mobile terminal device includes any of the information input devices 10 according to the first to tenth embodiments in the display unit 244.

### [Effects]

Since the above-described electronic apparatuses according to the eleventh embodiment include any of the information input devices 10 according to the first to tenth embodiments, the visual recognition of the information input device 10 in the display unit can be restrained.

### EXAMPLES

Although the present technique will be described specifically by way of examples, the present technique is not limited to these examples only.

### Example 1-1

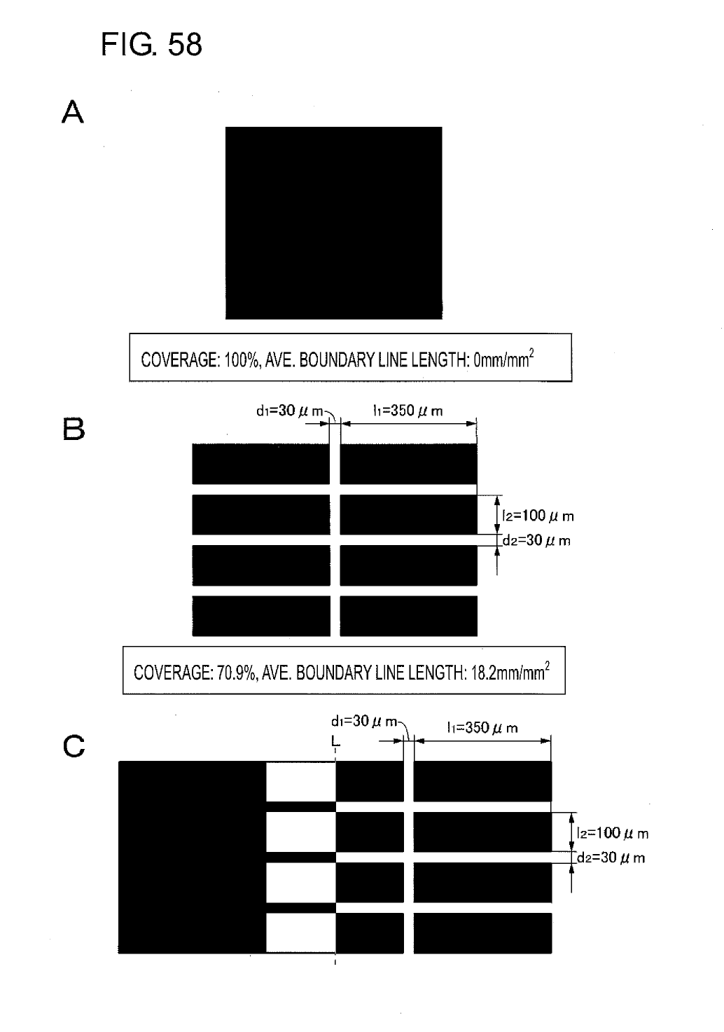

FIG. 57A is a plan view illustrating a portion of an X electrode portion in Example 1-1 in an enlarged manner. FIG. 57B is a plan view illustrating a portion of an insulating portion in Example 1-1 in an enlarged manner. FIG. 57C is a plan view illustrating a portion of a boundary portion between the X electrode portion and the insulating portion in Example 1-1 in an enlarged manner. A transparent conductive sheet having the X electrode portion, the insulating portion, and the boundary portion illustrated in FIGS. 57A to 57C was produced as follows. In FIGS. 57A to 57C, the portion painted black indicates a portion where an ITO layer (transparent conductive layer) is provided and the portion not painted black indicates a portion where no ITO layer (transparent conductive layer) is provided and a sheet (substrate) surface is exposed. Similarly in the following FIGS. 58A to 62C, the portion painted black indicates a portion where an ITO layer (transparent conductive layer) is provided and the portion not painted black indicates a portion where no ITO layer (transparent conductive layer) is provided and a sheet (substrate) surface is exposed.

First, an ITO layer was formed on the surface of a PET sheet with a thickness of 125 μm with a sputtering method to obtain a transparent conductive sheet. Next, the sheet resistance of this transparent conductive sheet was measured with a four-probe method. As a measuring device therefor, Loresta EP Model MCP-T360 manufactured by Mitsubishi Chemical Analytech Co., Ltd. was used. As a result, the sheet resistance was 150Ω/□. Next, after forming a resist layer on the ITO layer of the transparent conductive sheet, the resist layer was exposed with a Cr photomask used. As this Cr photomask, one including an X electrode portion forming region for forming the X electrode portion and an insulating portion forming region for forming the insulating portion between the X electrode portions was used. In the X electrode portion forming region, a regular and circular opening pattern was provided. In the insulating portion forming region, a regular and circular light-shielding portion pattern was provided. At the boundary portion between both the regions, a regular pattern shape was provided. Specifically, the circular opening in the X electrode portion forming region was cut in half to obtain a semicircular shape and the circular light-shielding portion in the insulating portion forming region was cut in half to obtain a semicircular shape in a boundary L between both the regions.

Next, the resist layer was developed to form a resist pattern and the ITO layer was subjected to wet etching with this resist pattern used as a mask. Thereafter, the resist layer was removed by an ashing treatment. As a result, the X electrode portion, the insulating portion, and the boundary portion illustrated in FIGS. 57A to 57C were obtained. From the above, the transparent conductive sheet as an X electrode sheet was obtained.

### Example 1-2

As a Cr photomask, one including a Y electrode portion forming region for forming a Y electrode portion and an insulating portion forming region provided between the Y electrode portion forming regions was used. A pattern of openings in the Y electrode portion forming region, a pattern of light-shielding portions in the insulating portion forming region, and a pattern shape in a boundary portion between both the regions were set to be the same as those in Example 1-1. In the same manner as in Example 1-1 except for these points, a transparent conductive sheet as a Y electrode sheet was obtained.

### Example 1-3

The transparent conductive sheet (X electrode sheet) of Example 1-1 and the transparent conductive sheet (Y electrode sheet) of Example 1-2 were overlapped with each other via an adhesive layer. At this time, they were disposed in such a manner that the X electrode portion of the transparent conductive sheet in Example 1-1 and the PET sheet of the transparent conductive sheet in Example 1-2 face each other. From the above, a transparent conductive layered sheet was obtained.

### Example 2-1

FIG. 58A is a plan view illustrating a portion of an X electrode portion in Example 2-1 in an enlarged manner. FIG. 58B is a plan view illustrating a portion of an insulating portion in Example 2-1 in an enlarged manner. FIG. 58C is a plan view illustrating a portion of a boundary portion between the X electrode portion and the insulating portion in Example 2-1 in an enlarged manner. A transparent conductive sheet having the X electrode portion, the insulating portion, and the boundary portion illustrated in FIGS. 58A to 58C was produced as follows.

As a Cr photomask, one including an X electrode portion forming region for forming the X electrode portion and an insulating portion forming region provided between the X electrode portion forming regions was used. In the X electrode portion forming region, a light-shielding portion for light-shielding the entire X electrode portion forming region was provided without providing an opening pattern. In the insulating portion forming region, a regular and rectangular light-shielding portion pattern was provided. At a boundary portion between both the regions, a regular pattern shape was provided. Specifically, a rectangular inverting portion where a hole portion is inverted into an island portion with a boundary L used as a dividing line was provided. The rectangular shape of the inverting portion and the rectangular shape of the light-shielding portion in the insulating portion forming region were set to have the same shape. In the same manner as in Example 1-1 except for these points, the transparent conductive sheet as an X electrode sheet having the X electrode portion, the insulating portion, and the boundary portion illustrated in FIGS. 58A to 58C was obtained.

### Example 2-2

As a Cr photomask, one including a Y electrode portion forming region for forming a Y electrode portion and an insulating portion forming region provided between the Y electrode portion forming regions was used. Patterns of a light-shielding portion in the Y electrode portion forming region and a light-shielding portion in the insulating portion forming region and a pattern shape in a boundary portion between both the regions were set to be the same as those in Example 2-1. In the same manner as in Example 2-1 except for these points, a transparent conductive sheet as a Y electrode sheet was obtained.

### Example 2-3

The transparent conductive sheet (X electrode sheet) of Example 2-1 and the transparent conductive sheet (Y electrode sheet) of Example 2-2 were overlapped with each other via an adhesive layer. At this time, they were disposed in such a manner that the X electrode portion of the transparent conductive sheet in Example 2-1 and the PET sheet of the transparent conductive sheet in Example 2-2 face each other. From the above, a transparent conductive layered sheet was obtained.

### Example 3-1

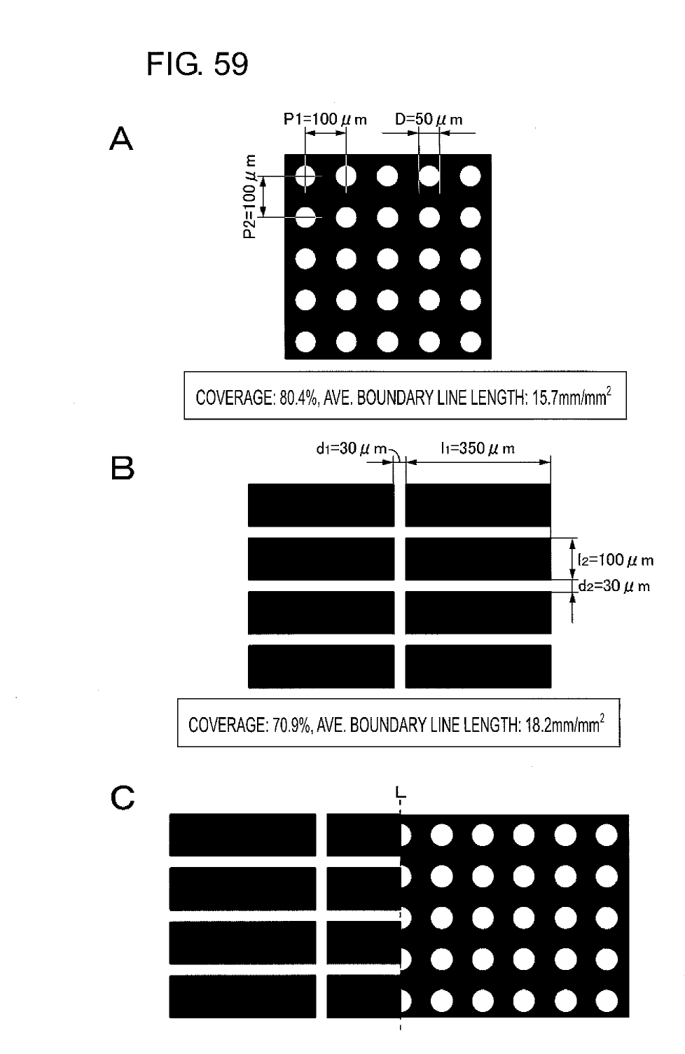

FIG. 59A is a plan view illustrating a portion of an X electrode portion in Example 3-1 in an enlarged manner. FIG. 59B is a plan view illustrating a portion of an insulating portion in Example 3-1 in an enlarged manner. FIG. 59C is a plan view illustrating a portion of a boundary portion between the X electrode portion and the insulating portion in Example 3-1 in an enlarged manner. A transparent conductive sheet having the X electrode portion, the insulating portion, and the boundary portion illustrated in FIGS. 59A to 59C was produced as follows.

As a Cr photomask, one including an X electrode portion forming region for forming the X electrode portion and an insulating portion forming region provided between the X electrode portion forming regions was used. In the X electrode portion forming region, a regular and circular opening pattern was provided. In the insulating portion forming region, a regular and rectangular light-shielding portion pattern was provided. At a boundary portion between both the regions, a regular pattern shape was provided. Specifically, the circular opening in the X electrode portion forming region was cut in half to obtain a semicircular shape and the rectangular light-shielding portion in the insulating portion forming region was cut in half at the position of the midpoint of a longer side thereof to obtain a semi-rectangular shape in a boundary L between both the regions. In the same manner as in Example 1-1 except for these points, the transparent conductive sheet as an X electrode sheet having the X electrode portion, the insulating portion, and the boundary portion illustrated in FIGS. 59A to 59C was obtained.

### Example 3-2

As a Cr photomask, one including a Y electrode portion forming region for forming a Y electrode portion and an insulating portion forming region provided between the Y electrode portion forming regions was used. A pattern of openings in the Y electrode portion forming region, a pattern of light-shielding portions in the insulating portion forming region, and a pattern shape in a boundary portion between both the regions were set to be the same as those in Example 3-1. In the same manner as in Example 3-1 except for these points, a transparent conductive sheet as a Y electrode sheet was obtained.

### Example 3-3

The transparent conductive sheet (X electrode sheet) of Example 3-1 and the transparent conductive sheet (Y electrode sheet) of Example 3-2 were overlapped with each other via an adhesive layer. At this time, they were disposed in such a manner that the X electrode portion of the transparent conductive sheet in Example 3-1 and the PET sheet of the transparent conductive sheet in Example 3-2 face each other. From the above, a transparent conductive layered sheet was obtained.

### Examples 4-1 to 4-3

A silver nanowire layer was formed on the surface of a PET sheet with a thickness of 125 μm with a coating method to obtain a transparent conductive film. Next, the sheet resistance of this transparent conductive sheet was measured with a four-probe method. As a measuring device therefor, Loresta EP Model MCP-T360 manufactured by Mitsubishi Chemical Analytech Co., Ltd. was used. As a result, the sheet resistance was 130Ω/□. In the same manner as in Examples 1-1 to 1-3 except for these points, transparent conductive films and a transparent conductive layered sheet were obtained.

### Examples 5-1 to 5-3

A silver nanowire layer was formed on the surface of a PET sheet with a thickness of 125 μm with a coating method to obtain a transparent conductive film. In the same manner as in Examples 2-1 to 2-3 except for this point, transparent conductive films and a transparent conductive layered sheet were obtained.

### Examples 6-1 to 6-3

A silver nanowire layer was formed on the surface of a PET sheet with a thickness of 125 μm with a coating method to obtain a transparent conductive film. In the same manner as in Examples 3-1 to 3-3 except for this point, transparent conductive films and a transparent conductive layered sheet were obtained.

### Comparative Example 1-1

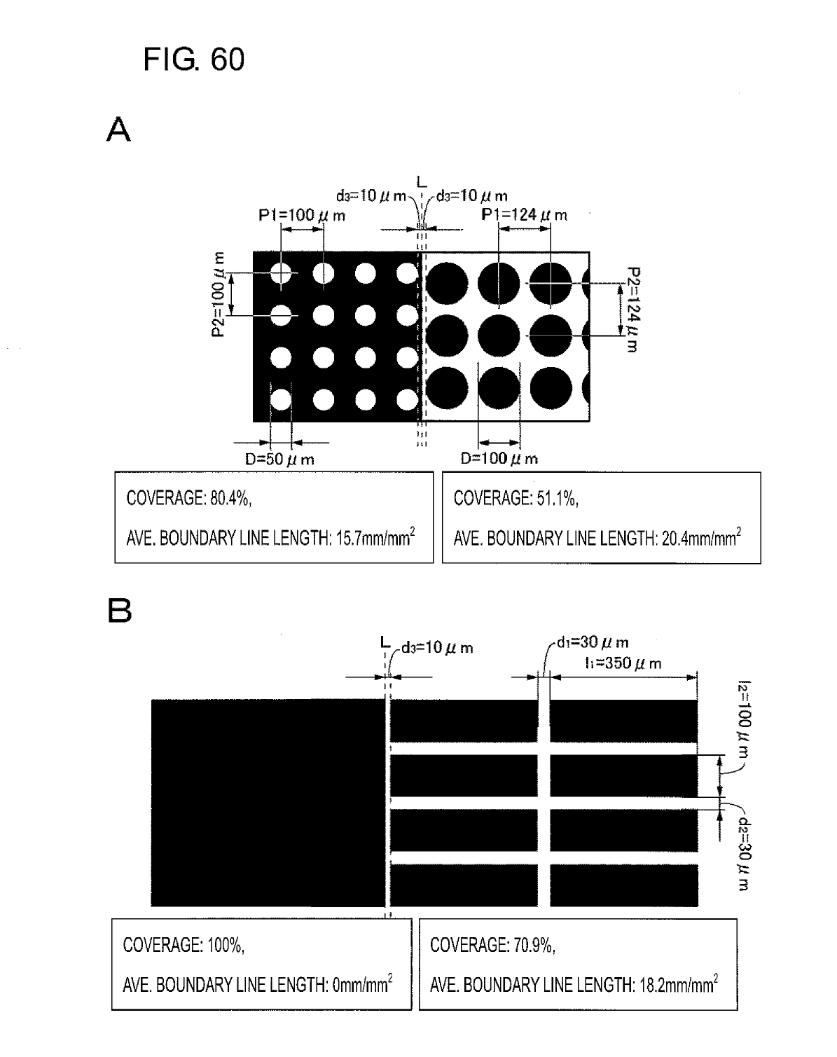

FIG. 60A is a plan view illustrating a portion of a boundary portion between an X electrode portion and an insulating portion in Comparative Example 1-1 in an enlarged manner. A transparent conductive sheet having the boundary portion illustrated in FIG. 60A was produced as follows.

At a boundary portion between an X electrode portion forming region and an insulating portion forming region, no regular pattern shape was provided. Specifically, a circular opening in the X electrode portion forming region and a circular light-shielding portion in the insulating portion forming region were spaced apart from a boundary L between both the regions by 10 μm. In the same manner as in Example 1-1 except for this point, the transparent conductive sheet as an X electrode sheet having the boundary portion illustrated in FIG. 60A was obtained.

### Comparative Example 1-2

A shape of a boundary portion between a Y electrode portion forming region and an insulating portion forming region was set to be the same as that in Comparative Example 1-1. In the same manner as in Example 1-2 except for this point, a transparent conductive sheet as a Y electrode sheet was obtained.

### Comparative Example 1-3

The transparent conductive sheet (X electrode sheet) of Comparative Example 1-1 and the transparent conductive sheet (Y electrode sheet) of Comparative Example 1-2 were overlapped with each other via an adhesive layer. At this time, they were disposed in such a manner that the X electrode portion of the transparent conductive sheet in Comparative Example 1-1 and the PET sheet of the transparent conductive sheet in Comparative Example 1-2 face each other. From the above, a transparent conductive layered sheet was obtained.

### Comparative Examples 1-4 to 1-6

A circular opening in an X electrode portion forming region and a circular light-shielding portion in an insulating portion forming region were spaced apart from a boundary L by 2 μm. In the same manner as in Comparative Examples 1-1 to 1-3 except for this point, transparent conductive films and a transparent conductive layered sheet were obtained.

### Comparative Example 2-1

At a boundary portion between an X electrode portion forming region and an insulating portion forming region, no regular pattern shape was provided. Specifically, a circular opening in the X electrode portion forming region and a rectangular light-shielding portion in the insulating portion forming region were spaced apart from a boundary L between both the regions by 10 μm. In the same manner as in Example 6-1 except for this point, a transparent conductive sheet as an X electrode sheet was obtained.

### Comparative Example 2-2

A shape of a boundary portion between a Y electrode portion forming region and an insulating portion forming region was set to be the same as that in Comparative Example 2-1. In the same manner as in Example 6-2 except for this point, a transparent conductive sheet as a Y electrode sheet was obtained.

### Comparative Example 2-3

The transparent conductive sheet (X electrode sheet) of Comparative Example 2-1 and the transparent conductive sheet (Y electrode sheet) of Comparative Example 2-2 were overlapped with each other via an adhesive layer. At this time, they were disposed in such a manner that the X electrode portion of the transparent conductive sheet in Comparative Example 2-1 and the PET sheet of the transparent conductive sheet in Comparative Example 2-2 face each other. From the above, a transparent conductive layered sheet was obtained.

### Comparative Examples 2-4 to 2-6

A circular opening in an X electrode portion forming region and a rectangular light-shielding portion in an insulating portion forming region were spaced apart from a boundary L by 2 μm. In the same manner as in Comparative Examples 2-1 to 2-3 except for this point, transparent conductive films and a transparent conductive layered sheet were obtained.

### Comparative Example 3-1

FIG. 60B is a plan view illustrating a portion of a boundary portion between an X electrode portion and an insulating portion in Comparative Example 3-1 in an enlarged manner. A transparent conductive sheet having the boundary portion illustrated in FIG. 60B was produced as follows.

At a boundary portion between an X electrode portion forming region and an insulating portion forming region, no regular pattern shape was provided. Specifically, a rectangular light-shielding portion in the insulating portion forming region was spaced apart from a boundary L between both the regions by 10 μm. In the same manner as in Example 5-1 except for this point, the transparent conductive sheet as an X electrode sheet having the boundary portion illustrated in FIG. 60B was obtained.

### Comparative Example 3-2

A shape of a boundary portion between a Y electrode portion forming region and an insulating portion forming region was set to be the same as that in Comparative Example 3-1. In the same manner as in Example 5-2 except for this point, a transparent conductive sheet as a Y electrode sheet was obtained.

### Comparative Example 3-3

The transparent conductive sheet (X electrode sheet) of Comparative Example 3-1 and the transparent conductive sheet (Y electrode sheet) of Comparative Example 3-2 were overlapped with each other via an adhesive layer. At this time, they were disposed in such a manner that the X electrode portion of the transparent conductive sheet in Comparative Example 3-1 and the PET sheet of the transparent conductive sheet in Comparative Example 3-2 face each other. From the above, a transparent conductive layered sheet was obtained.

### Comparative Examples 3-4 to 3-6

A rectangular light-shielding portion in an insulating portion forming region was spaced apart from a boundary L by 2 μm. In the same manner as in Comparative Examples 3-1 to 3-3 except for this point, transparent conductive films and a transparent conductive layered sheet were obtained.

### (Reflection L Value)

With a black tape being attached to a side of the transparent conductive sheet where the transparent electrode portion and the transparent insulating portion were formed, a measurement was performed in accordance with JIS 28722 with Color i5 manufactured by X-Rite Inc. from a side opposite to the side where the black tape was attached to. This measurement was performed at 5 positions randomly selected from the transparent electrode portion of the transparent conductive sheet. The measured values were simply averaged (arithmetic average) to obtain an average reflection L value in the transparent electrode portion. The same measurements were performed also for the transparent insulating portion of the transparent conductive sheet to obtain an average reflection L value in the transparent insulating portion. The results are shown in Table 3.

(Absolute Value of Difference between Reflection L Values)

The absolute values of differences between the reflection L values were obtained by substituting the reflection L values obtained in the evaluation of the above-described “Reflection L Value” into the following expression. The results are shown in Table 3.

Absolute value of difference between reflection L values=|(reflection L value in transparent electrode portion)−(reflection L value in transparent insulating portion)|

### (Optical Property)

For the transparent conductive sheets obtained as described above, non-visibility of the transparent electrode portion, glare, and moire and interfering light were evaluated as follows. First, the transparent conductive sheet was adhered onto a liquid crystal display with a diagonal of 3.5 inches via an adhesive sheet in such a manner that the surface of the transparent conductive sheet on the ITO side or the silver wire side faces a screen. Next, an AR film was adhered to the substrate (PET sheet) side of the transparent conductive sheet via an adhesive sheet. Thereafter, black screen or green screen was displayed by the liquid crystal display. By visually observing the display surface, non-visibility, glare, and moire and interfering light were evaluated. The results are shown in Tables 3 and 5.

Evaluation criteria for non-visibility, glare, and moire and interfering light are listed below.

### <Non-Visibility>

A: Pattern cannot be visually recognized at all when viewed from any angle.
B: Pattern is very hard to be visually recognized but visually recognizable depending on an angle.
C: Visually recognizable.

### <Glare>

A: No glare is sensed when observed from any angle.
B: No glare is sensed when observed from the front but glare is slightly sensed when observed obliquely.
C: Glare is sensed when observed from the front.

### <Moire and Interfering Light>

A: No moire and interfering light are sensed when observed from any angle.
B: No moire and interfering light are sensed when observed from the front but moire and interfering light are slightly sensed when observed obliquely.
C: Moire and interfering light are sensed when observed from the front.

Table 2 shows the configurations of the transparent conductive sheets according to Examples 1-1 to 6-3.

TABLE 2

| | | | | | | Nearest- | | Conductive | | Average | Ratio of | |
|---|---|---|---|---|---|---|---|---|---|---|---|---|
| | | | | Pattern | | neighbor | Minimum | material | | boundary | average | Boundary portion |
| | | Conductive | | | Size | distance | pitch | coverage | Coverage | line length | boundary line | Electrode portion side/Insulating |
| Example | Electrode | material | Region | Pattern shape | [μm] | [μm] | [μm] | (%) | difference (%) | (mm/mm²) | lengths | portion side |
| 1-1 | X | ITO | Electrode portion | Circle | Diameter 50 | 50 | 100 | 80 | 29 | 16 | 0.8 | Semicircle/Semicircle |
| | | | Insulating portion | Circle | Diameter 100 | 24 | 124 | 51 | | 20 | | |
| 1-2 | Y | ITO | Electrode portion | Circle | Diameter 50 | 50 | 100 | 80 | 29 | 16 | 0.8 | Semicircle/Semicircle |
| | | | Insulating portion | Circle | Diameter 100 | 24 | 124 | 51 | | 20 | | |
| 1-3 | X + Y | — | — | — | — | — | — | — | 58 at maximum | — | — | — |
| 2-1 | X | ITO | Electrode portion | Without pattern | — | — | — | 100 | 29 | 0 | — | Semi-rectangle/Semi-rectangle |
| | | | Insulating portion | Rectangle | 100 × 350 | 30 | 130 | 71 | | 18 | | (Inverting portion) |
| 2-2 | Y | ITO | Electrode portion | Without pattern | — | — | — | 100 | 29 | 0 | — | Semi-rectangle/Semi-rectangle |
| | | | Insulating portion | Rectangle | 100 × 350 | 30 | 130 | 71 | | 18 | | (Inverting portion) |
| 2-3 | X + Y | — | — | — | — | — | — | — | 58 at maximum | | — | — |
| 3-1 | X | ITO | Electrode portion | Circle | Diameter 50 | 50 | 100 | 80 | 9 | 16 | 0.89 | Semicircle/Semi-rectangle |
| | | | Insulating portion | Rectangle | 100 × 350 | 30 | 130 | 71 | | 18 | | |
| 3-2 | Y | ITO | Electrode portion | Circle | Diameter 50 | 50 | 100 | 80 | 9 | 16 | 0.89 | Semicircle/Semi-rectangle |
| | | | Insulating portion | Rectangle | 100 × 350 | 30 | 130 | 71 | | 18 | | |
| 3-3 | X + Y | — | — | — | — | — | — | — | 18 at maximum | — | — | — |
| 4-1 | X | Ag nanowire | Electrode portion | Circle | Diameter 50 | 50 | 100 | 80 | 29 | 16 | 0.8 | Semicircle/Semicircle |
| | | | Insulating portion | Circle | Diameter 100 | 24 | 124 | 51 | | 20 | | |
| 4-2 | Y | Ag nanowire | Electrode portion | Circle | Diameter 50 | 50 | 100 | 80 | 29 | 16 | 0.8 | Semicircle/Semicircle |
| | | | Insulating portion | Circle | Diameter 100 | 24 | 124 | 51 | | 20 | | |
| 4-3 | X + Y | — | — | — | — | — | — | — | 58 at maximum | — | — | — |
| 5-1 | X | Ag nanowire | Electrode portion | Without pattern | Without processing | — | — | 100 | 29 | 0 | — | Semi-rectangle/Semi-rectangle |
| | | | Insulating portion | Rectangle | 100 × 350 | 30 | 130 | 71 | | 18 | | (Inverting portion) |
| 5-2 | Y | Ag nanowire | Electrode portion | Without pattern | Without processing | — | — | 100 | 29 | 0 | — | Semi-rectangle/Semi-rectangle |
| | | | Insulating portion | Rectangle | 100 × 350 | 30 | 130 | 71 | | 18 | | (Inverting portion) |
| 5-3 | X + Y | — | — | — | — | — | — | — | 58 at maximum | — | — | — |
| 6-1 | X | Ag nanowire | Electrode portion | Circle | Diameter 50 | 50 | 100 | 80 | 9 | 16 | 0.89 | Semicircle/Semi-rectangle |
| | | | Insulating portion | Rectangle | 100 × 350 | 30 | 130 | 71 | | 18 | | |
| 6-2 | Y | Ag nanowire | Electrode portion | Circle | Diameter 50 | 50 | 100 | 80 | 9 | 16 | 0.89 | Semicircle/Semi-rectangle |
| | | | Insulating portion | Rectangle | 100 × 350 | 30 | 130 | 71 | | 18 | | |
| 6-3 | X + Y | — | — | — | — | — | — | — | 18 at maximum | — | — | — |

Semicircle: half of circle (pattern shape) in electrode portion or insulating portion,
Semi-rectangle: half of rectangle (pattern shape) in electrode portion or insulating portion

Table 3 shows the evaluation results of the transparent conductive sheets according to Examples 1-1 to 6-3

TABLE 3

| | Reflection | Absolute value of | | Moire/ | |
|---|---|---|---|---|---|
| | L | reflection L value | Non- | Interfering | |
| Example | value | difference | visibility | light | Glare |
| 1-1 | 5.9 | 0.2 | A | A | A |
| | 6.1 | | | | |
| 1-2 | 5.9 | 0.2 | A | A | A |
| | 6.1 | | | | |
| 1-3 | — | — | B | A | A |
| 2-1 | 5.9 | 0 | A | A | A |
| | 5.9 | | | | |
| 2-2 | 5.9 | 0 | A | A | A |
| | 5.9 | | | | |
| 2-3 | — | — | B | A | A |
| 3-1 | 5.9 | 0 | A | A | A |
| | 5.9 | | | | |
| 3-2 | 5.9 | 0 | A | A | A |
| | 5.9 | | | | |
| 3-3 | — | — | A | A | A |
| 4-1 | 9.4 | 0.2 | A | A | A |
| | 9.2 | | | | |
| 4-2 | 9.4 | 0.2 | | | |
| | 9.2 | | | | |
| 4-3 | — | — | B | A | A |
| 5-1 | 9.5 | 0.2 | A | A | A |
| | 9.3 | | | | |
| 5-2 | 9.5 | 0.2 | A | A | A |
| | 9.3 | | | | |
| 5-3 | — | — | B | A | A |
| 6-1 | 9.4 | 0.1 | A | A | A |
| | 9.3 | | | | |
| 6-2 | 9.4 | 0.1 | A | A | A |
| | 9.3 | | | | |
| 6-3 | — | — | A | A | A |

Table 4 shows the configurations of the transparent conductive sheets according to Comparative Examples 1-1 to 3-6.

TABLE 4

| | | | | | | Nearest- | | | | Average | | |
|---|---|---|---|---|---|---|---|---|---|---|---|---|
| | | | | Pattern | | neighbor | Minimum | Conductive | | boundary line | Ratio of average | Boundary portion |
| | | Conductive | | | Size | distance | pitch | material | Coverage | length | boundary line | Electrode portion side/ |
| Example | Electrode | material | Region | Pattern shape | [μm] | [μm] | [μm] | coverage (%) | difference (%) | (mm/mm²) | lengths | Insulating portion side |
| 1-1 | X | ITO | Electrode portion | Circle | Diameter 50 | 50 | 100 | 80 | 29 | 16 | 0.8 | Width 10 μm/ |
| | | | | | | | | | | | | Width 10 μm |
| | | | Insulating portion | Circle | Diameter 100 | 24 | 124 | 51 | | 20 | | |
| 1-2 | Y | ITO | Electrode portion | Circle | Diameter 50 | 50 | 100 | 80 | 29 | 16 | 0.8 | Width 10 μm/ |
| | | | | | | | | | | | | Width 10 μm |
| | | | Insulating portion | Circle | Diameter 100 | 24 | 124 | 51 | | 20 | | |
| 1-3 | X + Y | — | — | — | — | — | — | — | 58 at maximum | — | — | — |
| 1-4 | X | ITO | Electrode portion | Circle | Diameter 50 | 50 | 100 | 80 | 29 | 16 | 0.8 | Width 2 μm/ |
| | | | | | | | | | | | | Width 2 μm |
| | | | Insulating portion | Circle | Diameter 100 | 24 | 124 | 51 | | 20 | | |
| 1-5 | Y | ITO | Electrode portion | Circle | Diameter 50 | 50 | 100 | 80 | 29 | 16 | 0.8 | Width 2 μm/ |
| | | | | | | | | | | | | Width 2 μm |
| | | | Insulating portion | Circle | Diameter 100 | 24 | 124 | 51 | | 20 | | |
| 1-6 | X + Y | — | — | — | — | — | — | — | 58 at maximum | — | — | — |
| 2-1 | X | Ag | Electrode portion | Circle | Diameter 50 | 50 | 100 | 80 | 9 | 16 | 0.89 | Width 10 μm/ |
| | | | | | | | | | | | | Width 10 μm |
| | | nanowire | Insulating portion | Rectangle | 100 × 350 | 30 | 130 | 71 | | 18 | | |
| 2-2 | Y | Ag | Electrode portion | Circle | Diameter 50 | 50 | 100 | 80 | 9 | 16 | 0.89 | Width 10 μm/ |
| | | | | | | | | | | | | Width 10 μm |
| | | nanowire | Insulating portion | Rectangle | 100 × 350 | 30 | 130 | 71 | | 18 | | |
| 2-3 | X + Y | — | — | — | — | — | — | — | 18 at maximum | — | — | — |
| 2-4 | X | Ag | Electrode portion | Circle | Diameter 50 | 50 | 100 | 80 | 9 | 16 | 0.89 | Width 2 μm/ |
| | | | | | | | | | | | | Width 2 μm |
| | | nanowire | Insulating portion | Rectangle | 100 × 350 | 30 | 130 | 71 | | 18 | | |
| 2-5 | Y | Ag | Electrode portion | Circle | Diameter 50 | 50 | 100 | 80 | 9 | 16 | 0.89 | Width 2 μm/ |
| | | | | | | | | | | | | Width 2 μm |
| | | nanowire | Insulating portion | Rectangle | 100 × 350 | 30 | 130 | 71 | | 18 | | |
| 2-6 | X + Y | — | — | — | — | — | — | — | 18 at maximum | — | — | — |
| 3-1 | X | Ag | Electrode portion | Without pattern | Without processing | — | — | 100 | 29 | 0 | — | Width 10 μm |
| | | nanowire | Insulating portion | Rectangle | 100 × 350 | 30 | 130 | 71 | | 18 | | |
| 3-2 | Y | Ag | Electrode portion | Without pattern | Without processing | — | — | 100 | 29 | 0 | — | Width 10 μm |
| | | nanowire | Insulating portion | Rectangle | 100 × 350 | 30 | 130 | 71 | | 18 | | |
| 3-3 | X + Y | — | — | — | — | — | — | — | 58 at maximum | — | — | — |
| 3-4 | X | Ag | Electrode portion | Without pattern | Without processing | — | — | 100 | 29 | 0 | — | Width 2 μm |
| | | nanowire | Insulating portion | Rectangle | 100 × 350 | 30 | 130 | 71 | | 18 | | |
| 3-5 | Y | Ag | Electrode portion | Without pattern | Without processing | — | — | 100 | 29 | 0 | — | Width 2 μm |
| | | nanowire | Insulating portion | Rectangle | 100 × 350 | 30 | 130 | 71 | | 18 | | |
| 3-6 | X + Y | — | — | — | — | — | — | — | 58 at maximum | — | — | — |

Table 5 shows the evaluation results of the transparent conductive sheets according to Comparative Examples 1-1 to 3-6.

TABLE 5

| | | Absolute | | | |
|---|---|---|---|---|---|
| | | value of | | | |
| | | reflection L | | Moire/ | |
| Comparative | Reflection L | value | Non- | Interfering | |
| Example | value | difference | visibility | light | Glare |
| 1-1 | 5.9 | 0.2 | C | A | A |
| | 6.1 | | | | |
| 1-2 | 5.9 | 0.2 | C | A | A |
| | 6.1 | | | | |
| 1-3 | — | — | C | A | A |
| 1-4 | 5.9 | 0.2 | C | A | A |
| | 6.1 | | | | |
| 1-5 | 5.9 | 0.2 | C | A | A |
| | 6.1 | | | | |
| 1-6 | — | — | C | A | A |
| 2-1 | 9.4 | 0.1 | C | A | A |
| | 9.3 | | | | |
| 2-2 | 9.4 | 0.1 | C | A | A |
| | 9.3 | | | | |
| 2-3 | — | — | C | A | A |
| 2-4 | 9.4 | 0.1 | C | A | A |
| | 9.3 | | | | |
| 2-5 | 9.4 | 0.1 | C | | |
| | 9.3 | | | | |
| 2-6 | — | — | C | A | A |
| 3-1 | 9.5 | 0.2 | C | A | A |
| | 9.3 | | | | |
| 3-2 | 9.5 | 0.2 | C | A | A |
| | 9.3 | | | | |
| 3-3 | — | — | C | A | A |
| 3-4 | 9.5 | 0.2 | C | A | A |
| | 9.3 | | | | |
| 3-5 | 9.5 | 0.2 | C | A | A |
| | 9.3 | | | | |
| 3-6 | — | — | C | A | A |

The following points can be learned from Tables 2 to 5.

In Examples 1-1 to 6-3 in which a pattern shape was provided in the boundary portion, the visual recognition of the electrode portion can be restrained. In contrast, in Comparative Examples 1-1 to 3-6 in which no pattern was provided in the boundary portion, the electrode portion is visually recognized.

### Example 7

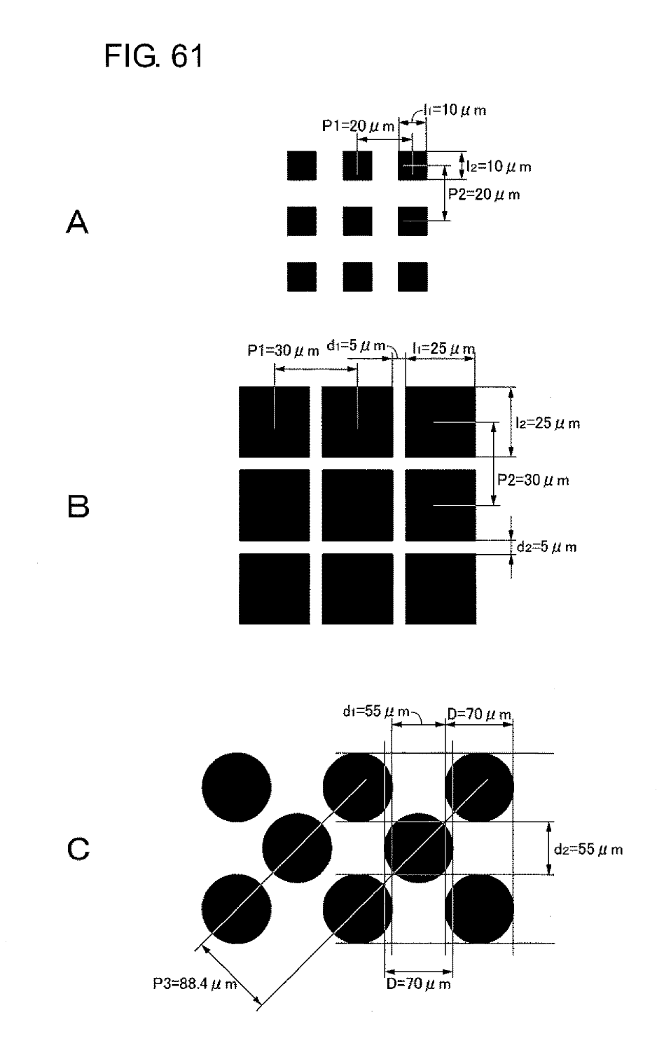

FIG. 61A is a plan view illustrating a portion of an insulating portion according to Example 7 in an enlarged manner. A transparent conductive sheet was obtained in the same manner as in Example 1-1 except that the insulating portion illustrated in FIG. 61A was formed by changing the shape, size, and pitch of the light-shielding portion in the insulating portion forming region of the Cr photomask. A circular opening in an X electrode portion forming region was cut in half to obtain a semicircular shape and a square light-shielding portion in the insulating portion forming region was cut in half at the midpoint of opposing two sides thereof to obtain a semi-square shape in a boundary L between both the regions.

### Example 8

FIG. 61B is a plan view illustrating a portion of an insulating portion according to Example 8 in an enlarged manner. A transparent conductive sheet was obtained in the same manner as in Example 1-1 except that the insulating portion illustrated in FIG. 61B was formed by changing the shape, size, and pitch of the light-shielding portion in the insulating portion forming region of the Cr photomask. A circular opening in an X electrode portion forming region was cut in half to obtain a semicircular shape and a square light-shielding portion in the insulating portion forming region was cut in half at the midpoint of opposing two sides thereof to obtain a semi-square shape in a boundary L between both the regions.

### Example 9

FIG. 61C is a plan view illustrating a portion of an insulating portion according to Example 9 in an enlarged manner. A transparent conductive sheet was obtained in the same manner as in Example 1-1 except that the insulating portion illustrated in FIG. 61C was formed by changing the size and pitch of the light-shielding portion in the insulating portion forming region of the Cr photomask.

### Example 10

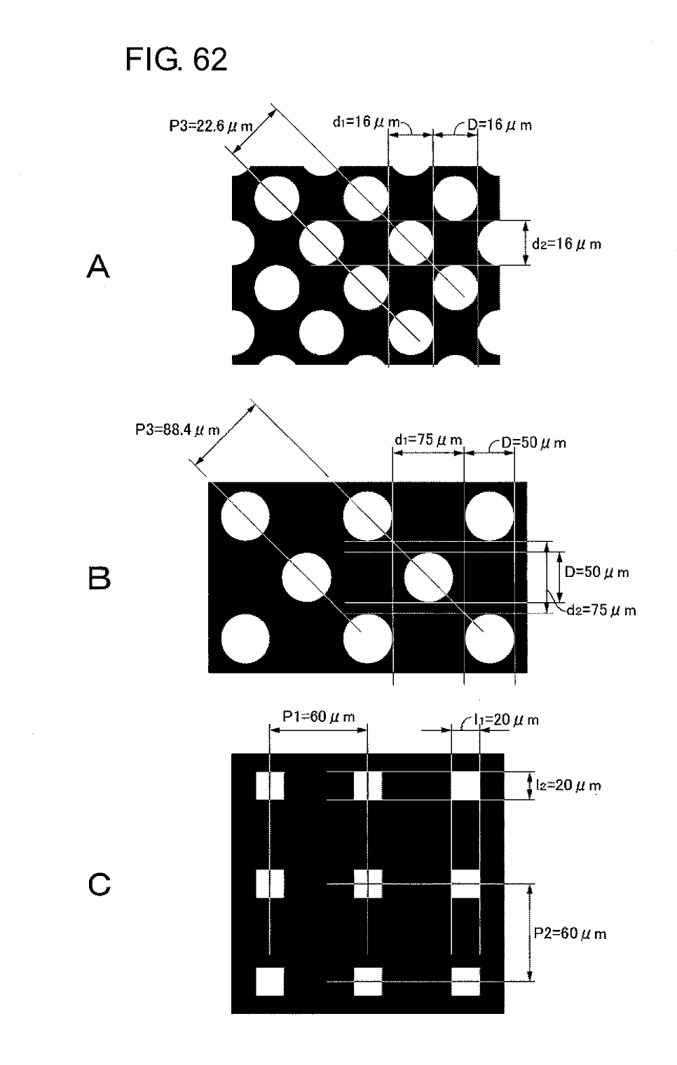

FIG. 62A is a plan view illustrating a portion of an X electrode portion according to Example 10 in an enlarged manner. A transparent conductive sheet was obtained in the same manner as in Example 1-1 except that the X electrode portion illustrated in FIG. 62A was formed by changing the size and pitch of the opening in the X electrode portion forming region of the Cr photomask.

### Example 11

FIG. 62B is a plan view illustrating a portion of an X electrode portion according to Example 11 in an enlarged manner. A transparent conductive sheet was obtained in the same manner as in Example 1-1 except that the X electrode portion illustrated in FIG. 62B was formed by changing the size and pitch of the opening in the X electrode portion forming region of the Cr photomask.

### Example 12

FIG. 62C is a plan view illustrating a portion of an

X electrode portion according to Example 12 in an enlarged manner. A transparent conductive sheet was obtained in the same manner as in Example 1-1 except that the X electrode portion illustrated in FIG. 62C was formed by changing the shape, size, and pitch of the opening in the X electrode portion forming region of the Cr photomask. In a boundary L between both regions, a square opening in the X electrode portion forming region was cut in half at the midpoint of opposing two sides thereof to obtain a semi-square shape and a circular light-shielding portion in the insulating portion forming region was cut in half to obtain a semicircular shape.

### (Moire and Interfering Light)

For the transparent conductive sheets obtained as described above, moire and interfering light were evaluated in the same manner as that for the above-described Examples 1-1 to 6-3. The results are shown in Table 6.

Table 6 shows the evaluation results for the transparent conductive sheets according to Examples 7 to 12.

TABLE 6

| | | | | Pattern | | Minimum | Boundary portion | |
|---|---|---|---|---|---|---|---|---|
| | | Conductive | | Pattern | Size | pitch | Electrode portion side/ | Moire/ |
| Example | Electrode | material | Region | shape | (μm) | (μm) | Insulating portion side | Interfering light |
| 7 | X | ITO | Electrode portion | Circle | Diameter 50 | 100 | Semicircle/Semi-square | A |
| | | | Insulating portion | Square | 10 × 10 | 20 | | C |
| 8 | X | ITO | Electrode portion | Circle | Diameter 50 | 100 | Semicircle/Semi-square | A |
| | | | Insulating portion | Square | 25 × 25 | 30 | | C |
| 9 | X | ITO | Electrode portion | Circle | Diameter 50 | 100 | Semicircle/Semicircle | A |
| | | | Insulating portion | Circle | Diameter 70 | 88.4 | | A |
| 10 | X | ITO | Electrode portion | Circle | Diameter 16 | 22.6 | Semicircle/Semicircle | C |
| | | | Insulating portion | Circle | Diameter 100 | 124 | | A |
| 11 | X | ITO | Electrode portion | Circle | Diameter 50 | 88.4 | Semicircle/Semicircle | A |
| | | | Insulating portion | Circle | Diameter 100 | 124 | | A |
| 12 | X | ITO | Electrode portion | Square | 20 × 20 | 60 | Semicircle/Semi-square | A |
| | | | Insulating portion | Circle | Diameter 100 | 124 | | A |

Semicircle: half of circle (pattern shape) in electrode portion or insulating portion
Semi-square: half of square (pattern shape) in electrode portion or insulating portion

It can be learned from Table 6 that moire and interfering light cannot be sensed when the minimum pitch is greater than 30 μm.

Although the embodiments and examples of the present technique have been described above specifically, the present technique is not limited to the above-described embodiments and examples and various modifications based on the technical concept of the present technique are possible.

For example, the configurations, methods, steps, shapes, materials, numerical values, and the like described in the above-described embodiments and examples are merely examples. If necessary, different configurations, methods, steps, shapes, materials, numerical values, and the like may be used.

Moreover, the configurations, methods, steps, shapes, materials, numerical values, and the like of the above-described embodiments and examples can be combined with one another without departing from the spirit of the present technique.

Moreover, in the above-described embodiments and examples, such a configuration that the shape pattern in the boundary portion is provided so as to be different from the patterns of the hole portions of the transparent electrode portion and the island portions of the transparent insulating portion may be employed.

Moreover, in the above-described embodiments and examples, such a configuration that the shape pattern in the boundary portion includes a shape other than those of the hole portions of the transparent electrode portion and the island portions of the transparent insulating portion may be employed.

Moreover, the present technique may employ the following configurations.

(1)

A transparent conductive element including:

a substrate having a surface; and

a transparent conductive portion and a transparent insulating portion provided alternately in a planar manner on the surface, wherein

at least one of the transparent conductive portion and the transparent insulating portion is a transparent conductive layer having a regular pattern therein, and

a shape pattern is provided in a boundary portion between the transparent conductive portion and the transparent insulating portion.

(2)

The transparent conductive element according to (1), wherein

a pattern in the transparent conductive portion is a pattern of a plurality of hole portions,

a pattern in the transparent insulating portion is a pattern of a plurality of island portions, and

the shape pattern in the boundary portion includes one or more selected from the group consisting of a whole of the hole portion, part of the hole portion, a whole of the island portion, and part of the island portion.

(3)

The transparent conductive element according to (2), wherein the whole of the island portion and the whole of the hole portion included in the shape pattern in the boundary portion are provided in contact with a boundary between the transparent conductive portion and the transparent insulating portion.

(4)

The transparent conductive element according to (2) or (3), wherein the part of the hole portion and the part of the island portion included in the shape pattern in the boundary portion have shapes such that the hole portion and the island portion are partially cut by the boundary between the transparent conductive portion and the transparent insulating portion, respectively.

(5)

The transparent conductive element according to any one of (2) to (4), wherein

both of the pattern of the plurality of hole portions and the pattern of the plurality of island portions are regular patterns, and

the shape pattern in the boundary portion is a regular shape pattern.

(6)

The transparent conductive element according to any one of (2) to (4), wherein

one of the pattern of the plurality of hole portions and the pattern of the plurality of island portions is a regular pattern, whereas the other one thereof is a random pattern, and

the shape pattern in the boundary portion is a random shape pattern.

(7)

The transparent conductive element according to any one of (2) to (6), wherein the hole portion and the island portion each have a dot shape.

(8)

The transparent conductive element according to any one of (2) to (6), wherein the hole portion has a dot shape and a gap portion between the island portions has a mesh shape.

(9)

The transparent conductive element according to (1), wherein

a pattern in the transparent conductive portion is a pattern of a plurality of hole portions,

a pattern in the transparent insulating portion is a pattern of a plurality of island portions, and

the shape pattern in the boundary portion includes a plurality of inverting portions in which the hole portions are inverted into the island portions.

(10)

The transparent conductive element according to (1), wherein

the transparent conductive portion is a transparent conductive layer continuously provided on the surface,

the transparent insulating portion is a transparent conductive layer having a plurality of island portions provided on the surface with a regular pattern, and

the shape pattern in the boundary portion includes one or more selected from the group consisting of a whole of the island portion and part of the island portion.

(11)

The transparent conductive element according to any one of (1) to (10), wherein average boundary line lengths in the transparent conductive portion and the transparent insulating portion are smaller than or equal to 20 mm/mm².

(12)

The transparent conductive element according to any one of (1) to (10), wherein an absolute value of a difference between reflection L values in the transparent conductive portion and in the transparent insulating portion is smaller than 0.3.

(13)

An input device including:

a substrate having a first surface and a second surface; and

a transparent conductive portion and a transparent insulating portion provided alternately in a planar manner on the first surface and the second surface, wherein

at least one of the transparent conductive portion and the transparent insulating portion is a transparent conductive layer having a regular pattern therein, and

a shape pattern is provided in a boundary portion between the transparent conductive portion and the transparent insulating portion.

(14)

An input device including:

a first transparent conductive element; and

a second transparent conductive element provided on

a surface of the first transparent conductive element, wherein

the first transparent conductive element and the second transparent conductive element each include:
a substrate having a surface; and
a transparent conductive portion and a transparent insulating portion provided alternately in a planar manner on the surface,

at least one of the transparent conductive portion and the transparent insulating portion is a transparent conductive layer having a regular pattern therein, and

a shape pattern is provided in a boundary portion between the transparent conductive portion and the transparent insulating portion.

(15)

An electronic apparatus including a transparent conductive element having: a substrate having a first surface and a second surface; and a transparent conductive portion and a transparent insulating portion provided alternately in a planar manner on the first surface and the second surface, wherein

at least one of the transparent conductive portion and the transparent insulating portion is a transparent conductive layer having a regular pattern therein, and

a shape pattern is provided in a boundary portion between the transparent conductive portion and the transparent insulating portion.

(16)

An electronic apparatus including:

a first transparent conductive element; and

a second transparent conductive element provided on a surface of the first transparent conductive element, wherein

the first transparent conductive element and the second transparent conductive element each include:
a substrate having a first surface and a second surface; and
a transparent conductive portion and a transparent insulating portion provided alternately in a planar manner on the first surface and the second surface,

at least one of the transparent conductive portion and the transparent insulating portion is a transparent conductive layer having a regular pattern therein, and

a shape pattern is provided in a boundary portion between the transparent conductive portion and the transparent insulating portion.

(17)

A master for producing a transparent conductive element, including a surface where a transparent conductive portion forming region and a transparent insulating portion forming region are provided alternately in a planar manner, wherein

at least one of the transparent conductive portion forming region and the transparent insulating portion forming region has a regular pattern in the region, and

a shape pattern is provided in a boundary portion between the transparent conductive portion forming region and the transparent insulating portion forming region.

### REFERENCE SIGNS LIST

1 First transparent conductive element
2 Second transparent conductive element
3 Optical layer
4 Display device
5, 32 Adhering layer
10 Information input device
11, 21, 31 Substrate
12, 22 Transparent conductive layer
13, 23 Transparent electrode portion
14, 24 Transparent insulating portion
13a, 23a Hole portion
13b, 23b Conductive portion
14a, 24a Island portion
14b, 24b Gap portion
15 Inverting portion
41 Resist layer
33 Opening
L Boundary
R₁ First region
R₂ Second region

1-17. (canceled)

18. A transparent conductive element comprising:
a substrate having a surface; and
a transparent conductive portion and a transparent insulating portion provided alternately in a planar manner on the surface, wherein
at least one of the transparent conductive portion and the transparent insulating portion is a transparent conductive layer having a regular pattern therein,
a shape pattern is provided in a boundary portion between the transparent conductive portion and the transparent insulating portion,
a pattern in the transparent conductive portion is a pattern of a plurality of hole portions,
a pattern in the transparent insulating portion is a pattern of a plurality of island portions,
the shape pattern in the boundary portion includes one or more selected from the group consisting of a whole of the hole portion, part of the hole portion, a whole of the island portion, and part of the island portion, and
the whole of the island portion and the whole of the hole portion included in the shape pattern in the boundary portion are provided in contact with a boundary between the transparent conductive portion and the transparent insulating portion.

19. A transparent conductive element comprising:
a substrate having a surface; and
a transparent conductive portion and a transparent insulating portion provided alternately in a planar manner on the surface, wherein
at least one of the transparent conductive portion and the transparent insulating portion is a transparent conductive layer having a regular pattern therein,
a shape pattern is provided in a boundary portion between the transparent conductive portion and the transparent insulating portion,
a pattern in the transparent conductive portion is a pattern of a plurality of hole portions,
a pattern in the transparent insulating portion is a pattern of a plurality of island portions,
the shape pattern in the boundary portion includes one or more selected from the group consisting of a whole of the hole portion, part of the hole portion, a whole of the island portion, and part of the island portion, and
the part of the hole portion and the part of the island portion included in the shape pattern in the boundary portion have shapes such that the hole portion and the island portion are partially cut by a boundary between the transparent conductive portion and the transparent insulating portion, respectively.

20. A transparent conductive element comprising:
a substrate having a surface; and
a transparent conductive portion and a transparent insulating portion provided alternately in a planar manner on the surface, wherein
at least one of the transparent conductive portion and the transparent insulating portion is a transparent conductive layer having a regular pattern therein,
a shape pattern is provided in a boundary portion between the transparent conductive portion and the transparent insulating portion,
a pattern in the transparent conductive portion is a pattern of a plurality of hole portions,
a pattern in the transparent insulating portion is a pattern of a plurality of island portions, and
the shape pattern in the boundary portion includes a plurality of inverting portions in which the hole portions are inverted into the island portions.

21. The transparent conductive element according to claim 18, wherein
both of the pattern of the plurality of hole portions and the pattern of the plurality of island portions are regular patterns, and
the shape pattern in the boundary portion is a regular shape pattern.

22. The transparent conductive element according to claim 18, wherein
one of the pattern of the plurality of hole portions and the pattern of the plurality of island portions is a regular pattern, whereas the other one thereof is a random pattern, and
the shape pattern in the boundary portion is a random shape pattern.

23. The transparent conductive element according to claim 18, wherein the hole portion and the island portion each have a dot shape.

24. The transparent conductive element according to claim 18, wherein the hole portion has a dot shape and a gap portion between the island portions has a mesh shape.

25. The transparent conductive element according to claim 18, wherein average boundary line lengths in the transparent conductive portion and the transparent insulating portion are smaller than or equal to 20 mm/mm².

26. The transparent conductive element according to claim 18, wherein an absolute value of a difference between reflection L values in the transparent conductive portion and in the transparent insulating portion is smaller than 0.3.

27. A transparent conductive element comprising:
a substrate having a surface; and
a transparent conductive portion and a transparent insulating portion provided alternately in a planar manner on the surface, wherein
the transparent insulating portion is a transparent conductive layer having a regular pattern therein,
a shape pattern is provided in a boundary portion between the transparent conductive portion and the transparent insulating portion,
a pattern in the transparent insulating portion is a pattern of a plurality of island portions, and
the shape pattern in the boundary portion includes a plurality of inverting portions in which a whole or part of the island portions in the transparent insulating portion are inverted into the hole portions in the transparent conductive portion.

28. The transparent conductive element according to claim 27, wherein the transparent conductive portion is a transparent conductive layer continuously provided on the surface.

29. An input device comprising the transparent conductive element according to claim 18.

30. An electronic apparatus comprising the transparent conductive element according to claim 18.

31. A master for forming a transparent conductive element, including a surface where a transparent conductive portion forming region and a transparent insulating portion forming region are provided alternately in a planar manner, wherein
at least one of the transparent conductive portion forming region and the transparent insulating portion forming region has a regular pattern in the region,
a shape pattern is provided in a boundary portion between the transparent conductive portion forming region and the transparent insulating portion forming region,
the transparent conductive portion forming region is a pattern of a plurality of hole portions,
the transparent insulating portion forming region is a pattern of a plurality of island portions,
the shape pattern in the boundary portion includes one or more selected from the group consisting of a whole of the hole portion, part of the hole portion, a whole of the island portion, and part of the island portion, and
the whole of the island portion and the whole of the hole portion included in the shape pattern in the boundary portion are provided in contact with a boundary between the transparent conductive portion forming region and the transparent insulating portion forming region.

32. A master for forming a transparent conductive element, including a surface where a transparent conductive portion forming region and a transparent insulating portion forming region are provided alternately in a planar manner, wherein
at least one of the transparent conductive portion forming region and the transparent insulating portion forming region has a regular pattern in the region,
a shape pattern is provided in a boundary portion between the transparent conductive portion forming region and the transparent insulating portion forming region,
the transparent conductive portion forming region includes a pattern of a plurality of hole portions,
the transparent insulating portion forming region includes a pattern of a plurality of island portions,
the shape pattern in the boundary portion includes one or more selected from the group consisting of a whole of the hole portion, part of the hole portion, a whole of the island portion, and part of the island portion, and
the part of the hole portion and the part of the island portion included in the shape pattern in the boundary portion have shapes such that the hole portion and the island portion are partially cut by a boundary between the transparent conductive portion forming region and the transparent insulating portion forming region, respectively.

33. A master for forming a transparent conductive element, including a surface where a transparent conductive portion forming region and a transparent insulating portion forming region are provided alternately in a planar manner, wherein
at least one of the transparent conductive portion forming region and the transparent insulating portion forming region has a regular pattern in the region,
a shape pattern is provided in a boundary portion between the transparent conductive portion forming region and the transparent insulating portion forming region,
the transparent conductive portion forming region includes a pattern of a plurality of hole portions,
the transparent insulating portion forming region includes a pattern of a plurality of island portions, and
the shape pattern in the boundary portion includes a plurality of inverting portions in which the hole portions are inverted into the island portions.

34. A master for forming a transparent conductive element, including a surface where a transparent conductive portion forming region and a transparent insulating portion forming region are provided alternately in a planar manner, wherein
the transparent insulating portion forming region has a regular pattern in the region,
a shape pattern is provided in a boundary portion between the transparent conductive portion forming region and the transparent insulating portion forming region,
the transparent conductive portion forming region includes a pattern of a plurality of island portions, and
the shape pattern in the boundary portion includes a plurality of inverting portions in which the whole or part of the island portions in the transparent insulating portion forming region are inverted into the hole portions in the transparent conductive portion forming region.

35. A transparent conductive element comprising:
a substrate having a surface; and
a transparent conductive portion and a transparent insulating portion provided alternately in a planar manner on the surface, wherein
the transparent insulating portion is a transparent conductive layer having a regular pattern therein,
the transparent conductive portion is a transparent conductive layer continuously provided,
a shape pattern is provided in a boundary portion between the transparent conductive portion and the transparent insulating portion,
a pattern in the transparent insulating portion is a pattern of a plurality of island portions,
the shape pattern in the boundary portion includes one or more selected from the group consisting of a whole and part of the island portion, and
the whole of the island portion included in the shape pattern in the boundary portion is provided in contact with a boundary between the transparent conductive portion and the transparent insulating portion.

36. A transparent conductive element comprising:
a substrate having a surface; and
a transparent conductive portion and a transparent insulating portion provided alternately in a planar manner on the surface, wherein
the transparent insulating portion is a transparent conductive layer having a regular pattern therein,
the transparent conductive portion is a transparent conductive layer continuously provided,
a shape pattern is provided in a boundary portion between the transparent conductive portion and the transparent insulating portion,
a pattern in the transparent insulating portion is a pattern of a plurality of island portions,
the shape pattern in the boundary portion includes one or more selected from the group consisting of a whole and part of the island portion, and
the part of the island portion included in the shape pattern in the boundary portion has a shape such that the island portion is partially cut by a boundary between the transparent conductive portion and the transparent insulating portion, respectively.

37. An input device comprising the transparent conductive element according to claim 35.

38. An electronic apparatus comprising the transparent conductive element according to claim 35.

39. A master for forming a transparent conductive element, including a surface where a transparent conductive portion forming region and a transparent insulating portion forming region are provided alternately in a planar manner, wherein
the transparent insulating portion forming region has a regular pattern in the region,
the transparent conductive portion fainting region includes a solid pattern,
a shape pattern is provided in a boundary portion between the transparent conductive portion forming region and the transparent insulating portion forming region,
the transparent insulating portion forming region is a pattern of a plurality of island portions,
the shape pattern in the boundary portion includes one or more selected from the group consisting of a whole and part of the island portion, and
the whole of the island portion included in the shape pattern in the boundary portion is provided in contact with a boundary between the transparent conductive portion forming region and the transparent insulating portion forming region.

40. A master for forming a transparent conductive element, including a surface where a transparent conductive portion forming region and a transparent insulating portion forming region are provided alternately in a planar manner, wherein
the transparent insulating portion forming region has a regular pattern in the region,
the transparent conductive portion forming region includes a solid pattern,
a shape pattern is provided in a boundary portion between the transparent conductive portion forming region and the transparent insulating portion forming region,
the shape pattern in the boundary portion is a pattern of a plurality of island portions,
the shape pattern in the boundary portion includes one or more selected from the group consisting of a whole and part of the island portion, and
the part of the island portion included in the shape pattern in the boundary portion has a shape such that the island portion is partially cut by a boundary between the transparent conductive portion forming region and the transparent insulating portion forming region.
